(19) United States
(12) Patent Application Publication
(10) Pub. No.: US 2023/0057142 A1
(43) Pub. Date: Feb. 23, 2023

(54) LIGHT EMITTING DEVICE AND POLYCYCLIC COMPOUND FOR THE SAME

(71) Applicant: Samsung Display Co., Ltd., Yongin-si (KR)

(72) Inventors: Yuji SUZAKI, Yokohama (JP); Hirokazu KUWABARA, Yokohama (JP); Ryuhei FURUE, Yokohama (JP); Tetuji HAYANO, Yokohama (JP)

(73) Assignee: Samsung Display Co., Ltd., Yongin-si (KR)

(21) Appl. No.: 17/675,482

(22) Filed: Feb. 18, 2022

(30) Foreign Application Priority Data
Jul. 9, 2021 (KR) 10-2021-0090258

(51) Int. Cl. H01L 51/00; C07F 5/02; C09K 11/06

(52) U.S. Cl. CPC H01L 51/008; C07F 5/025; C09K 11/06; H01L 51/5012

(57) ABSTRACT

A light emitting device of an embodiment includes a first electrode, a second electrode disposed on the first electrode, and an emission layer disposed between the first electrode and the second electrode. The emission layer may include a polycyclic compound of an embodiment represented by Formula 1. The light emitting device including the polycyclic compound of an embodiment may show improved efficiency and device life.

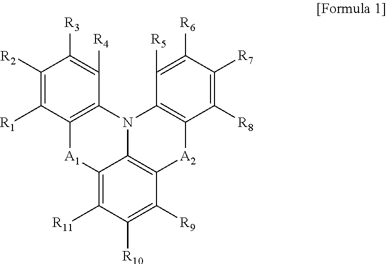

### CROSS-REFERENCE TO RELATED APPLICATION(S)

This application claims priority to and benefits of Korean Patent Application No. 10-2021-0090258 under 35 U.S.C. § 119, filed on Jul. 9, 2021 in the Korean Intellectual Property Office, the entire contents of which are incorporated herein by reference.

### BACKGROUND

### 1. Technical Field

The disclosure relates to a light emitting device and a polycyclic compound used therein.

### 2. Description of the Related Art

Active development continues for a light emitting display device as an image display device. The light emitting display device is a so-called self-luminescent display device in which holes and electrons respectively injected from a first electrode and a second electrode recombine in an emission layer, and a light-emitting material in the emission layer emits light to achieve display.

In the application of a light emitting display device to an image display device, there is a demand for increasing emission efficiency and device life, and continuous development is required on materials for a light emitting device which stably achieves such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting device showing excellent emission efficiency and long-life characteristics.

The disclosure also provides a polycyclic compound which is a material for a light emitting device having high efficiency and long-life characteristics.

An embodiment provides a light emitting device which may include a first electrode, a second electrode disposed on the first electrode, and an emission layer disposed between the first electrode and the second electrode and including a polycyclic compound represented by Formula 1.

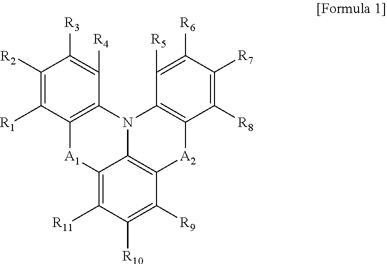

In Formula 1, at least one of A₁ and A₂ may be a group represented by

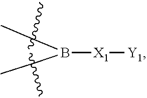

and the remainder of A₁ and A₂ may be a direct linkage, C(R₂₁)(R₂₂), B(R₂₃), N(R₂₄), Si(R₂₅)(R₂₆), P(R₂₇), O, S, SO, SO₂, or CO, X₁ may be O, S, SO, or SO₂, Y₁ may be CO(R₂₈) or R₂₉, R₁ to R₁₁ and R₂₁ to R₂₈ may each independently be a hydrogen atom, a deuterium atom, a halogen atom, a hydroxyl group, a cyano group, a substituted or unsubstituted oxy group, a substituted or unsubstituted thio group, a substituted or unsubstituted amino group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring, and R₂₉ may be a deuterium atom, a halogen atom, a hydroxyl group, a cyano group, a substituted or unsubstituted oxy group, a substituted or unsubstituted thio group, a substituted or unsubstituted amino group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In an embodiment, the polycyclic compound represented by Formula 1 may be represented by Formula 1-A1 or Formula 1-A2.

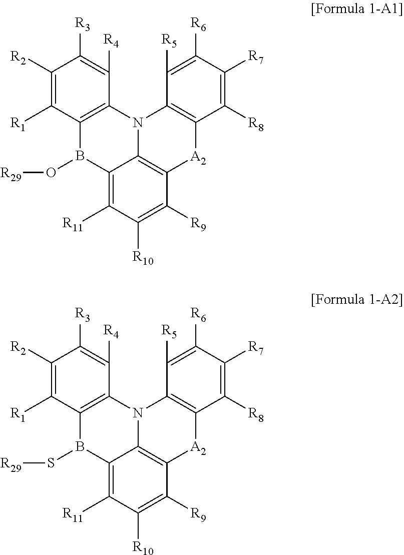

In Formula 1-A1 and Formula 1-A2, A₂, R₁ to R₁₁, and R₂₉ may be the same as defined in Formula 1.

In an embodiment, the polycyclic compound represented by Formula 1 may be represented by Formula 1-B1 or Formula 1-B2.

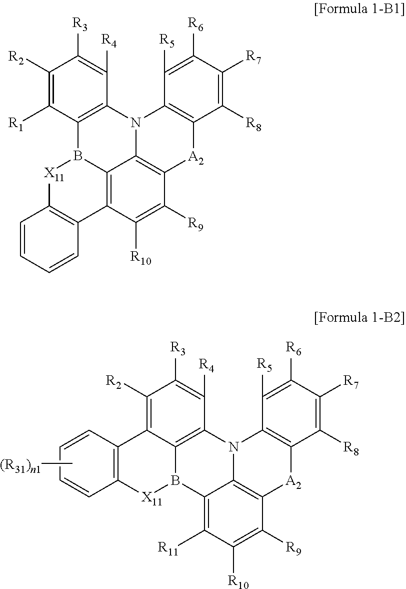

In Formula 1-B1 and Formula 1-B2, X₁₁ may be O, S, or SO, n1 may be an integer from 0 to 4, R₃₁ is a hydrogen atom, a deuterium atom, a substituted or unsubstituted alkyl group or 1 to 20 carbon atoms, or a substituted or unsubstituted aryl group of 6 to 30 ring-forming carbon atoms, and A₂ and R₁ to R₁₁ may be the same as defined in Formula 1.

In an embodiment, the polycyclic compound represented by Formula 1 may be represented by Formula 1-B11 or Formula 1-B21.

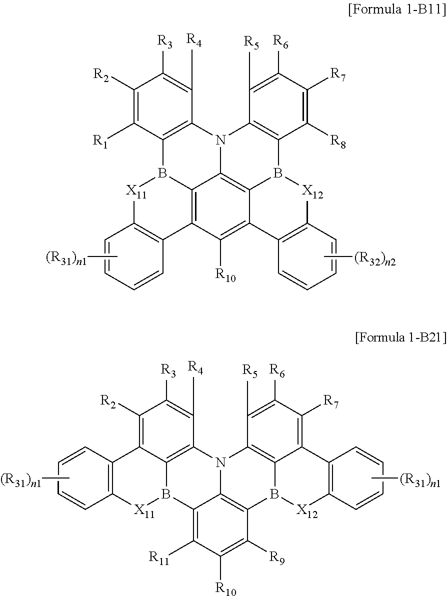

In Formula 1-B11 and Formula 1-B21, X₁₁ and X₁₂ may each independently be O, or S, n1 and n2 may each independently be an integer from 0 to 4, R₃₁ and R₃₂ may each independently be a hydrogen atom, a deuterium atom, or a substituted or unsubstituted alkyl group of 1 to 20 carbon atoms, and R₁ to R₁₁ may be the same as defined in Formula 1.

In an embodiment, the polycyclic compound represented by Formula 1 may be represented by Formula 1-C.

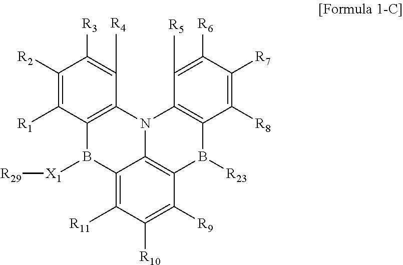

In Formula 1-C, R₁ to R₁₁, R₂₃, R₂₉, and X₁ may be the same as defined in Formula 1.

In an embodiment, A₁ or A₂ may be B(R₂₃), and R₂₃ may be a substituted or unsubstituted methoxy group, a substituted or unsubstituted isopropoxy group, a substituted or unsubstituted methylthio group, a substituted or unsubstituted isopropylthio group, a substituted or unsubstituted phenoxy group, a substituted or unsubstituted phenyl group, or a substituted or unsubstituted phenylthio group.

In an embodiment, R₁ to R₁₁ may each independently be a substituted or unsubstituted alkyl group of 1 to 5 carbon atoms, a substituted or unsubstituted aryl group of 6 to 12 carbon atoms, a substituted or unsubstituted alkyl amino group, a substituted or unsubstituted aryl amino group, a substituted or unsubstituted aryl oxy group, or an unsubstituted carbazole group.

In an embodiment, the polycyclic compound represented by Formula 1 may be represented by any one of Formula 1-E1 to Formula 1-E3.

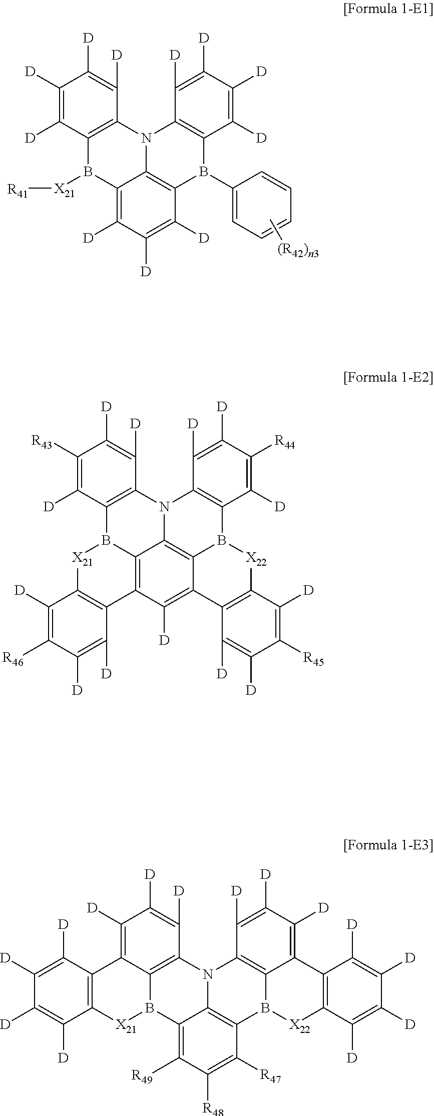

In Formula 1-E1, n3 may be an integer from 0 to 5. In Formula 1-E1 to Formula 1-E3, X₂₁ and X₂₂ may each independently be O or S, and R₄₁ to R₄₉ may each independently be a hydrogen atom, a deuterium atom, a methyl group substituted with a deuterium atom, an isopropyl group substituted with a deuterium atom, a t-butyl group substituted with a deuterium atom, or a phenyl group substituted with a deuterium atom.

In an embodiment A₁ and A₂ in Formula 1 may be the same.

In an embodiment, the emission layer may be a delayed fluorescence emission layer including a host and a dopant, and the dopant may include the polycyclic compound.

In an embodiment, the emission layer may include at least one selected from Compound Group 1, which is explained below.

Another embodiment provides a polycyclic compound represented by Formula 1.

In an embodiment, in Formula 1, at least one of R₁ to R₁₁ may be a deuterium atom, or at least one of A₁, A₂, and R₁ to R₁₁ may include a deuterium atom as a substituent.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the attached drawings, in which:

FIG. 1 is a plan view showing a display apparatus according to an embodiment;

FIG. 2 is a schematic cross-sectional view showing a display apparatus according to an embodiment;

FIG. 3 is a schematic cross-sectional view showing a light emitting device of an embodiment;

FIG. 4 is a schematic cross-sectional view showing a light emitting device of an embodiment;

FIG. 5 is a schematic cross-sectional view showing a light emitting device of an embodiment;

FIG. 6 is a schematic cross-sectional view showing a light emitting device of an embodiment;

FIG. 7 is a schematic cross-sectional view showing a display apparatus according to an embodiment; and

FIG. 8 is a schematic cross-sectional view showing a display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

The term “at least one of” is intended to include the meaning of “at least one selected from” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

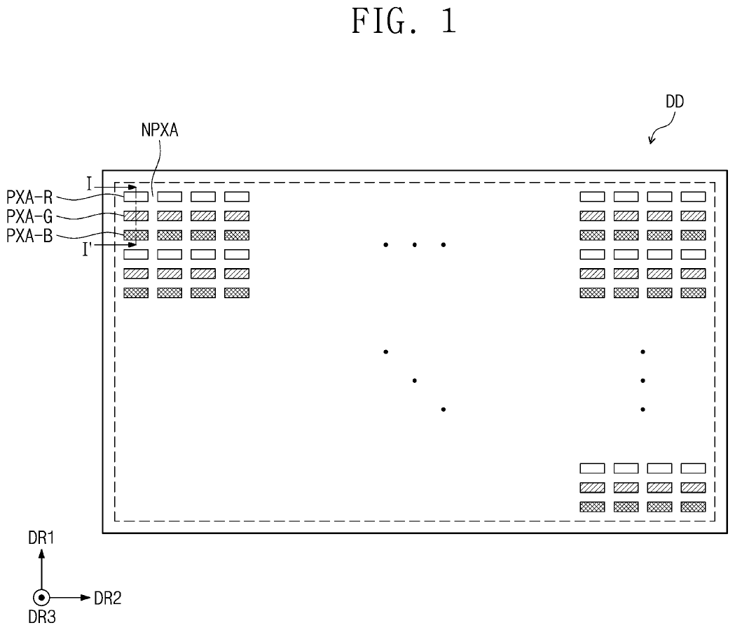

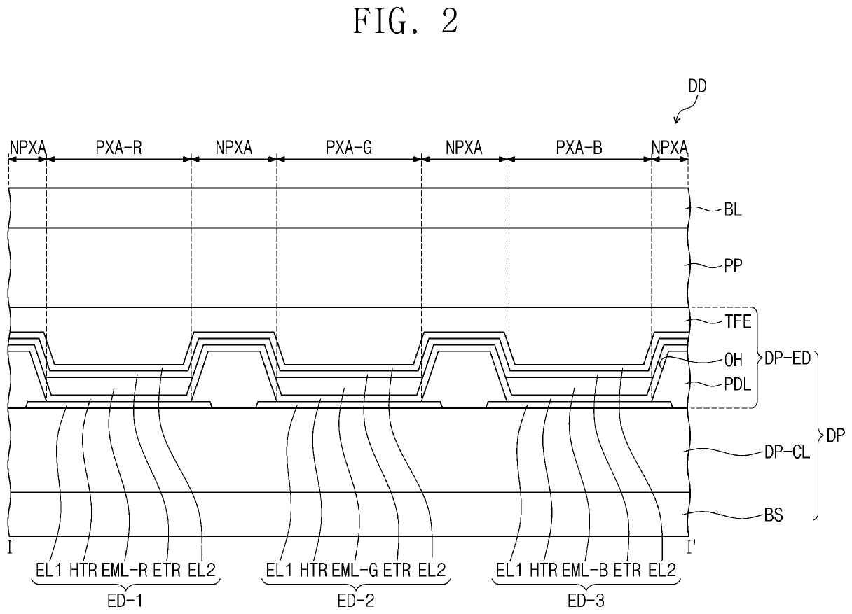

Hereinafter, embodiments will be explained with reference to the drawings. FIG. 1 is a plan view showing an embodiment of a display apparatus DD. FIG. 2 is a schematic cross-sectional view of a display apparatus DD of an embodiment. FIG. 2 is a schematic cross-sectional view showing a part corresponding to line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include multiples of each of the light emitting devices ED-1, ED-2, and ED-3. The optical layer PP may be disposed on the display panel DP and may control light reflected at the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface where the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a plugging layer (not shown). The plugging layer (not shown) may be disposed between a display device layer DP-ED and a base substrate BL. The plugging layer (not shown) may be an organic layer. The plugging layer (not shown) may include at least one of an acrylic resin, a silicon-based resin, and an epoxy-based resin.

The display panel DP may include a base layer BS, a circuit layer DP-CL provided on the base layer BS and a display device layer DP-ED. The display device layer DP-ED may include a pixel definition layer PDL, light emitting devices ED-1, ED-2, and ED-3 disposed in the pixel definition layer PDL, and an encapsulating layer TFE disposed on the light emitting devices ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include switching transistors and driving transistors for driving the light emitting devices ED-1, ED-2, and ED-3 of the display device layer DP-ED.

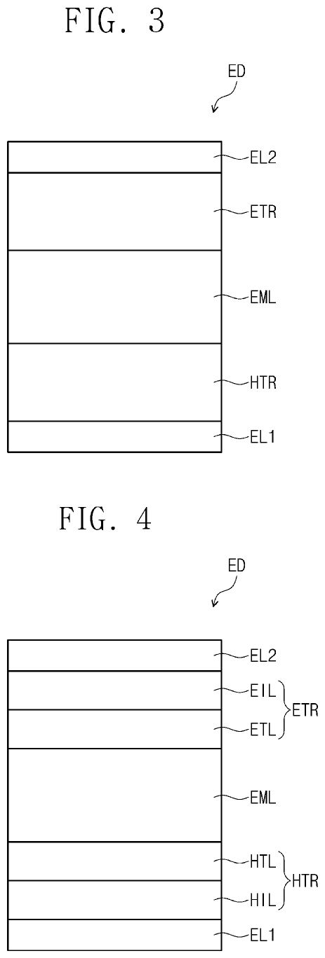

Each of the light emitting devices ED-1, ED-2, and ED-3 may have a structure of a light emitting device ED of embodiments according to FIG. 3 to FIG. 6, which will be explained later. Each of the light emitting devices ED-1, ED-2, and ED-3 may include a first electrode EL1, a hole transport region HTR, emission layers EML-R, EML-G, and EML-B, an electron transport region ETR, and a second electrode EL2.

FIG. 2 shows an embodiment where the emission layers EML-R, EML-G, and EML-B of the light emitting devices ED-1, ED-2, and ED-3 are disposed in openings OH defined in a pixel definition layer PDL, and a hole transport region HTR, an electron transport region ETR, and a second electrode EL2 are each provided as common layers in all light emitting devices ED-1, ED-2, and ED-3. However, embodiments are not limited thereto. Although not shown in FIG. 2, in an embodiment, the hole transport region HTR and the electron transport region ETR may each be patterned and provided in the openings OH defined in the pixel definition layer PDL. For example, in an embodiment, the hole transport region HTR, the emission layers EML-R, EML-G, and EML-B, and the electron transport region ETR of the light emitting devices ED-1, ED-2, and ED-3 may be patterned by an ink jet printing method and provided.

An encapsulating layer TFE may cover the light emitting devices ED-1, ED-2, and ED-3. The encapsulating layer TFE may encapsulate the display device layer DP-ED. The encapsulating layer TFE may be a thin film encapsulating layer. The encapsulating layer TFE may be one layer or a stack of multiple layers. The encapsulating layer TFE may include at least one insulating layer. The encapsulating layer TFE according to an embodiment may include at least one inorganic layer (hereinafter, encapsulating inorganic layer). The encapsulating layer TFE according to an embodiment may include at least one organic layer (hereinafter, encapsulating organic layer) and at least one encapsulating inorganic layer.

The encapsulating inorganic layer may protect the display device layer DP-ED from moisture and/or oxygen and the encapsulating organic layer may protect the display device layer DP-ED from foreign materials such as dust particles. The encapsulating inorganic layer may include silicon nitride, silicon oxy nitride, silicon oxide, titanium oxide, or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be disposed on the second electrode EL2 and may be disposed to fill the openings OH.

Referring to FIG. 1 and FIG. 2, the display apparatus DD may include non-luminous areas NPXA and luminous areas PXA-R, PXA-G, and PXA-B. The luminous areas PXA-R, PXA-G, and PXA-B may each be areas emitting light produced from the light emitting devices ED-1, ED-2, and ED-3, respectively. The luminous areas PXA-R, PXA-G, and PXA-B may be separated from each other on a plane.

The luminous areas PXA-R, PXA-G, and PXA-B may each be areas separated by the pixel definition layer PDL. The non-luminous areas NPXA may be areas between neighboring luminous areas PXA-R, PXA-G, and PXA-B and may be areas corresponding to the pixel definition layer PDL. For example, in an embodiment, each of the luminous areas PXA-R, PXA-G, and PXA-B may correspond to a pixel. The pixel definition layer PDL may separate the light emitting devices ED-1, ED-2, and ED-3. The emission layers EML-R, EML-G, and EML-B of the light emitting devices ED-1, ED-2, and ED-3 may be disposed in the openings OH defined in the pixel definition layer PDL and separated from each other.

The luminous areas PXA-R, PXA-G, and PXA-B may be divided into groups according to the color of light produced from each of the light emitting devices ED-1, ED-2, and ED-3. In the display apparatus DD of an embodiment, shown in FIG. 1 and FIG. 2, three luminous areas PXA-R, PXA-G, and PXA-B respectively emitting red light, green light, and blue light are illustrated as an embodiment. For example, the display apparatus DD of an embodiment may include a red luminous area PXA-R, a green luminous area PXA-G, and a blue luminous area PXA-B, which are separated from each other.

In the display apparatus DD according to an embodiment, the light emitting devices ED-1, ED-2, and ED-3 may each emit light having different wavelength regions. For example, in an embodiment, the display apparatus DD may include a first light emitting device ED-1 emitting red light, a second light emitting device ED-2 emitting green light, and a third light emitting device ED-3 emitting blue light. For example, each of the red luminous area PXA-R, the green luminous area PXA-G, and the blue luminous area PXA-B of the display apparatus DD may correspond to the first light emitting device ED-1, the second light emitting device ED-2, and the third light emitting device ED-3, respectively.

However, embodiments are not limited thereto, and the first to third light emitting devices ED-1, ED-2, and ED-3 may emit light in a same wavelength region, or at least one thereof may emit light in a different wavelength region. For example, the first to third light emitting devices ED-1, ED-2, and ED-3 may all emit blue light.

The luminous areas PXA-R, PXA-G, and PXA-B in the display apparatus DD according to an embodiment may be arranged in a stripe shape. Referring to FIG. 1, the red luminous areas PXA-R, the green luminous areas PXA-G, and the blue luminous areas PXA-B may be arranged along a second direction DR2. The red luminous area PXA-R, the green luminous area PXA-G, and the blue luminous area PXA-B may be arranged by turns along a first direction DR1.

In FIG. 1 and FIG. 2, the areas of the luminous areas PXA-R, PXA-G, and PXA-B are shown as having a similar area, but embodiments are not limited thereto. The areas of the luminous areas PXA-R, PXA-G and PXA-B may be different from each other according to a wavelength region of light emitted. The areas of the luminous areas PXA-R, PXA-G, and PXA-B may be areas in a plan view that are defined by the first direction axis DR1 and the second direction axis DR2.

The arrangement type of the luminous areas PXA-R, PXA-G, and PXA-B is not limited to the configuration shown in FIG. 1, and the arrangement order of the red luminous areas PXA-R, the green luminous areas PXA-G, and the blue luminous areas PXA-B may be provided in various combinations according to the display quality characteristics which are required for the display apparatus DD. For example, the arrangement type of the luminous areas PXA-R, PXA-G, and PXA-B may be a PENTILE™ arrangement type or a diamond arrangement type.

In an embodiment, the areas of the luminous areas PXA-R, PXA-G, and PXA-B may be different from each other. For example, in an embodiment, an area of the green luminous area PXA-G may be smaller than an area of the blue luminous area PXA-B, but embodiments are not limited thereto.

Hereinafter, FIG. 3 to FIG. 6 are each a schematic cross-sectional view showing a light emitting device according to embodiments. A light emitting device ED according to an embodiment may include a first electrode EL1, a hole transport region HTR, an emission layer EML, an electron transport region ETR, and a second electrode EL2 stacked in that order.

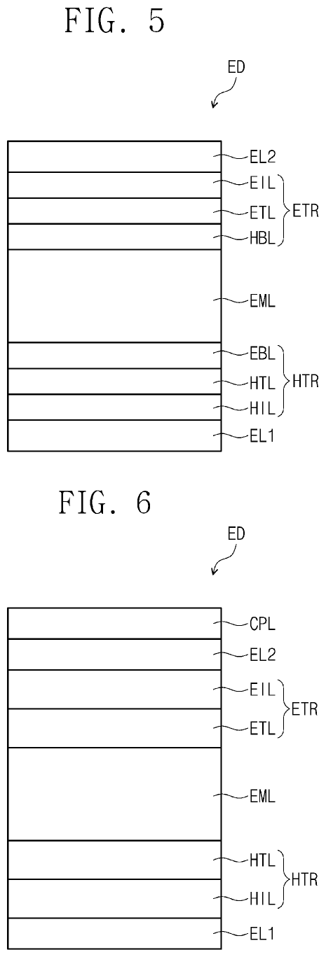

In comparison to FIG. 3, FIG. 4 shows a schematic cross-sectional view of a light emitting device ED of an embodiment, wherein a hole transport region HTR includes a hole injection layer HIL and a hole transport layer HTL, and an electron transport region ETR includes an electron injection layer EIL and an electron transport layer ETL. In comparison to FIG. 3, FIG. 5 shows a schematic cross-sectional view of a light emitting device ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 shows a schematic cross-sectional view of a light emitting device ED of an embodiment that includes a capping layer CPL disposed on the second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. If the first electrode EL1 is a transmissive electrode, the first electrode EL1 may include a transparent metal oxide such as indium tin oxide (ITO), indium zinc oxide (IZO), zinc oxide (ZnO), and indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, compounds thereof, or mixtures thereof (for example, a mixture of Ag and Mg).

In another embodiment, the first electrode EL1 may have a structure of multiple layers including a reflective layer or a transflective layer formed of the above materials, and a transmissive conductive layer formed of ITO, IZO, ZnO, or ITZO. For example, the first electrode EL1 may include a three-layer structure of ITO/Ag/ITO. However, embodiments are not limited thereto. The first electrode EL1 may include the aforementioned metal material, combinations of two or more metal materials selected from the aforementioned metal materials, or oxides of the aforementioned metal materials, without limitation. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may include at least one of a hole injection layer HIL, a hole transport layer HTL, a buffer layer (not shown), an emission auxiliary layer (not shown), or an electron blocking layer EBL. A thickness of the hole transport region HTR may be in a range of about 50 Å to about 15,000 Å.

The hole transport region HTR may be a layer formed of a single material, a layer formed of different materials, or a multilayer structure including layers formed of different materials.

For example, the hole transport region HTR may have the structure of a single layer of a hole injection layer HIL or a hole transport layer HTL, or may have a structure of a single layer formed of a hole injection material and a hole transport material. The hole transport region HTR may have a structure of a single layer formed using different materials, or a structure in which a hole injection layer TIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1.

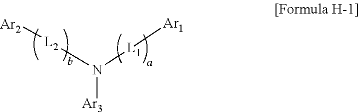

In Formula H-1, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. In Formula H-1, a and b may each independently be an integer from 0 to 10. If a or b is 2 or more, L₁ groups and L₂ groups may each independently be a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. In Formula H-1, Ar₃ may be a substituted or unsubstituted aryl group of 6 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In still another embodiment, the compound represented by Formula H-1 may be a carbazole-based compound including a substituted or unsubstituted carbazole group in at least one of Ar₁ and Ar₂, or may be a fluorene-based compound including a substituted or unsubstituted fluorene group in at least one of A₁ and Ar₂.

The compound represented by Formula H-1 may be represented by any one selected from Compound Group H. However, the compounds shown in Compound Group H are only examples, and the compound represented by Formula H-1 is not limited to Compound Group H.

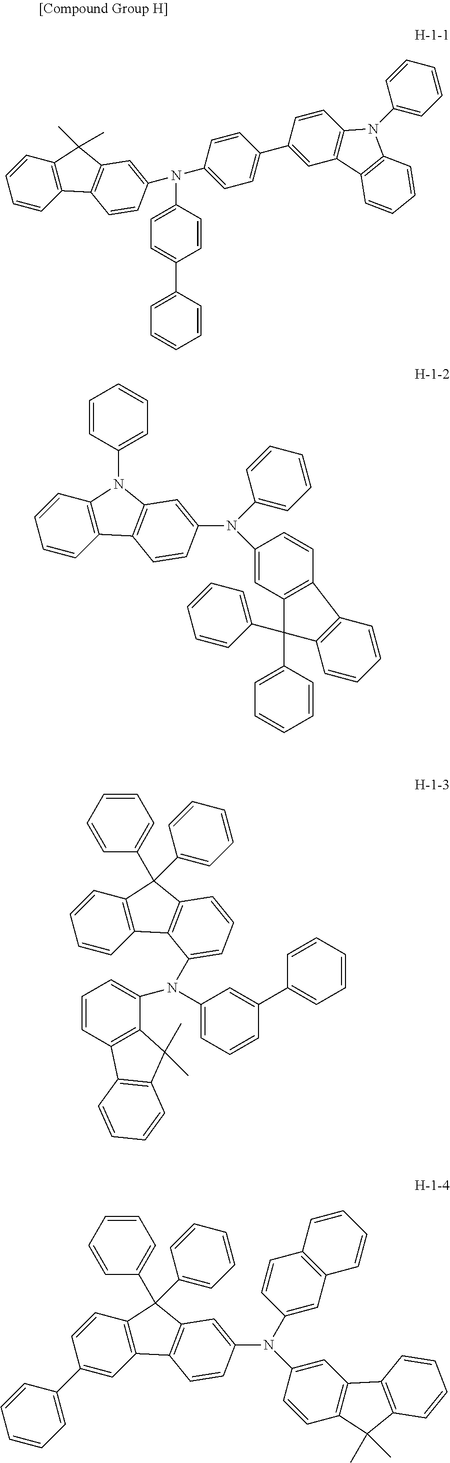 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

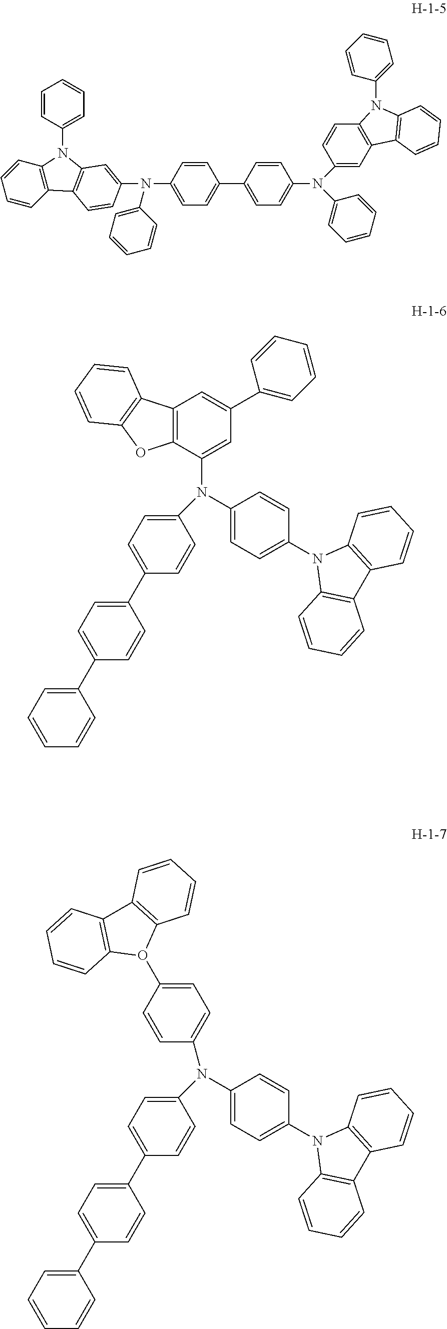

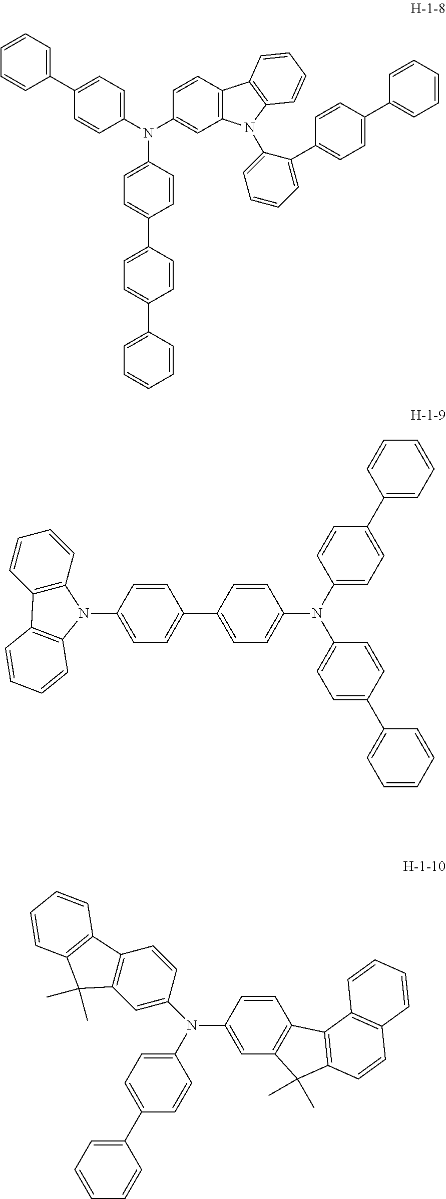 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

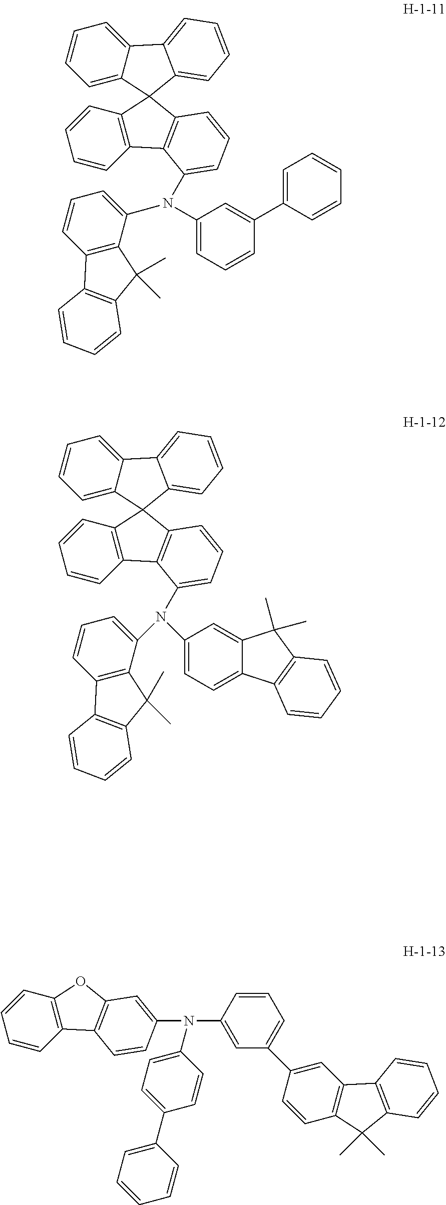 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

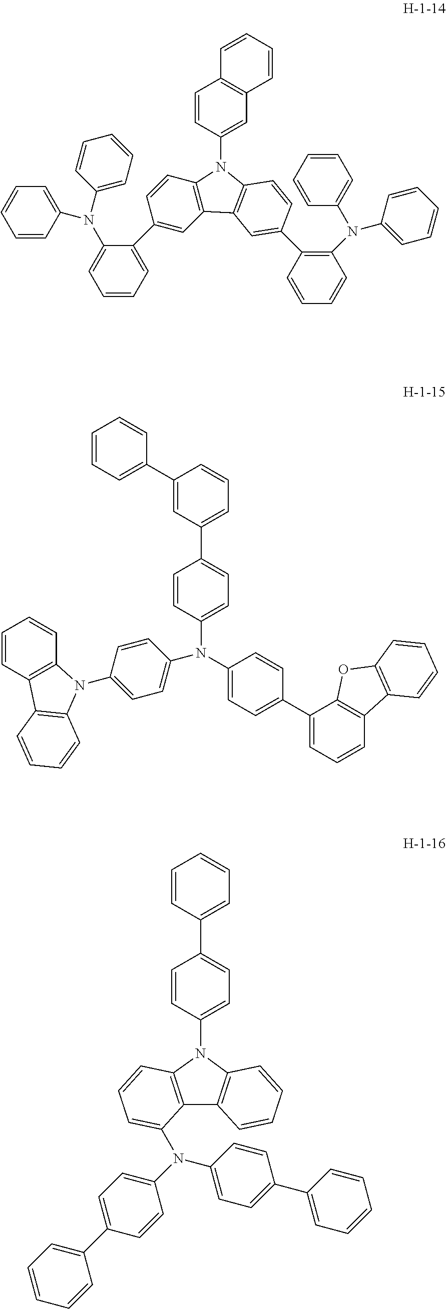 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

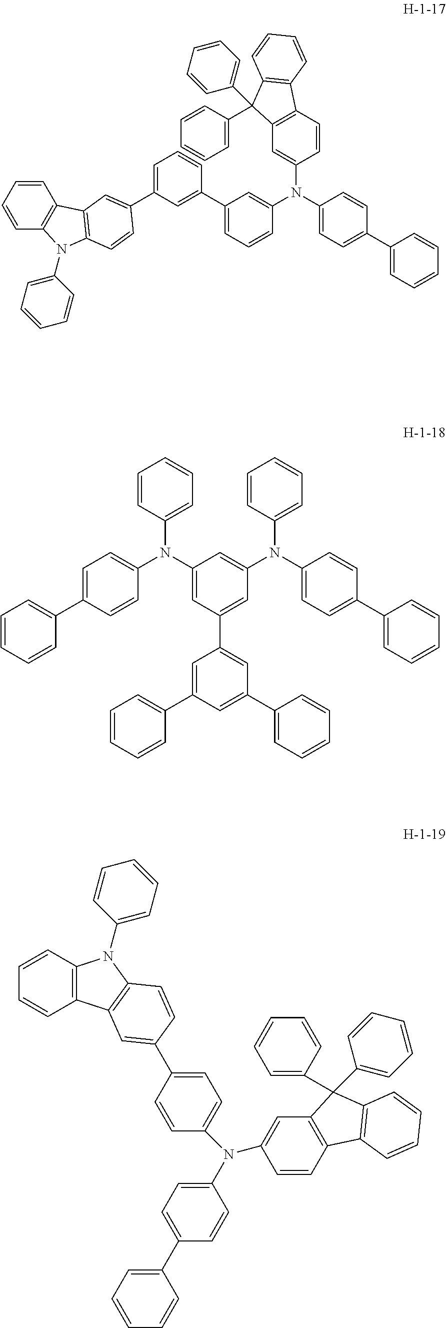 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h] quinoxaline-2,3,6,7,10,11-hexacarbonitrile (HATCN).

The hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP), etc.

The hole transport region HTR may include the compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. If the hole transport region HTR includes a hole injection layer HIL, a thickness of the hole injection layer may be, for example, in a range of about 30 Å to about 1,000 Å. If the hole transport region HTR includes a hole transport layer HTL, a thickness of the hole transport layer HTL may be in a range of about 30 Å to about 1,000 Å. If the hole transport region HTR includes an electron blocking layer EBL, a thickness of the electron blocking layer EBL may be in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase of driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include one of metal halide compounds, quinone derivatives, metal oxides, and cyano group-containing compounds, without limitation. For example, the p-dopant may include metal halide compounds such as CuI and RbI, quinone derivatives such as tetracyanoquinodimethane (TCNQ) and 2,3,5,6-tetrafluoro-7,7′,8,8-tetracyanoquinodimethane (F4-TCNQ), metal oxides such as tungsten oxide and molybdenum oxide, cyano group-containing compounds such as dipyrazino[2,3-f:2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one of a buffer layer (not shown) or an electron blocking layer EBL in addition to the hole injection layer HIL and the hole transport layer HTL. The buffer layer (not shown) may compensate for a resonance distance according to a wavelength of light emitted from an emission layer EML and may increase light emitting efficiency. As materials included in the buffer layer (not shown), materials which may be included in the hole transport region HTR may be used. The electron blocking layer EBL may block the injection of electrons from an electron transport region ETR to a hole transport region HTR.

The emission layer EML is provided on the hole transport region HTR. In the light emitting device ED of an embodiment, the emission layer EML may include the polycyclic compound of an embodiment.

In the description, the term “substituted or unsubstituted” may mean a group that is substituted or unsubstituted with one or more substituents selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. Each of the substituents recited above may itself be substituted or unsubstituted. For example, a biphenyl group may be interpreted as an aryl group or as a phenyl group substituted with a phenyl group.

In the description, the term “combined with an adjacent group to form a ring” may mean a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring which is formed by combining with an adjacent group may itself be combined with another ring to form a spiro structure.

In the description, the term “adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. For example, two methyl groups in 4,5-dimethylphenanthrene may be interpreted as “adjacent groups” to each other.

In the description, examples of a halogen atom may include a fluorine atom, a chlorine atom, a bromine atom, or an iodine atom.

In the description, an oxy group may be an alkyl group or an aryl group which is combined with an oxygen atom. The oxy group may include an alkoxy group or an aryl oxy group. The alkoxy group may be a linear, a branched, or a cyclic chain. The number of carbon atoms in the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, embodiments are not limited thereto.

In the description, a thio group may include an alkyl thio group or an aryl thio group. The thio group may be an alkyl group or an aryl group which is combined with a sulfur atom. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the description, the number of carbon atoms in an amino group is not specifically limited, but may be 1 to 30. The amino group may include an alkyl amino group, an aryl amino group, or a heteroaryl amino group. Examples of the amino group may include a methylamino group, a dimethylamino group, a phenylamino group, a diphenylamino group, a naphthylamino group, a 9-methyl-anthracenylamino group, etc., without limitation.

In the description, an alkyl group may be a linear, a branched, or a cyclic type. The number of carbon atoms in the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, an alkenyl group may be a hydrocarbon group including one or more carbon-carbon double bonds in the middle or at the terminal of an alkyl group of two or more carbon atoms. The alkenyl group may be a linear chain or a branched chain. The number of carbon atoms in the alkenyl group is not specifically limited but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, etc., without limitation.

In the description, an aryl group may be any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the description, a heteroaryl group may include one or more of B, O, N, P, Si, or S as heteroatoms. If the heteroaryl group includes two or more heteroatoms, two or more heteroatoms may be the same as each other or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the description, the explanation on the aryl group may be applied to an arylene group except that the arylene group is a divalent group. The explanation on the heteroaryl group may be applied to a heteroarylene group except that the heteroarylene group is a divalent group.

In the description, an alkyl group in an alkyl thio group, an alkyl sulfoxy group, an alkyl oxy group, an alkyl amino group, an alkyl boron group, an alkyl silyl group, and an alkyl amine group may be the same as the alkyl group as described above.

In the description, an aryl group in an aryl oxy group, an aryl thio group, an aryl sulfoxy group, an aryl amino group, an aryl boron group, an aryl silyl group, and an aryl amine group may be the same as the aryl group as described above.

In the description, a direct linkage may be a single bond.

In the description,

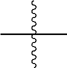

and [symbol] each represents a binding site to a neighboring [symbol] atom.

In the light emitting device ED of an embodiment, the emission layer EML may include a polycyclic compound represented by Formula 1.

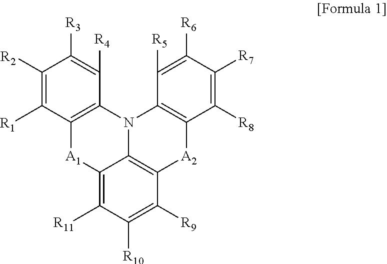

In Formula 1, at least one of A₁ and A₂ may be a group represented by

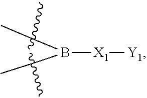

and the remainder of A₁ and A₂ may be a direct linkage, C(R₂₁)(R₂₂), B(R₂₃), N(R₂₄), Si(R₂₅)(R₂₆), P(R₂₇), O, S, SO, SO₂, or CO. The polycyclic compound of an embodiment may include at least one boron atom as a ring-forming atom. For example, in an embodiment, at least one of A₁ and A₂ may be a group represented by

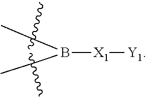

In another embodiment, both A₁ and A₂ may be a group represented by

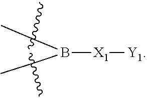

In Formula 1, X₁ may be O, S, SO, or SO₂. In Formula 1, Y₁ may be CO(R₂₈) or R₂₉. X₁ may include an oxygen atom or a sulfur atom. In an embodiment, the polycyclic compound of an embodiment may include an oxygen atom directly bonded to a boron atom which is a ring-forming atom. In another embodiment, the polycyclic compound of an embodiment may include a sulfur atom directly bonded to a boron atom which is a ring-forming atom.

In Formula 1, R₁ to R₁₁ and R₂₁ to R₂₈ may each independently be a hydrogen atom, a deuterium atom, a halogen atom, a hydroxyl group, a cyano group, a substituted or unsubstituted oxy group, a substituted or unsubstituted thio group, a substituted or unsubstituted amino group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

For example, each of R₆ and R₇ may be a vinyl group, and R₆ and R₇ may be combined to form a phenyl group. For example, R₂₈ may be a substituted or unsubstituted alkyl group of 1 to 5 carbon atoms. For example, R₂₈ may be a methyl group. However, these are only examples, and embodiments are not limited thereto.

In Formula 1, R₂₉ may be a deuterium atom, a halogen atom, a hydroxyl group, a cyano group, a substituted or unsubstituted oxy group, a substituted or unsubstituted thio group, a substituted or unsubstituted amino group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In an embodiment, in Formula 1, if at least one of A₁ and A₂ is a group represented by

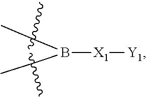

and Y₁ is R₂₉, then R₂₉ may not be a hydrogen atom. For example, in Formula 1, A₁ and A₂ may not be —BOH, —BSH, —BSOH, or —BSO₂H.

In an embodiment, R₁ to R₁₁ may each independently be a substituted or unsubstituted alkyl group of 1 to 5 carbon atoms, a substituted or unsubstituted aryl group of 6 to 12 carbon atoms, a substituted or unsubstituted alkyl amino group, a substituted or unsubstituted aryl amino group, a substituted or unsubstituted aryl oxy group, or an unsubstituted carbazole group. For example, R₁ to R₁₁ may each independently be a methyl group, a trifluoromethyl group, an ethyl group, a substituted or unsubstituted t-butyl group, a vinyl group, a dimethylamino group, a substituted or unsubstituted diphenylamino group, a substituted or unsubstituted phenyl group, or a substituted or unsubstituted phenoxy group. However, these are only examples, and embodiments are not limited thereto.

For example, in Formula 1, A₁ may be a group represented by

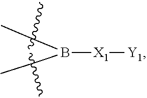

and A₂ may be a direct linkage. For example, A₁ may be a group represented by

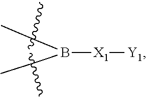

A₂ may be C(R₂₁)(R₂₂), and R₂₁ and R₂₂ may each independently be a methyl group, an ethyl group, or a substituted or unsubstituted phenyl group. In an embodiment, in Formula 1, A₁ may be a group represented by

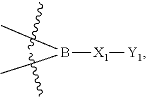

A₂ may be N(R₂₄), and R₂₄ may be a substituted or unsubstituted phenyl group. In an embodiment, in Formula 1, A₁ may be a group represented by

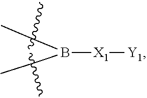

A₂ may be Si(R₂₅)(R₂₆), and R₂₅ and R₂₆ may each be a substituted or unsubstituted phenyl group. In an embodiment, in Formula 1, A₁ may be a group represented by

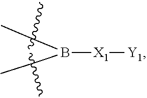

A₂ may be P(R₂₇), and R₂₇ may be a substituted or unsubstituted phenyl group.

In another embodiment, both A₁ and A₂ may each independently be a group represented by

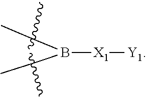

If both A₁ and A₂ are a group represented by

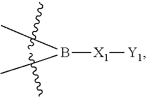

then X₁ of A₁ and X₁ of A₂ may be the same or different. If both A₁ and A₂ are a group represented by

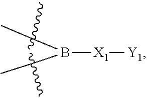

then Y₁ of A₁ and Y₁ of A₂ may be the same or different.

In an embodiment, in Formula 1, A₁ and A₂ may be the same. The polycyclic compound represented by Formula 1 may be left-ring symmetric with respect to N (nitrogen atom) of Formula 1. In an embodiment, in Formula 1, at least one of R₁ to R₁₁ may be a deuterium atom. In another embodiment, in Formula 1, at least one of A₁, A₂, and R₁ to R₁₁ may include a deuterium atom as a substituent.

The polycyclic compound represented by Formula 1 may include a direct linkage between a boron atom and an oxygen atom, or a direct linkage between a boron atom and a sulfur atom. In an embodiment, Formula 1 may be represented by Formula 1-A1 or Formula 1-A2. Formula 1-A1 represents Formula 1 where A₁ is a group represented by

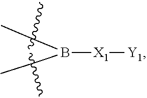

X₁ is an oxygen atom, and Y₁ is R₂₉. Formula 1-A2 represents Formula 1 where A₁ is a group represented by

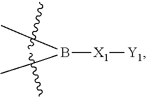

X₁ is a sulfur atom, and Y₁ is R₂₉.

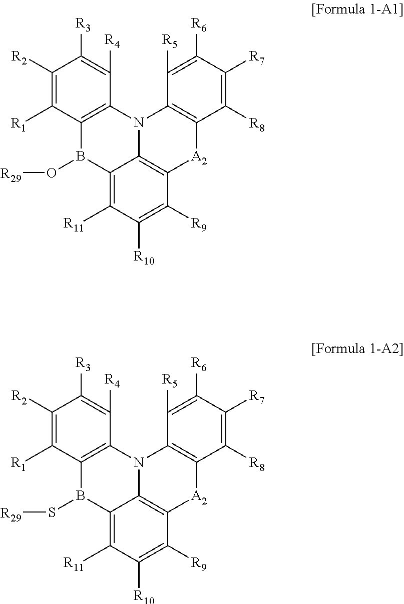

In Formula 1-A1 and Formula 1-A2, A₂, R₁ to R₁₁, and R₂₉ may be the same as defined in Formula 1. For example, in Formula 1-A1 and Formula 1-A2, R₂₉ may be a methyl group, an ethyl group, an isopropyl group, or a substituted or unsubstituted phenyl group.

In an embodiment, in Formula 1-A1 and Formula 1-A2, R₂₉ may be combined with adjacent R₁ to form a ring. In another embodiment, in Formula 1-A1 and Formula 1-A2, R₂₉ may be combined with adjacent R₁₁ to form a ring. For example, in Formula 1-A1, R₂₉ may be a substituted or unsubstituted phenyl group, and R₂₉ may be combined with adjacent R₁ to form a ring to form a fused ring of seven rings, including a boron atom and an oxygen atom as ring-forming atoms. For example, in Formula 1-A2, R₂₉ may be a substituted or unsubstituted phenyl group, and R₂₉ may be combined with adjacent R₁ to form a ring to form a fused ring of seven rings, including a boron atom and a sulfur atom as ring-forming atoms.

In an embodiment, Formula 1 may be represented by Formula 1-B1 or Formula 1-B2. Formula 1-B1 represents Formula 1 where A₁ is a group represented by

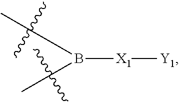

X₁ is represented by X₁₁, Y₁ is a substituted or unsubstituted phenyl group, and Y₁ is combined with adjacent R₁₁ to form a fused ring of seven rings. Formula 1-B2 represents Formula 1 where A₁ is a group represented by

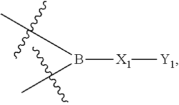

X₁ is represented by X₁₁, Y₁ is a substituted or unsubstituted phenyl group, and Y₁ is combined with adjacent R₁ to form a fused ring of seven rings.

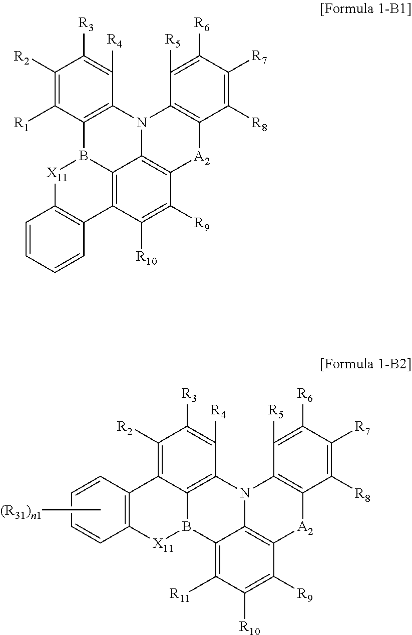

In Formula 1-B1 and Formula 1-B2, A₂ and R₁ to R₁₁ may be the same as defined in Formula 1. In Formula 1-B1 and Formula 1-B2, X₁₁ may be O, S, or SO. X₁₁ may include an oxygen atom or a sulfur atom.

In Formula 1-B1 and Formula 1-B2, n1 may be an integer from 0 to 4. If n1 is 2 or more, multiple R₃₁ groups may be the same, or at least one thereof may be different. In Formula 1-B1 and Formula 1-B2, R₃₁ may be a hydrogen atom, a deuterium atom, a substituted or unsubstituted alkyl group of 1 to 20 carbon atoms, or a substituted or unsubstituted aryl group of 6 to 30 ring-forming carbon atoms. For example, R₃₁ may be a substituted or unsubstituted t-butyl group, or an unsubstituted phenyl group. However, these are only examples, and embodiments are not limited thereto.

In an embodiment, Formula 1 may be represented by Formula 1-B11 or Formula 1-B21. Formula 1-B11 represents Formula 1 where A₁ and A₂ are each independently a group represented by

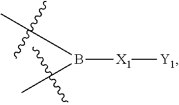

X₁ is represented by X₁₁ or X₁₂, Y₁ is a substituted or unsubstituted phenyl group, and Y₁ is combined with adjacent R₉ or R₁₁ to form a fused ring of nine rings. Formula 1-B11 may correspond to Formula 1-B1 where A₂ is a group represented by

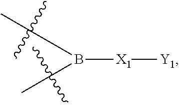

X₁ is represented by X₁₂, Y₁ is a substituted or unsubstituted phenyl group, and Y₁ is combined with adjacent R₉ to form a fused ring of nine rings.

Formula 1-B21 represents Formula 1 where A₁ and A₂ are each independently a group represented by

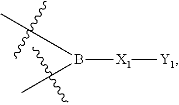

X₁ is represented by X₁₁ or X₁₂, Y₁ is a substituted or unsubstituted phenyl group, and Y₁ is combined with adjacent R₁ or R₈ to form a fused ring of nine rings. Formula 1-B21 may correspond to Formula 1-B2 where A₂ is a group represented by

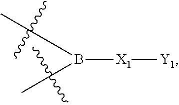

X₁ is represented by X₁₂, Y₁ is a substituted or unsubstituted phenyl group, and Y₁ is combined with adjacent R₈ to form a fused ring of nine rings.

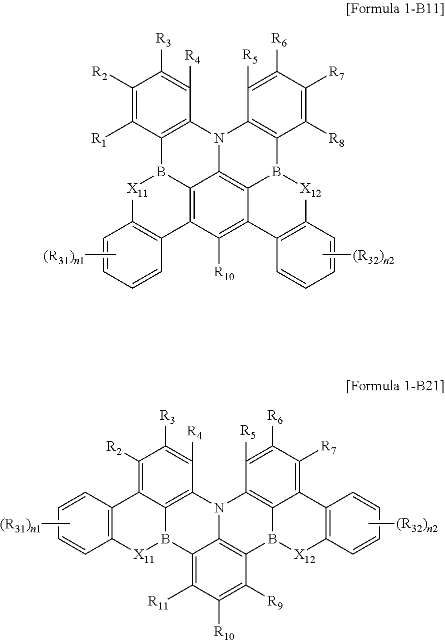

In Formula 1-n11 and Formula 1-B21, R₁ to R₁₁ may be the same as defined in Formula 1.

In Formula 1-B11 and Formula 1-B21, X₁₁ and X₁₂ may each independently be O or S. In Formula 1-B11 and Formula 1-B21, the fused ring of nine rings may include an oxygen atom or a sulfur atom as a ring-forming atom.

In Formula 1-B11 and Formula 1-B21, n1 and n2 may each independently be an integer from 0 to 4. If n1 is 2 or more, multiple R₃₁ groups may be the same, or at least one thereof may be different. If n2 is 2 or more, multiple R₃₂ groups may be the same, or at least one thereof may be different.

In Formula 1-B11 and Formula 1-B21, R₃₁ and R₃₂ may each independently be a hydrogen atom, a deuterium atom, or a substituted or unsubstituted alkyl group or 1 to 20 carbon atoms. For example, in Formula 1-B11 and Formula 1-B21, R₃₁ and R₃₂ may be the same.

In Formula 1, each of A₁ and A₂ may include a boron atom. In an embodiment, Formula 1 may be represented by Formula 1-C. Formula 1-C represents a case where A₁ is a group represented by

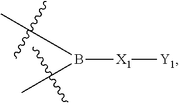

Y₁ is represented by R₂₉, and A₂ is B(R₂₃).

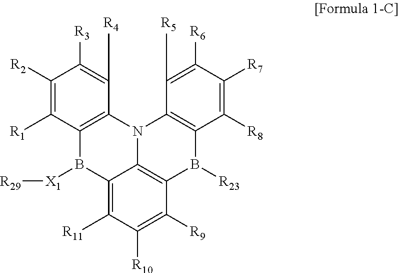

In Formula 1-C, R₁ to R₁₁, R₂₃, R₂₉, and X₁ may be the same as defined in Formula 1.

For example, in Formula 1-C, R₂₃ may be a substituted or unsubstituted methoxy group, a substituted or unsubstituted isopropoxy group, a substituted or unsubstituted methylthio group, a substituted or unsubstituted isopropylthio group, a substituted or unsubstituted phenoxy group, a substituted or unsubstituted phenyl group, or a substituted or unsubstituted phenylthio group. If R₂₃ is a substituted phenyl group, the substituted phenyl group may be a phenyl group substituted with a methyl group, an isopropyl group, or a phenyl group. However, these are only examples, and embodiments are not limited thereto.

The polycyclic compound of an embodiment may include a deuterium atom as a substituent, or may include a substituent substituted with a deuterium atom. In an embodiment, Formula 1 may be represented by any one of Formula 1-E1 to Formula 1-E3. The polycyclic compound of an embodiment represented by Formula 1-E1 to Formula 1-E3 may include at least one deuterium atom.

Formula 1-E1 corresponds to Formula 1 where A₁ is a group represented by

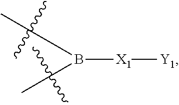

A₂ is B(R₂₃), and R₂₃ is a substituted or unsubstituted phenyl group. Formula 1-E1 may correspond to Formula 1 where R₁ to R₁₁ are deuterium atoms. Formula 1-E1 may correspond to Formula 1-C where R₂₃ is a substituted or unsubstituted phenyl group, and R₁ to R₁₁ are deuterium atoms.

Formula 1-E2 corresponds to Formula 1 where A₁ and A₂ are each independently a group represented by

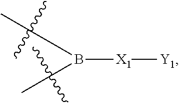

X₁ is represented by X₂₁ or X₂₂, Y₁ is a substituted or unsubstituted phenyl group, Y₁ is combined with adjacent R₉ or R₁₁ to form a fused ring of nine rings, and R₁, R₃ to R₆, R₈, and R₁₀ are deuterium atoms. Formula 1-E2 may correspond to Formula 1-B11 where R₁, R₃ to R₆, R₈, and R₁₀ are deuterium atoms. Formula 1-E2 may correspond to Formula 1-B11 where three R₃₁ groups among four R₃₁ groups, and three R₃₂ groups among four R₃₂ groups are deuterium atoms.

Formula 1-E3 corresponds to Formula 1 where A₁ and A₂ are each independently a group represented by

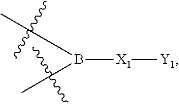

is represented by X₂₁ or X₂₂, Y₁ is a substituted or unsubstituted phenyl group, Y₁ is combined with adjacent R₁ or R₈ to form a fused ring of nine rings, and R₃ to R₆ are deuterium atoms. Formula 1-E3 may correspond to Formula 1-B21 where R₂ to R₇, multiple R₃₁ groups, and multiple R₃₂ groups are deuterium atoms.

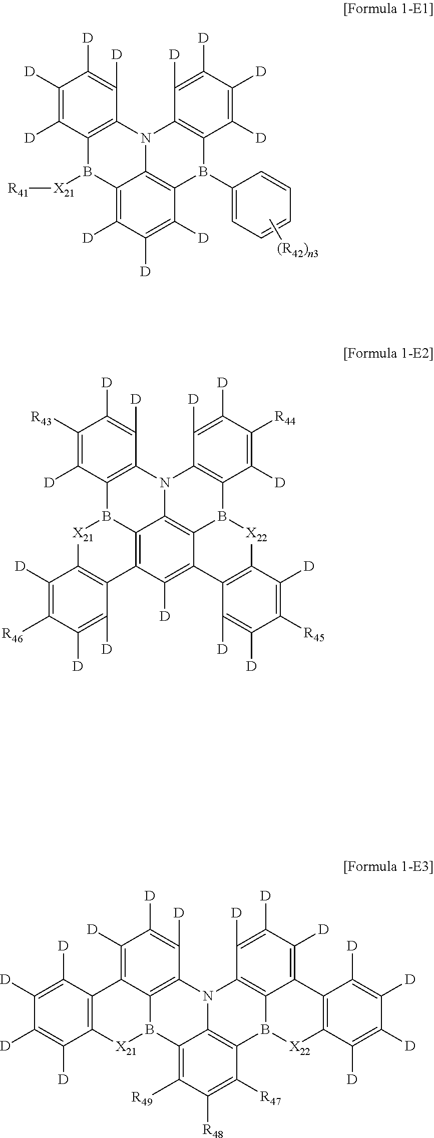

In Formula 1-E1, n3 may be an integer from 0 to 5. In Formula 1-E1, if n3 is 2 or more, multiple R₄₂ groups may be the same, or at least one thereof may be different. In Formula 1-E1, X₂₁ may be O or S. In Formula 1-E1, R₄₁ and R₄₂ may each independently be a hydrogen atom, a deuterium atom, a methyl group substituted with a deuterium atom, an isopropyl group substituted with a deuterium atom, a t-butyl group substituted with a deuterium atom, or a phenyl group substituted with a deuterium atom.

In Formula 1-E2 and Formula 1-E3, X₂₁ and X₂₂ may each independently be O or S. In Formula 1-E2 and Formula 1-E3, R₄₃ to R₄₉ may be each independently a hydrogen atom, a deuterium atom, a methyl group substituted with a deuterium atom, an isopropyl group substituted with a deuterium atom, a t-butyl group substituted with a deuterium atom, or a phenyl group substituted with a deuterium atom.

The polycyclic compound of an embodiment may include a fused ring of five rings, including a nitrogen atom and a boron atom as ring-forming atoms. An oxygen atom or a sulfur atom may be bonded the boron atom which is the ring-forming atom. The polycyclic compound of an embodiment may include a fused ring structure represented by Formula Z-1 or Formula Z-2.

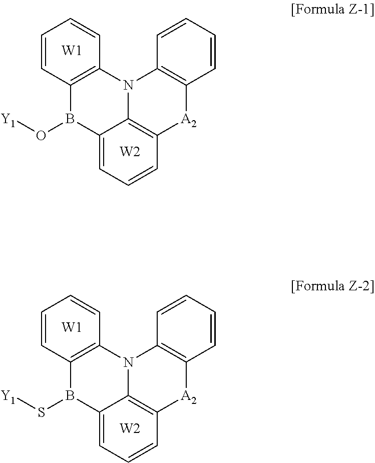

Formula Z-1 and Formula Z-2 represent cases of a fused ring structure of five rings, including a nitrogen atom and a boron atom as ring-forming atoms, where an oxygen atom or a sulfur atom is bonded to the boron atom. In Formula Z-1 and Formula Z-2, A₂ and Y₁ may be the same as defined in Formula 1. In Formula Z-1 and Formula Z-2, each of W1 and W2 may represent a benzene ring.

The polycyclic compound of an embodiment may include an oxygen atom directly bonded to a boron atom, or a sulfur atom directly bonded to a boron atom. Y₁ bonded to the oxygen atom directly bonded to the boron atom may be combined with adjacent ring W1 or ring W2 to form a fused ring. Y₁ bonded to the sulfur atom directly bonded to the boron atom may be combined with adjacent ring W1 or ring W2 to form a fused ring.

The polycyclic compound of an embodiment may include an oxygen atom directly bonded to a boron atom which is a ring-forming atom, or a sulfur atom directly bonded to a boron atom which is a ring-forming atom, and the stability of the compound may be improved. The unshared electron pair of the oxygen atom directly bonded to a boron atom or the unshared electron pair of the sulfur atom directly bonded to a boron atom may contribute to the stabilization of the polycyclic compound. The unshared electron pair of the oxygen atom or the unshared electron pair of the sulfur atom may stabilize the multi resonance of a fused ring composed of five rings to improve the stability of the polycyclic compound. Accordingly, the polycyclic compound of an embodiment, of which stability is improved, may contribute to the improvement of the efficiency and life of a light emitting device.

The polycyclic compound of an embodiment may be any one selected from Compound Group 1. The light emitting device ED of an embodiment may include at least one polycyclic compound selected from Compound Group 1 in an emission layer EML.

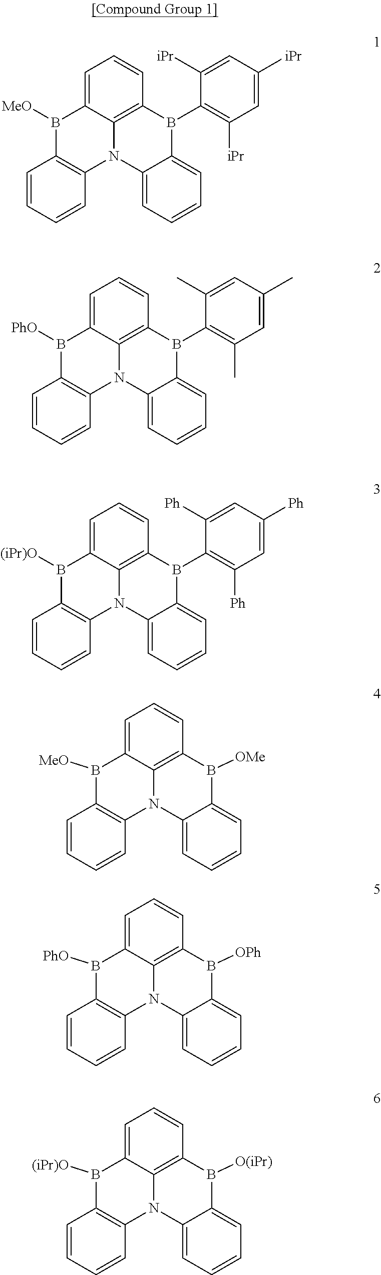

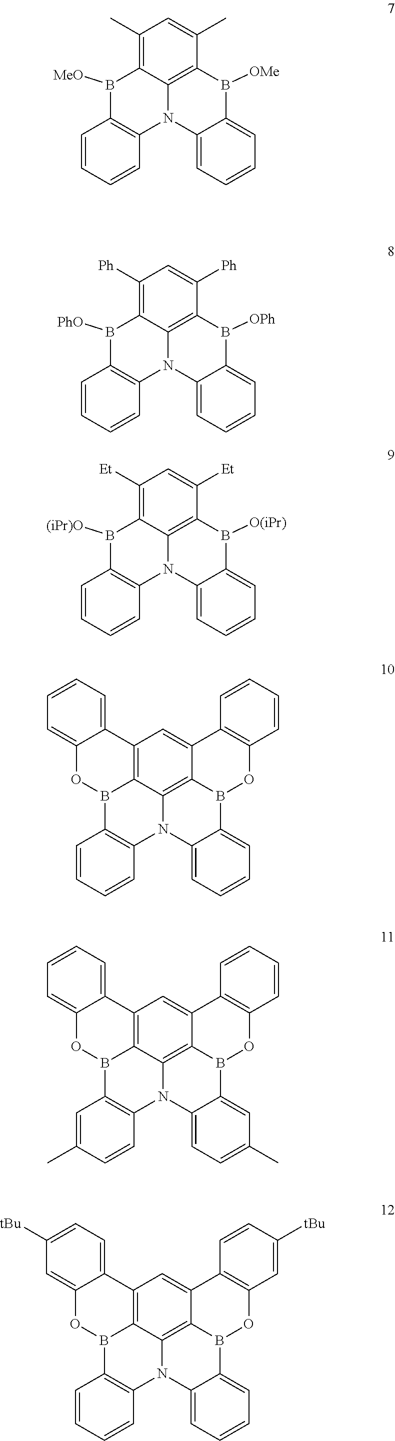

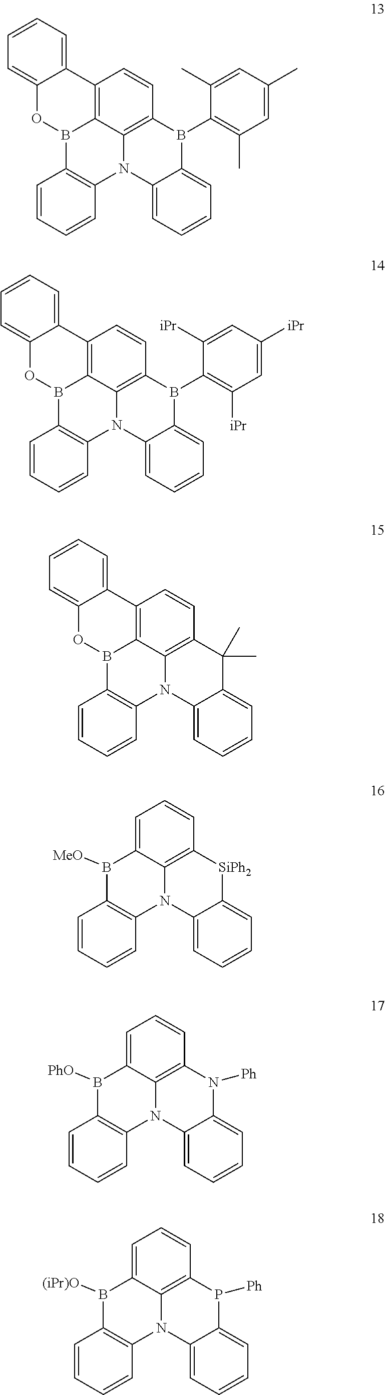

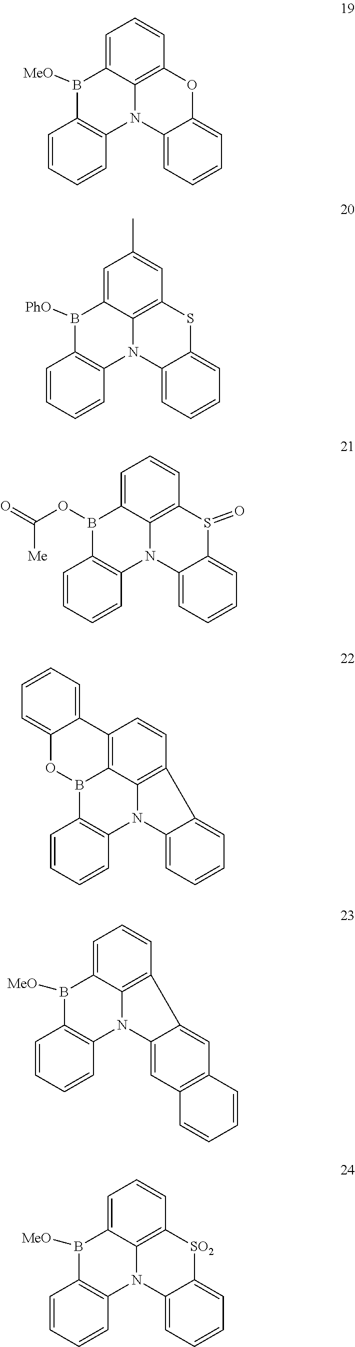 [SMILES: COB1c2ccccc2N2c3ccccc3Oc3cccc1c32 ; Cc1cc2c3c(c1)B(Oc1ccccc1)c1ccccc1N3c1ccccc1S2 ; CC(=O)OB1c2ccccc2N2c3ccccc3S(=O)c3cccc1c32 ; c1ccc2c(c1)OB1c3ccccc3-n3c4ccccc4c4ccc-2c1c43 ; COB1c2ccccc2-n2c3cc4ccccc4cc3c3cccc1c32 ; COB1c2ccccc2N2c3ccccc3S(=O)(=O)c3cccc1c32]

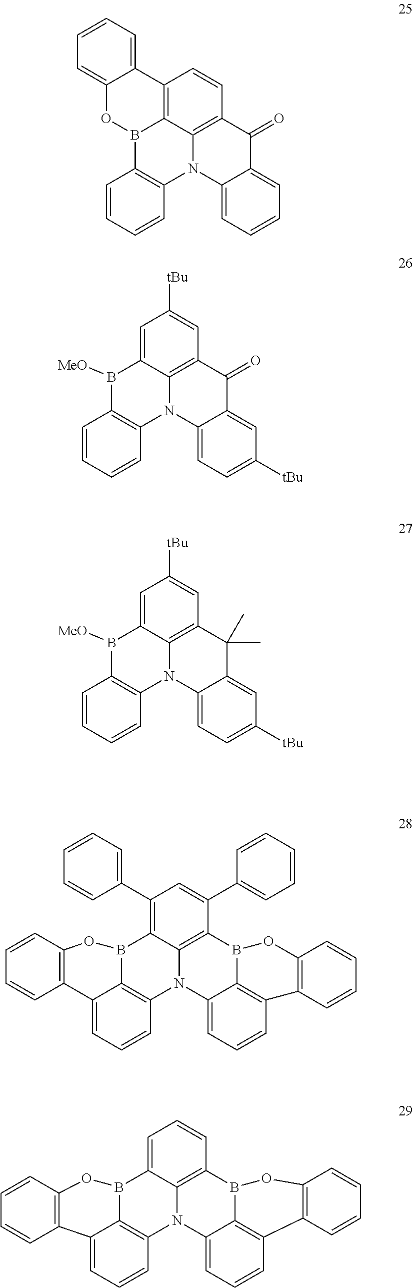 [SMILES: O=c1c2ccccc2n2c3c4c(ccc13)-c1ccccc1OB4c1ccccc1-2 ; COB1c2ccccc2-n2c3ccc(C(C)(C)C)cc3c(=O)c3cc(C(C)(C)C)cc1c32 ; COB1c2ccccc2N2c3ccc(C(C)(C)C)cc3C(C)(C)c3cc(C(C)(C)C)cc1c32 ; c1ccc(-c2cc(-c3ccccc3)c3c4c2B2Oc5ccccc5-c5cccc(c52)N4c2cccc4c2B3Oc2ccccc2-4)cc1 ; c1ccc2c(c1)OB1c3cccc4c3N(c3cccc-2c31)c1cccc2c1B4Oc1ccccc1-2]

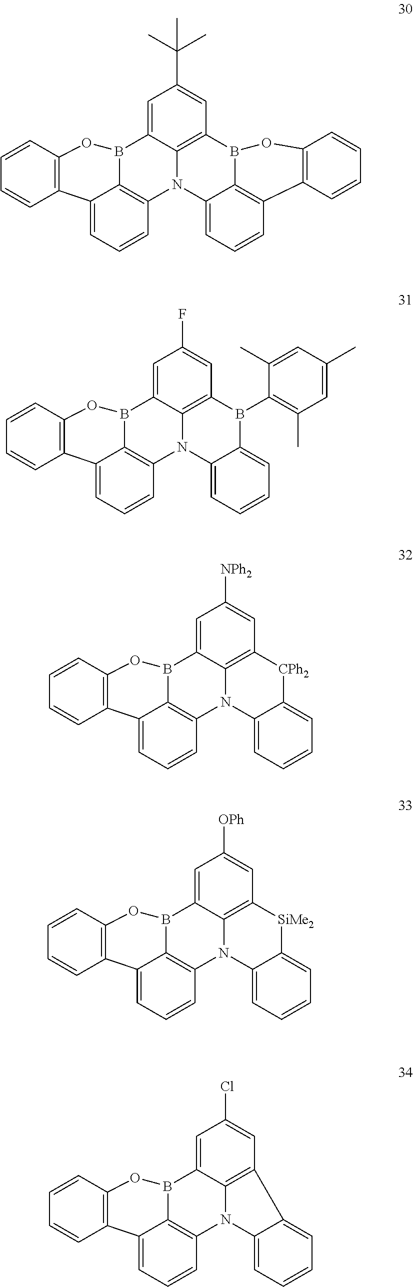

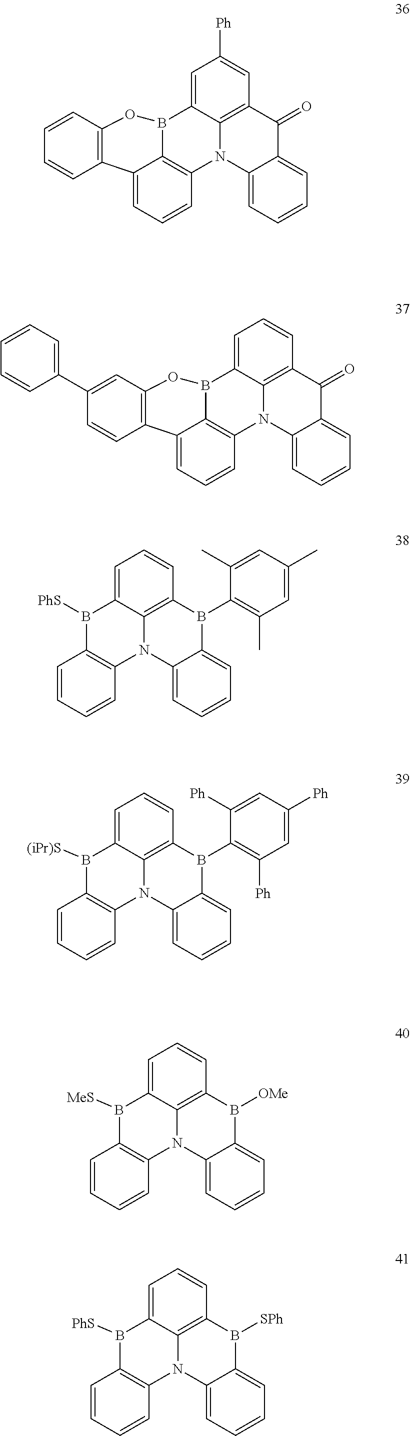

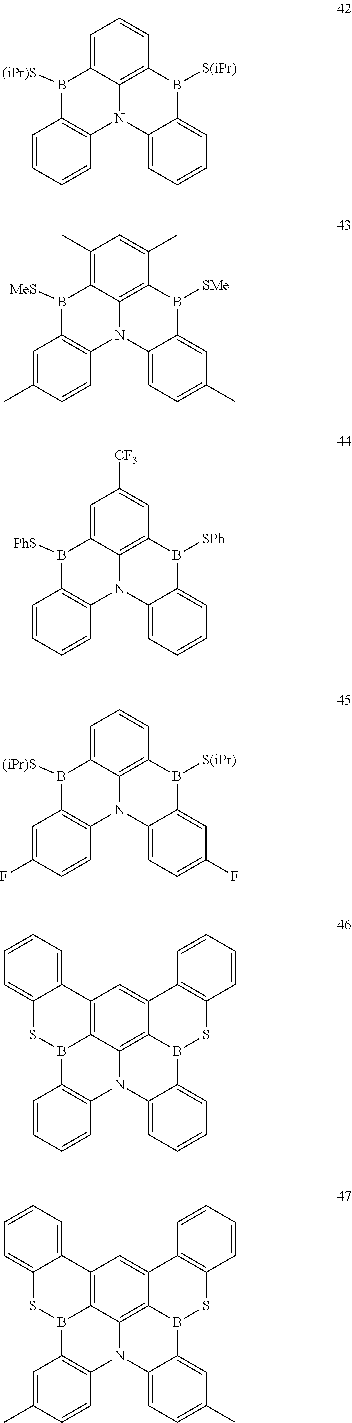

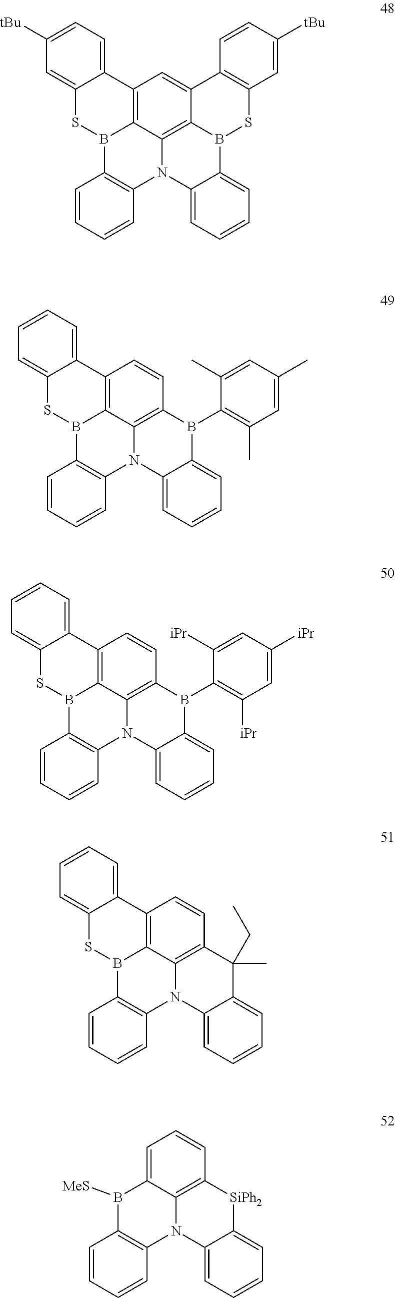

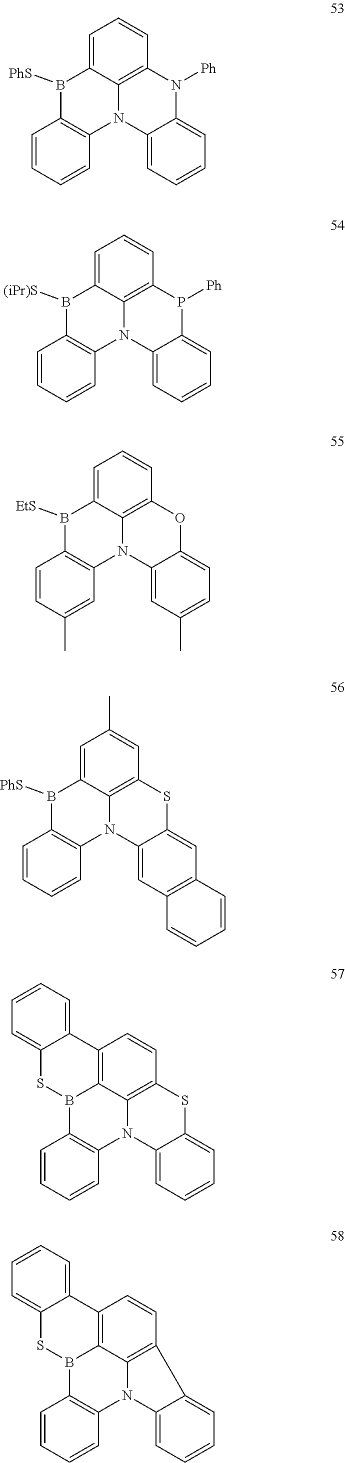

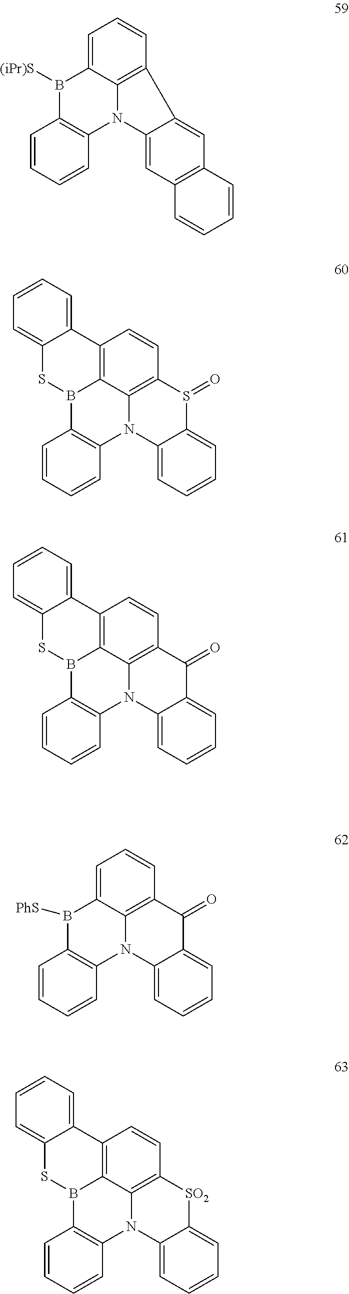

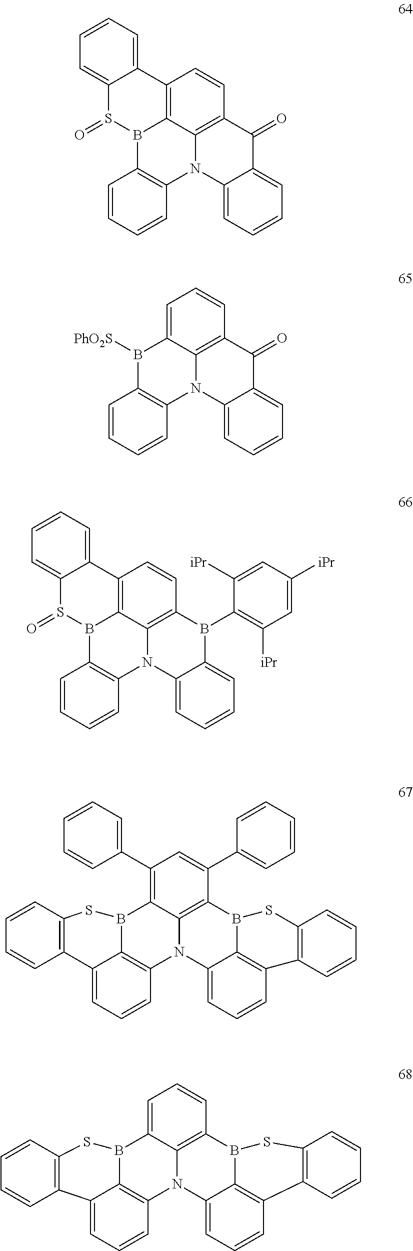

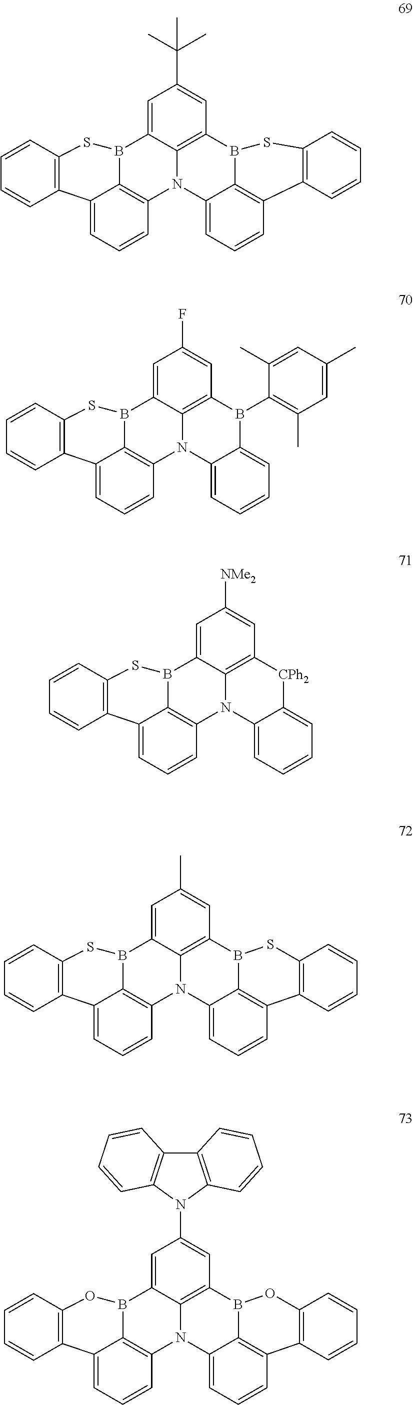

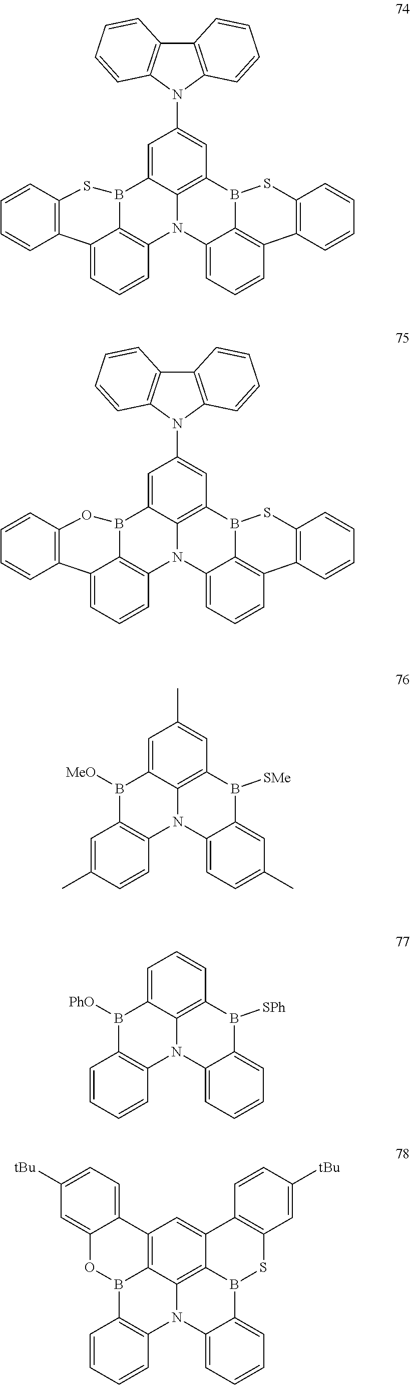

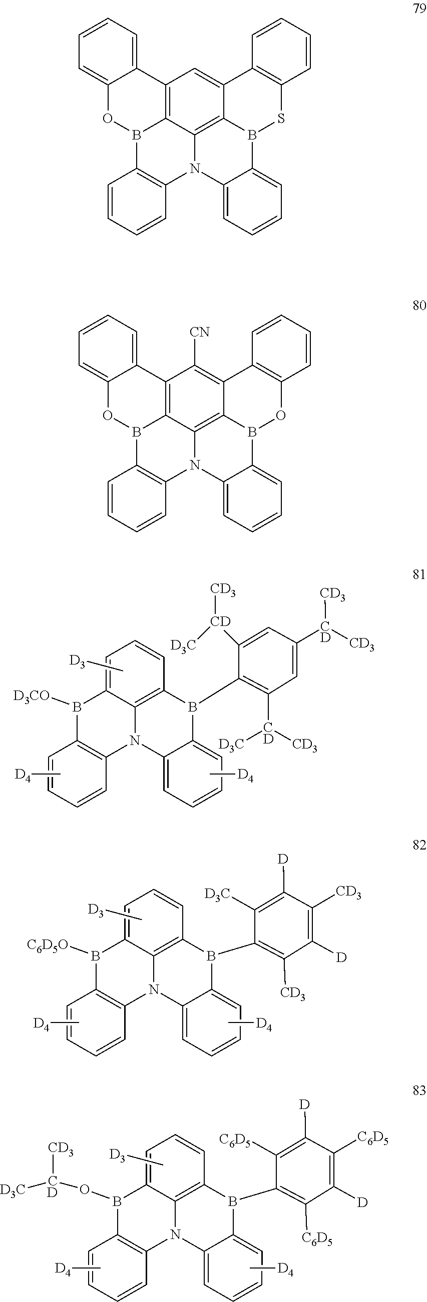

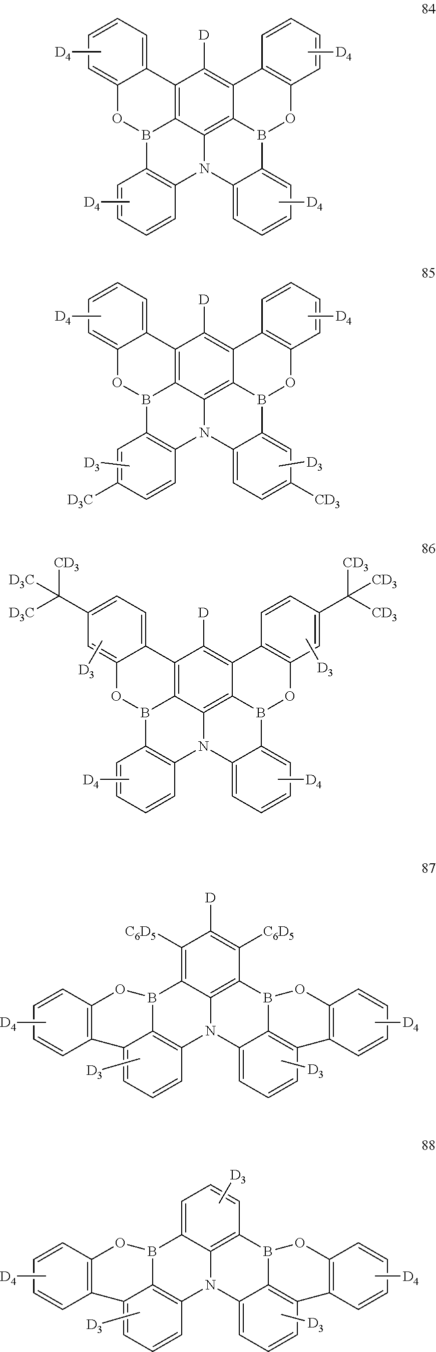

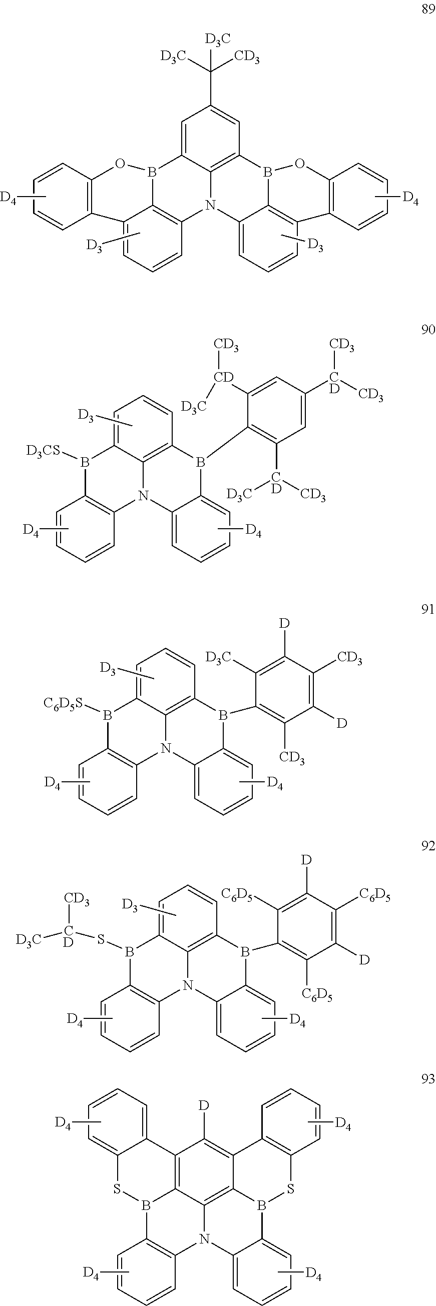

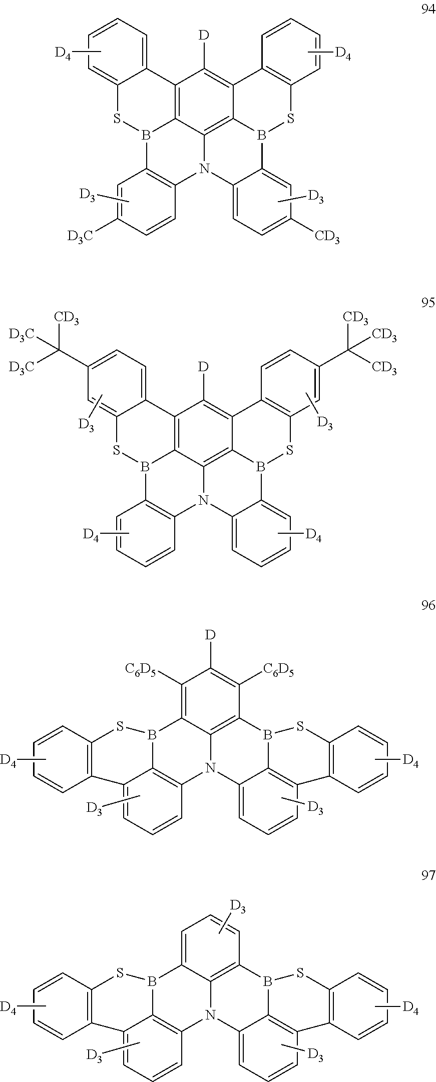

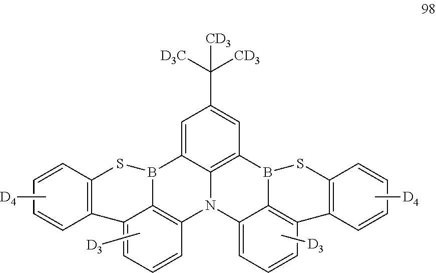

In Compound Group 1, Me is a methyl group, Et is an ethyl group, iPr is an isopropyl group, tBu is a t-butyl group, Ph is a phenyl group, and D is a deuterium atom.

The polycyclic compound of an embodiment may emit blue light. The polycyclic compound of an embodiment may be a thermally activated delayed fluorescence emitting material. The polycyclic compound of an embodiment represented by Formula 1 may be a blue thermally activated delayed fluorescence dopant.

In the light emitting device ED of an embodiment, the emission layer EML may emit delayed fluorescence. For example, the emission layer EML may emit thermally activated delayed fluorescence (TADF).

In an embodiment, the emission layer EML may include a host and a dopant, and the dopant may include a polycyclic compound of an embodiment. For example, in the light emitting device ED of an embodiment, the emission layer EML may include a host for emitting delayed fluorescence and a dopant for emitting delayed fluorescence, and the polycyclic compound of an embodiment may be included as a dopant for emitting delayed fluorescence. The emission layer EML may include at least one polycyclic compound selected from Compound Group 1 as a thermally activated delayed fluorescence dopant.

In an embodiment, the emission layer EML may be a delayed fluorescence emission layer, and the emission layer EML may include a host material and the polycyclic compound of an embodiment. For example, in an embodiment, the polycyclic compound may be used as a TADF dopant.

The emission layer EML may have a thickness in a range of about 100 Å to about 1,000 Å. For example, the emission layer EML may have a thickness in a range of about 100 Å to about 300 Å. The emission layer EML may be a layer formed of a single material, a layer formed of different materials, or a multilayer structure having layers formed of different materials.

In the light emitting device ED of an embodiment, the emission layer EML may include anthracene derivatives, pyrene derivatives, fluoranthene derivatives, chrysene derivatives, dihydrobenzanthracene derivatives, or triphenylene derivatives. For examples, the emission layer EML may include anthracene derivatives or pyrene derivatives.

In the light emitting devices ED of embodiments, shown in FIG. 3 to FIG. 6, the emission layer EML may include a host and a dopant, and the emission layer EML may include a compound represented by Formula E-1. The compound represented by Formula E-1 may be used as a fluorescence host material.

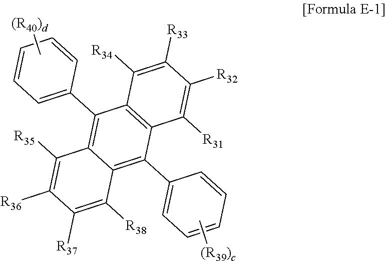

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula E-1, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any one selected from Compound E1 to Compound E19.

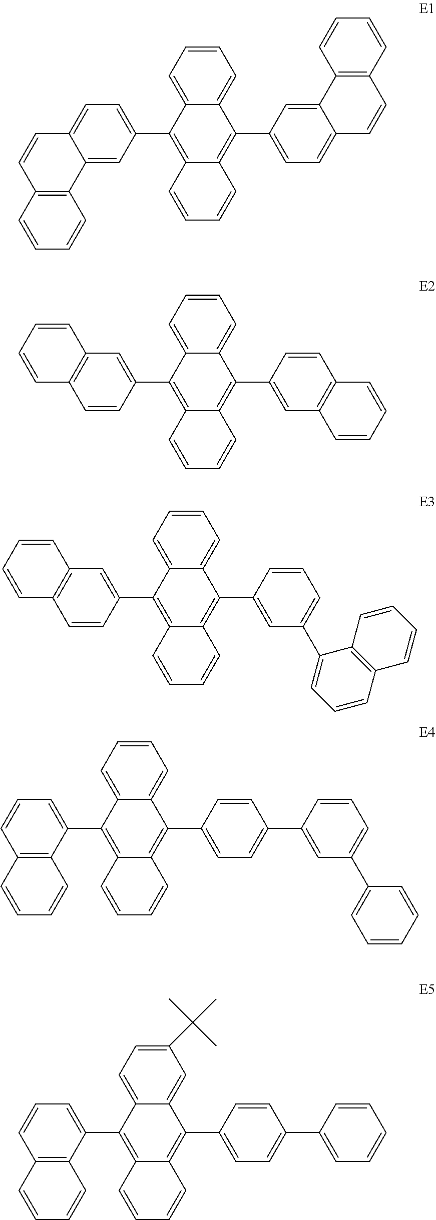

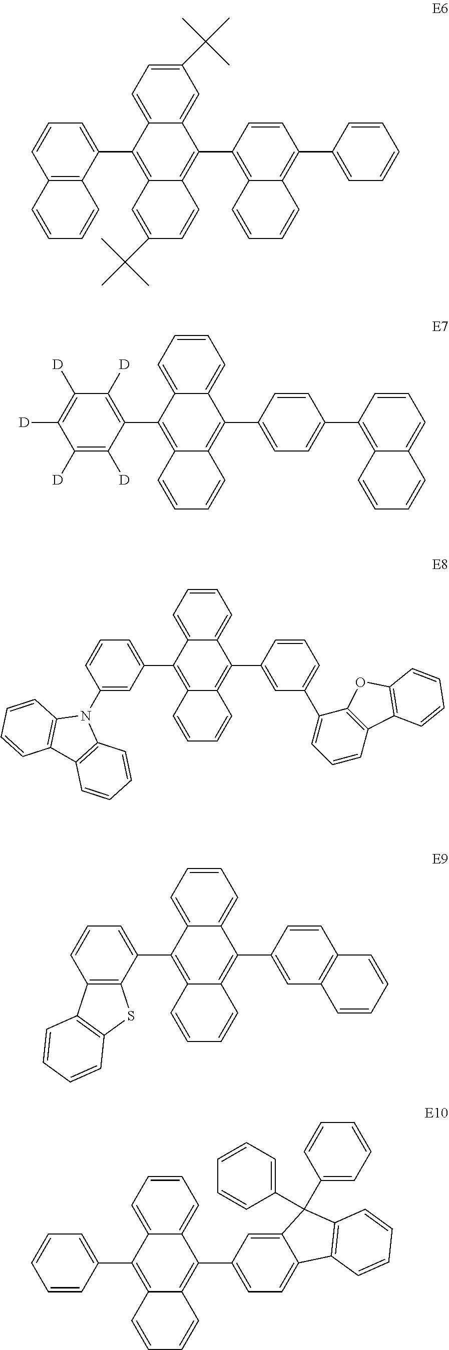

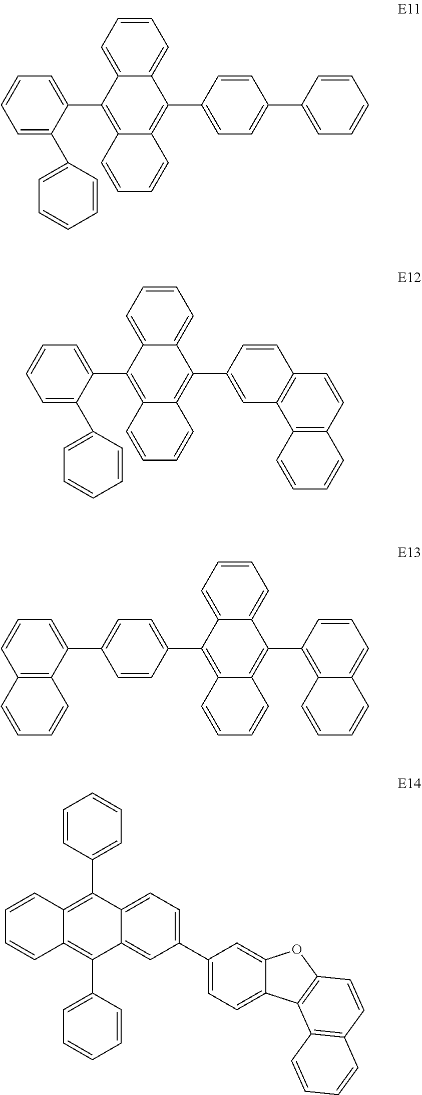

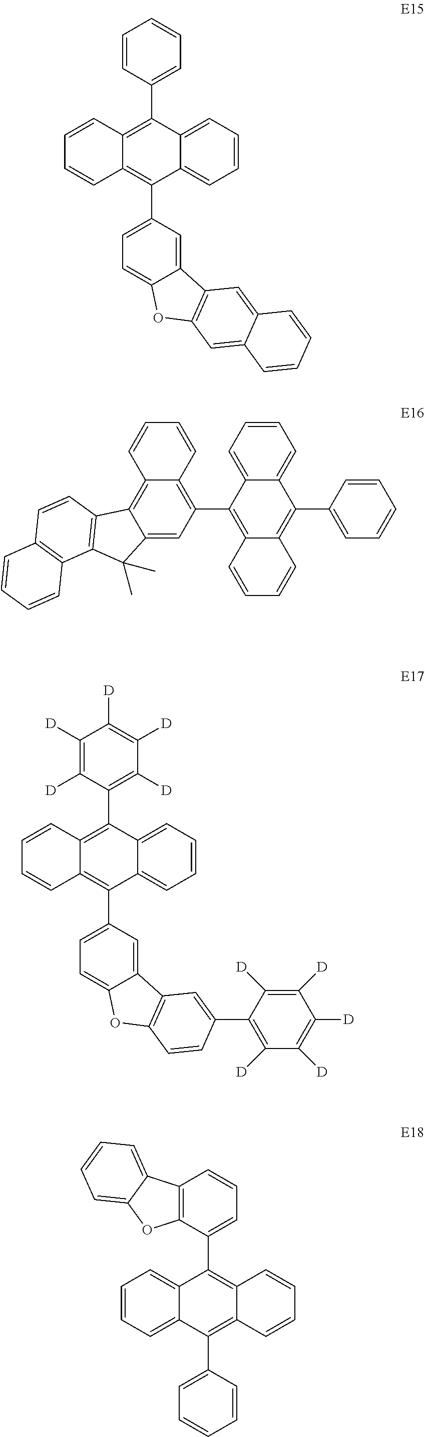

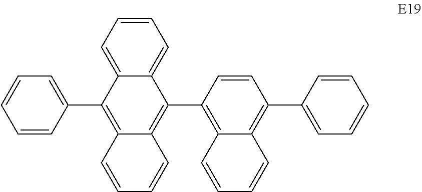 [SMILES: c1ccc(-c2ccc(-c3c4ccccc4c(-c4ccccc4)c4ccccc34)c3ccccc23)cc1]

In an embodiment, the emission layer EML may include a compound represented by Formula E-2a or Formula E-2b. The compound represented by Formula E-2a or Formula E-2b may be used as a phosphorescence host material.

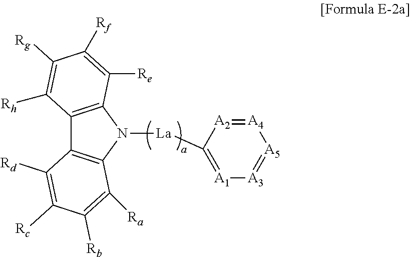

In Formula E-2b, a may be an integer from 0 to 10, and Lₐ may be a direct linkage, a substituted or unsubstituted arylene group of 6 to 30 ring-forming carbon atoms, or a substituted or unsubstituted heteroarylene group of 2 to 30 ring-forming carbon atoms. In a is 2 or more, multiple Lₐ groups may each independently be a substituted or unsubstituted arylene group of 6 to 30 ring-forming carbon atoms, or a substituted or unsubstituted heteroarylene group of 2 to 30 ring-forming carbon atoms.

In Formula E-2a, A₁ to A₅ may each independently be N or C(Rᵢ). Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, etc. as a ring-forming atom.

In Formula E-2a, two or three of A₁ to A₅ may be N, and the remainder of A₁ to A₅ may be C(Rᵢ).

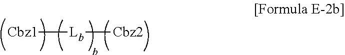

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10, and if b is 2 or more, multiple L_{b} groups may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be any one selected from Compound Group E-2. However, the compounds shown in Compound Group E-2 are only examples, and the compound represented by Formula E-2a or Formula E-2b is not limited to Compound Group E-2.

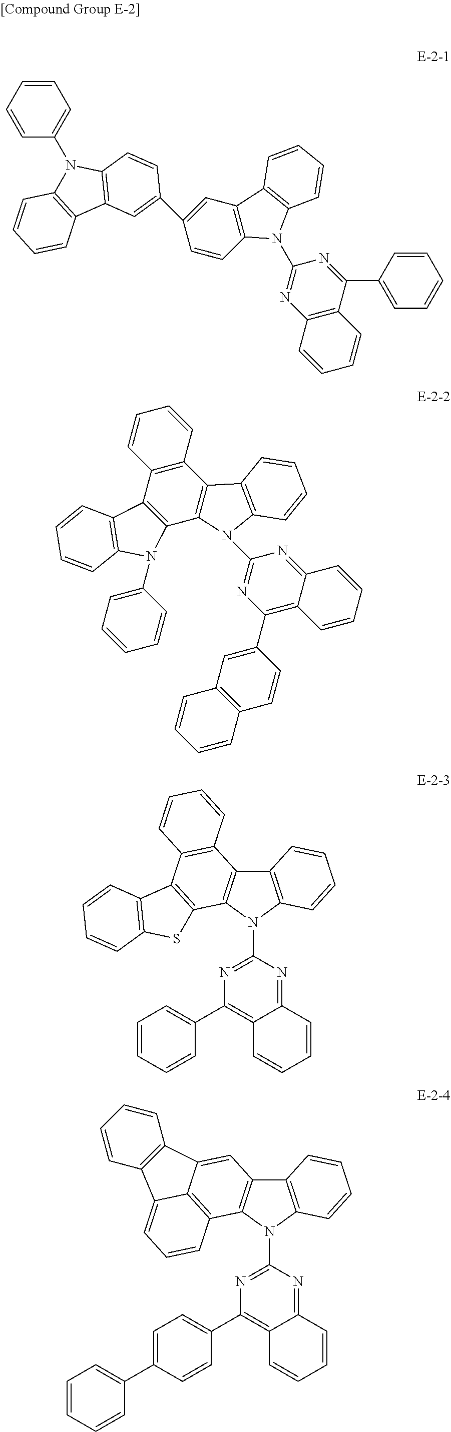

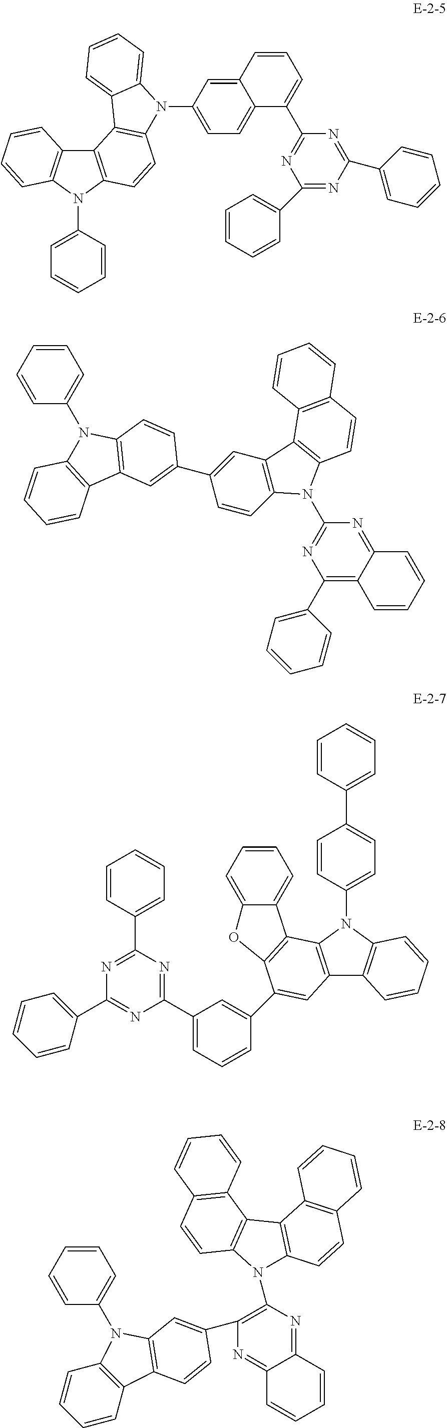 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

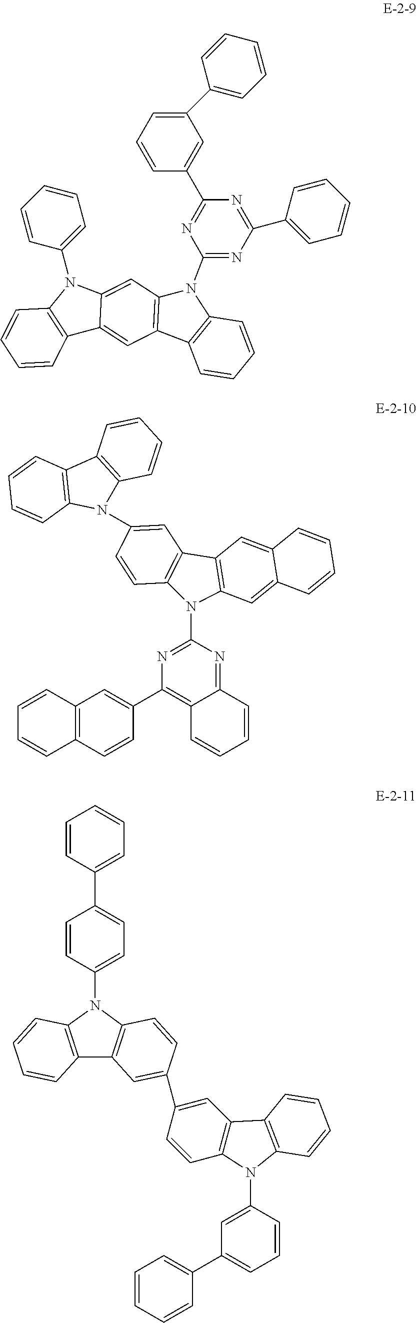 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

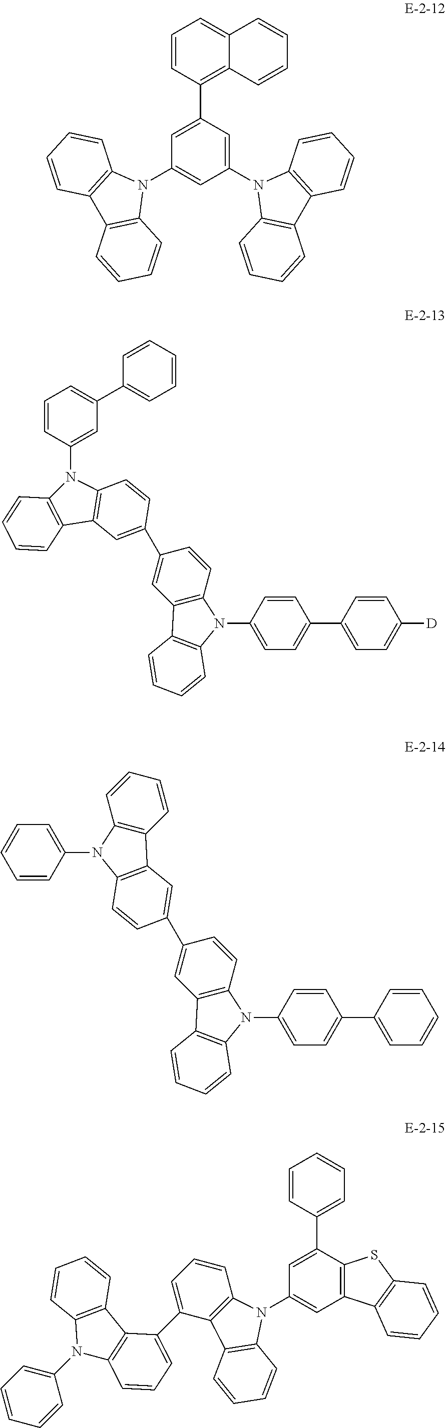 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

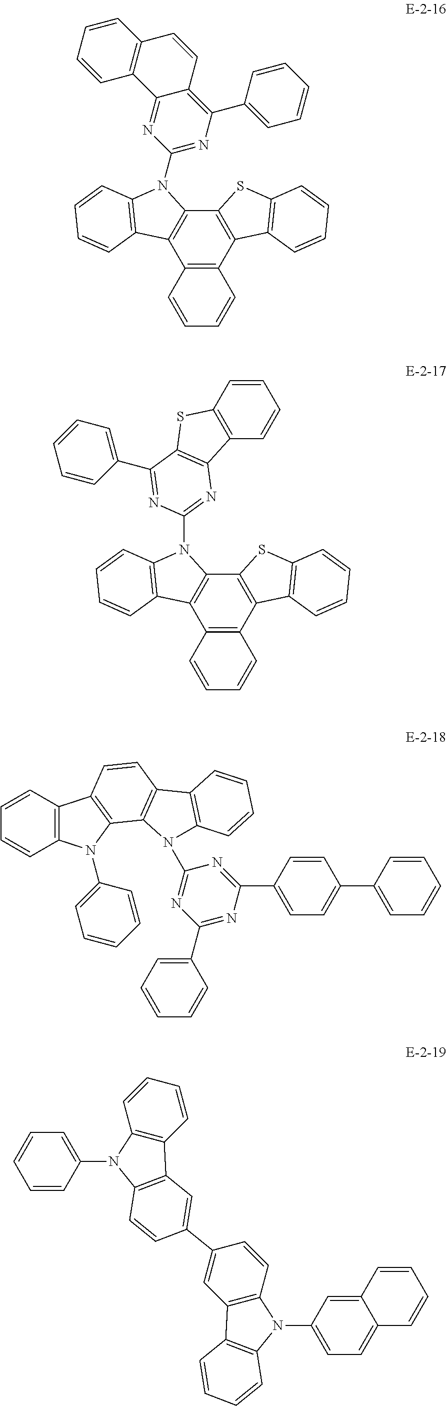 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

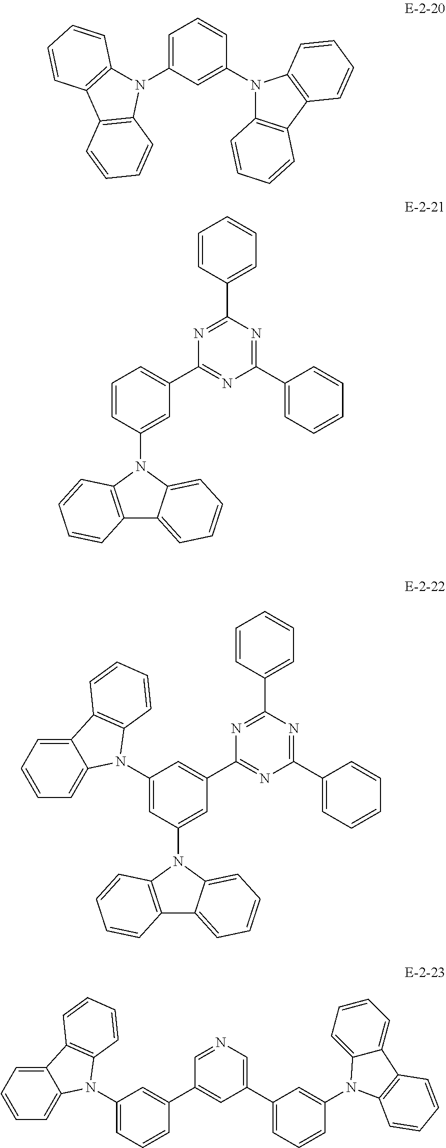

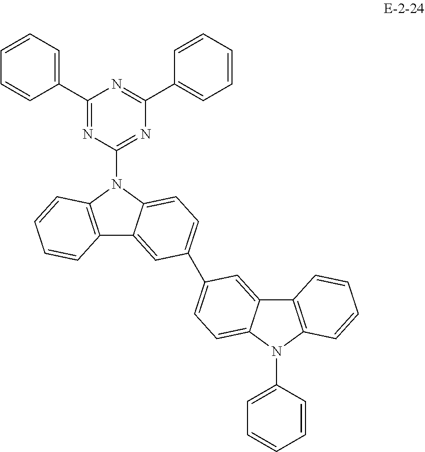 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a common material of the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(carbazol-9-yl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

The emission layer EML may include a compound represented by Formula M-a or Formula M-b. The compound represented by Formula M-a or Formula M-b may be used as a phosphorescence dopant material.

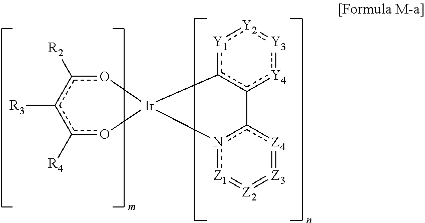

In Formula M-a, Y₁ to Y₄ and Z₁ to Z₄ may each independently be C(R₁) or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, m may be 0 or 1, and n may be 2 or 3. In Formula M-a, if m is 0, n may be 3, and if m is 1, n may be 2.

The compound represented by Formula M-a may be used as a phosphorescence dopant. The compound represented by Formula M-a may be any one selected from Compounds M-a1 to M-a25. However, Compounds M-a1 to M-a25 below are only examples, and the compound represented by Formula M-a is not limited to Compounds M-a1 to M-a25.

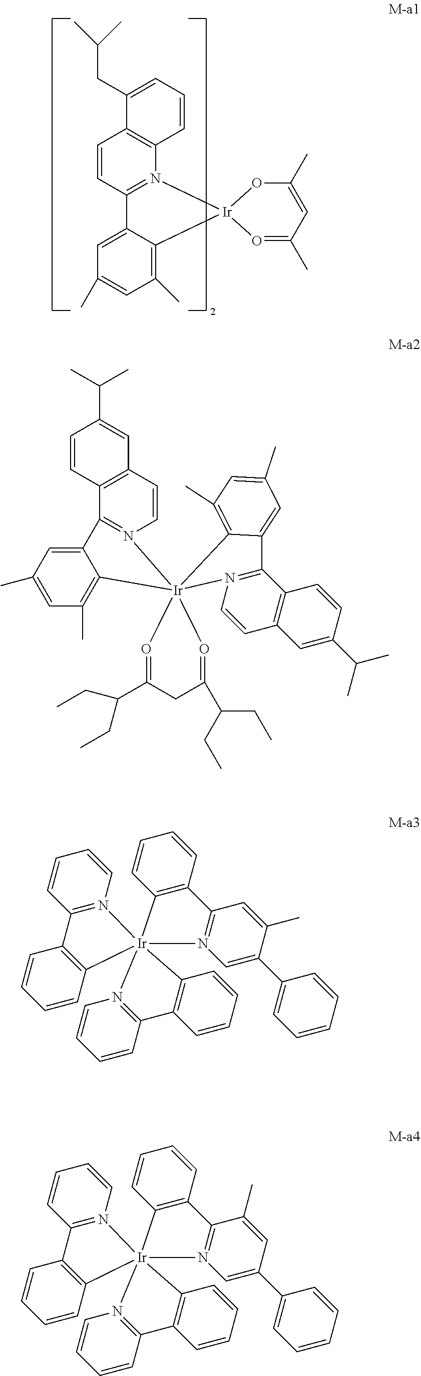

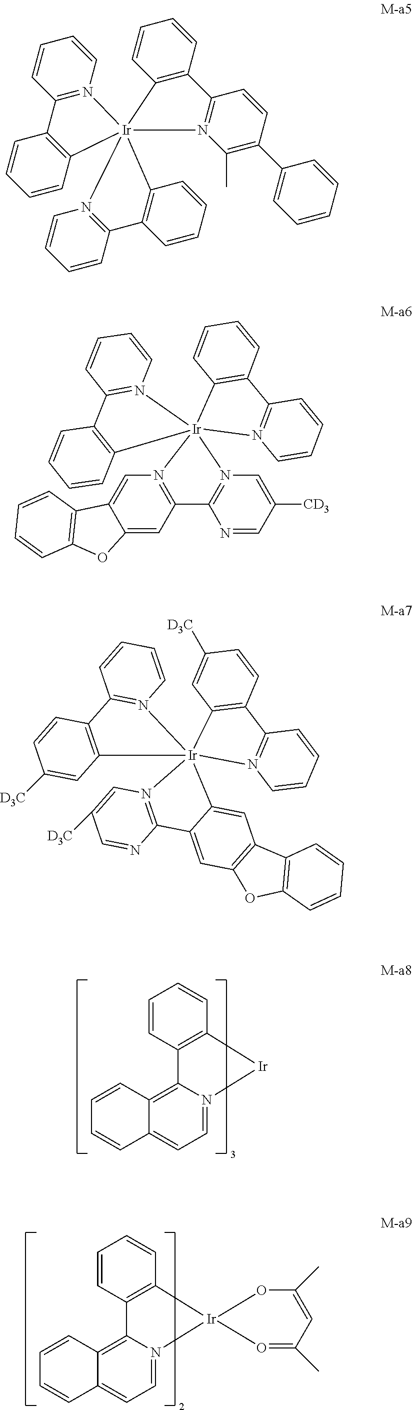

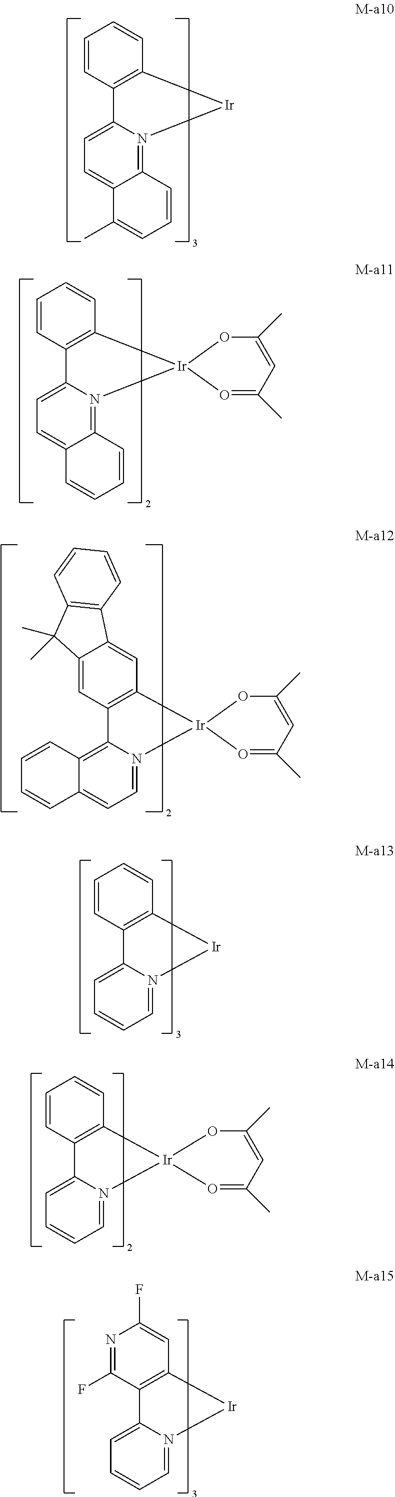

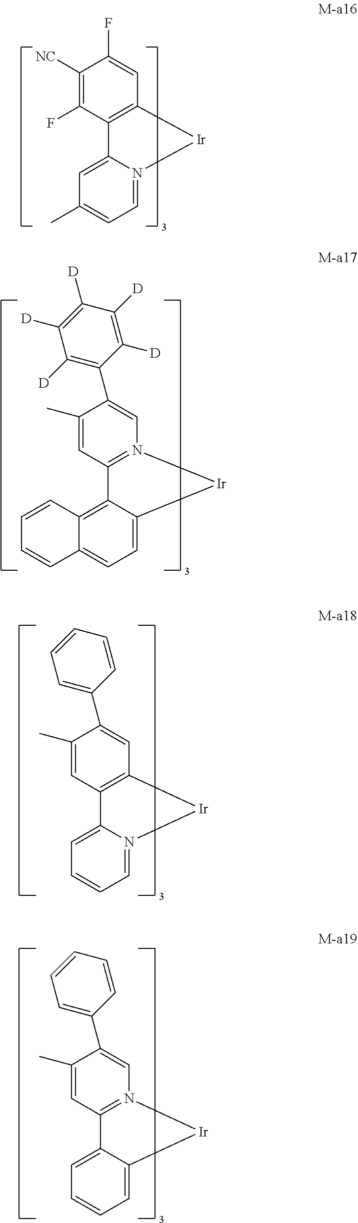

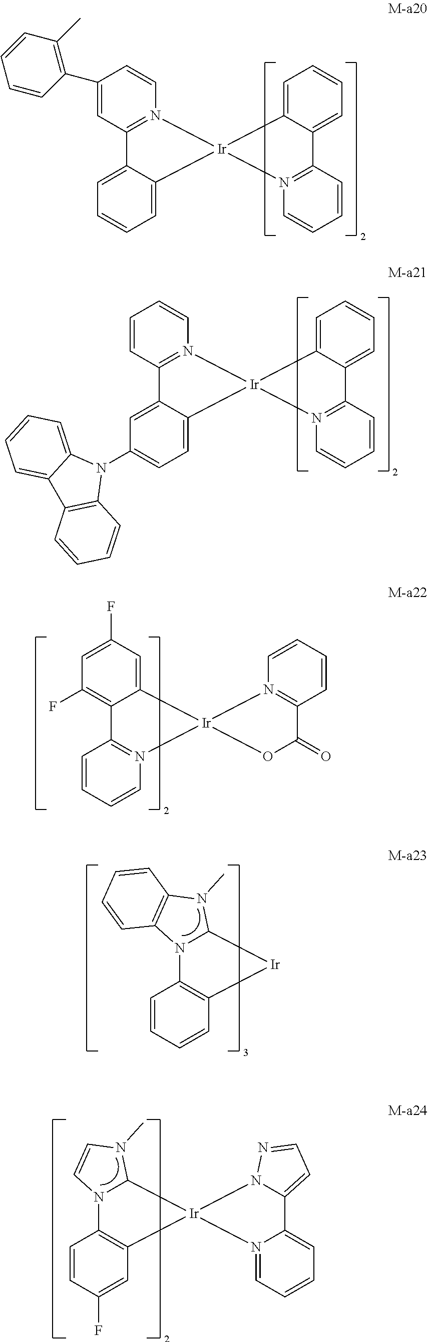

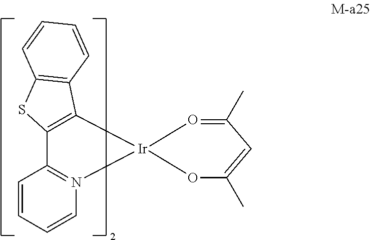

Compound M-a1 and Compound M-a2 may be used as red dopant materials, and Compound M-a3 to Compound M-a7 may be used as green dopant materials.

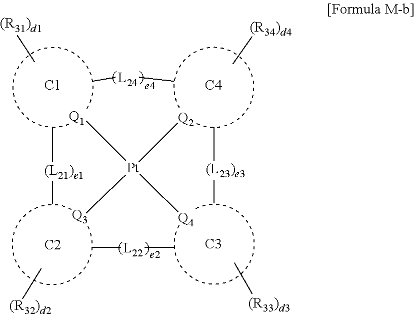

In Formula M-b, Q to Q may each independently be C or N, and C1 to C4 may each independently be a substituted or unsubstituted hydrocarbon ring of 5 to 30 ring-forming carbon atoms, or a substituted or unsubstituted heterocycle of 2 to 30 ring-forming carbon atoms. In Formula M-b, L₂₁ to L₂₄ may each independently be a direct linkage,

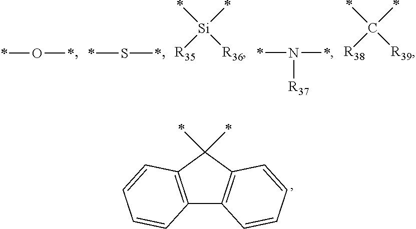

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, and e1 to e4 may each independently be 0 or 1. In Formula M-b, R₃₁ to R₃₉ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring, and d1 to d4 may each independently be an integer from 0 to 4.

The compound represented by Formula M-b may be used as a blue phosphorescence dopant or a green phosphorescence dopant.

The compound represented by Formula M-b may be any one selected from Compound M-b-1 to Compound M-b-11. However, Compound M-b-1 to Compound M-b-11 are only examples, and the compound represented by Formula M-b is not limited to Compound M-b-1 to Compound M-b-11.

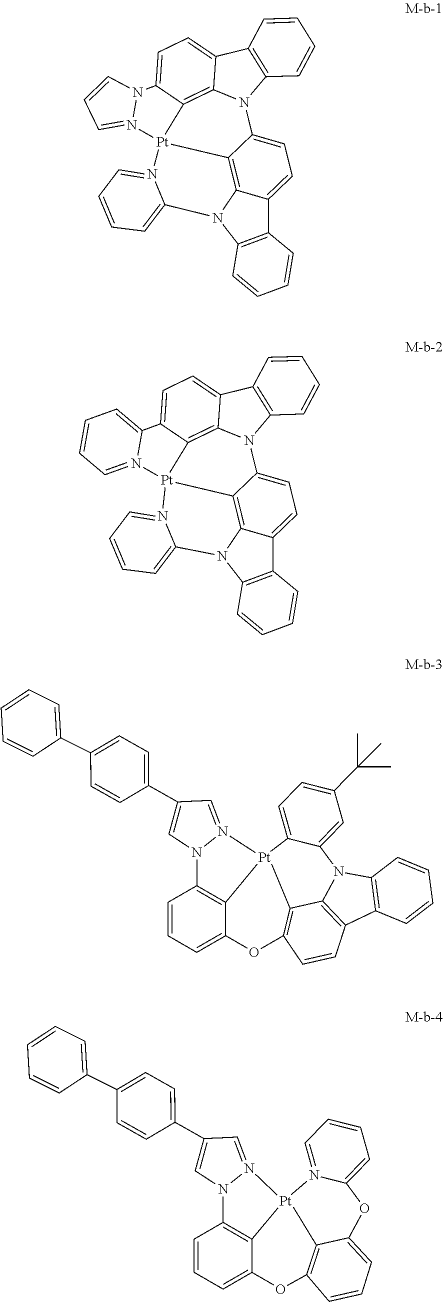

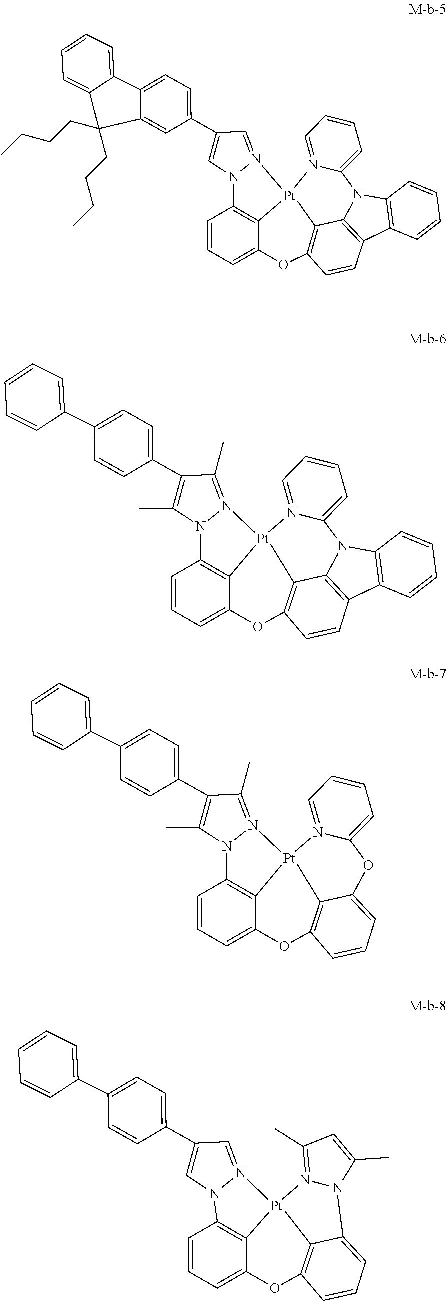

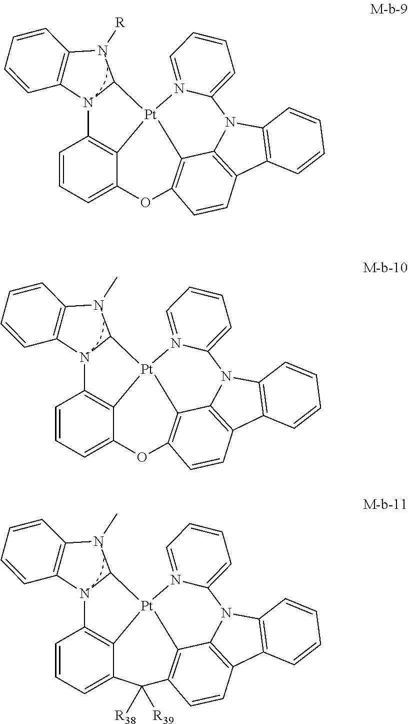

In Compound M-b-1 to Compound M-b-11, R, R₃₈, and R₃₉ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

The emission layer EML may include a compound represented by any one of Formula F-a to Formula F-c. The compounds represented by Formula F-a to Formula F-c may be used as fluorescence dopant materials.

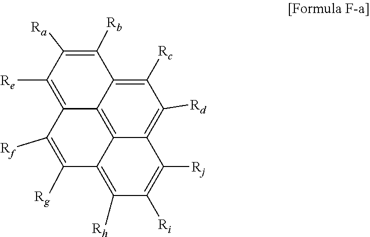

In Formula F-a, two selected from Rₐ to Rⱼ may each independently be substituted with a group represented by *—NAr₁Ar₂. The remainder of Rₐ to Rⱼ not substituted with the group represented by *—NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by *—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one of Ar₁ and Ar₂ may be a heteroaryl group including O or S as a ring-forming atom.

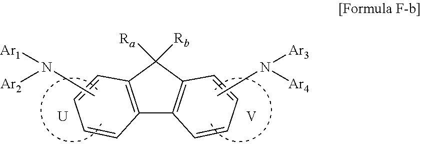

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula F-b, Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may each independently be 0 or 1. For example, in Formula F-b, if the number of U or V is 1, a fused ring may be present at the part designated by U or V, and if the number of U or V is 0, a fused ring may not be present at the part designated by U or V. If the number of U is 0 and the number of V is 1, or if the number of U is 1 and the number of V is 0, a ring having the fluorene core of Formula F-b may be a ring compound with four rings. If the number of both U and V is 0, the ring of Formula F-b may be a ring compound with three rings. If the number of both U and V is 1, a ring having the fluorene core of Formula F-b may be a ring compound with five rings.

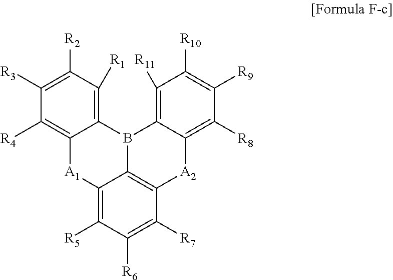

In Formula F-c, A₁ and A₂ may each independently be O, S, Se, or N(Rₘ), and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula F-c, A₁ and A₂ may each independently be combined with the substituents of an adjacent ring to form a fused ring. For example, if A₁ and A₂ are each independently N(Rₘ), A₁ may be combined with R₄ or R₅ to form a ring. For example, A₂ may be combined with R₇ or R₈ to form a ring.

In an embodiment, the emission layer EML may include as a dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalene-2-yl)vinyl)phenyl)-N-phenylbenzenamine (N-BDAVBi)), and 4,4′-bis[2-4-(N,N-diphenylamino)phenyl]vinyl]biphenyl (DPAVBi), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), etc.

The emission layer EML may include a phosphorescence dopant material. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) or thulium (Tm). Particularly, iridium(III) bis(4,6-difluorophenylpyridinato-N,C2′)picolinate (Firpic), bis(2,4-difluorophenylpyridinato)-tetrakis(1-pyrazolyl)borate iridium(III) (Fir6), or platinum octaethyl porphyrin (PtOEP) may be used as the phosphorescence dopant. However, embodiments are not limited thereto.

The emission layer EML may include a quantum dot material. The quantum dot may be a Group II-VI compound, a Group III-VI compound, a Group I-III-VI compound, a Group III-V compound, a Group III-II-V compound, a Group IV-VI compound, a Group IV element, a Group IV compound, and combinations thereof.

The Group II-VI compound may be a binary compound selected from the group consisting of CdSe, CdTe, CdS, ZnS, ZnSe, ZnTe, ZnO, HgS, HgSe, HgTe, MgSe, MgS, and mixtures thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof, or any combination thereof.

The Group III-VI compound may be a binary compound such as In₂S₃, and In₂Se₃, a ternary compound such as InGaS₃, and InGaSe₃; or any combinations thereof.

The Group I-III-VI compound may be a ternary compound selected from the group consisting of AgInS, AgInS₂, CuInS, CuInS₂, AgGaS₂, CuGaS₂, CuGaO₂, AgGaO₂, AgAlO₂ and mixtures thereof, a quaternary compound such as AgInGaS₂, and CuInGaS₂; or any combination thereof.

The Group III-V compound may be a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof, or any combination thereof. The Group III-V compound may further include a Group II metal. For example, InZnP, etc. may be selected as a Group III-II-V compound.

The Group IV-VI compound may be a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, a quaternary compound selected from the group consisting of SnPbSSe, SnPbSeTe, SnPbSTe, and mixtures thereof, or any combination thereof. The Group IV element may be selected from the group consisting of Si, Ge, and a mixture thereof. The Group IV compound may be a binary compound selected from the group consisting of SiC, SiGe, and a mixture thereof.

A binary compound, a ternary compound, or a quaternary compound may be present in a particle at uniform concentration or may be present in a particle at a partially different concentration distribution state. In an embodiment, the quantum dot may have a core/shell structure in which one quantum dot surrounds another quantum dot. The interface of the core and the shell may have a concentration gradient in which the concentration of an element that is present in the shell decreases toward the center.

In embodiments, the quantum dot may have a core-shell structure including a core including a nanocrystal and a shell surrounding the core. The shell of the quantum dot may be a protection layer that prevents chemical deformation of the core to maintain semiconductor properties and/or may be a charging layer that imparts electrophoretic properties to the quantum dot. The shell may be a single layer or a multilayer. Examples of the shell of the quantum dot may include a metal oxide, a non-metal oxide, a semiconductor compound, or combinations thereof.

For example, the metal oxide or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO; or a ternary compound such as MgAl₂O₄, CoFe₂O₄, NiFe₂O₄ and CoMn₂O₄, but embodiments are not limited thereto.

The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width of half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm or less. Within these ranges, color purity or color reproducibility may be improved. Light emitted through the quantum dot may be emitted in all directions, and light viewing angle properties may be improved.

The shape of the quantum dot may be a shape that is used in the art, without limitation. For example, a quantum dot may have a spherical shape, a pyramidal shape, a multi-arm shape, or a cubic shape, or the quantum dot may be in the form of a nanoparticle, a nanotube, a nanowire, a nanofiber, a nanoplate, etc.

The quantum dot may control the color of light emitted according to a particle size thereof, and accordingly, the quantum dot may have various emission colors such as blue, red, and green.

In the light emitting devices ED of embodiments, as shown in FIG. 3 to FIG. 6, the electron transport region ETR is provided on the emission layer EML. The electron transport region ETR may include at least one of a hole blocking layer HBL, an electron transport layer ETL, or an electron injection layer EIL. However, embodiments are not limited thereto.

The electron transport region ETR may be a layer formed of a single material, a layer formed of different materials, or a multilayer structure having layers formed of different materials.

For example, the electron transport region ETR may have a single layer structure of an electron injection layer EIL or an electron transport layer ETL, or a single layer structure formed of an electron injection material and an electron transport material. The electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-1.

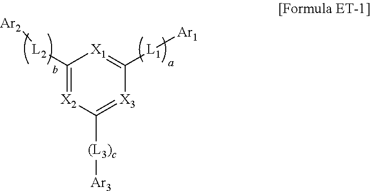

In Formula ET-1, at least one of X₁ to X₃ may be N, and the remainder of X₁ to X₃ may be C(Rₐ). Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-1, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and mixtures thereof, without limitation.

The electron transport region ETR may include at least one selected from Compounds ET1 to ET36.

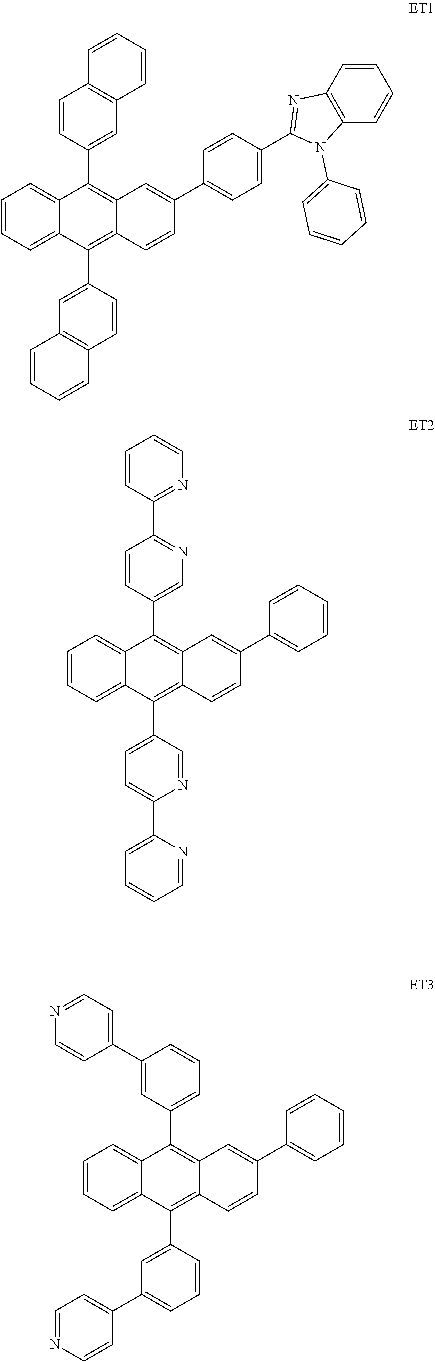 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

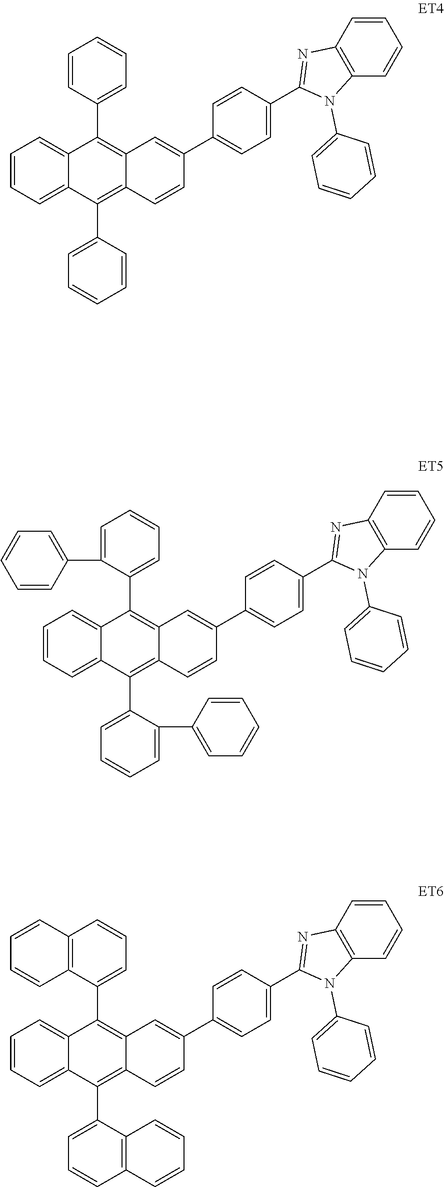 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

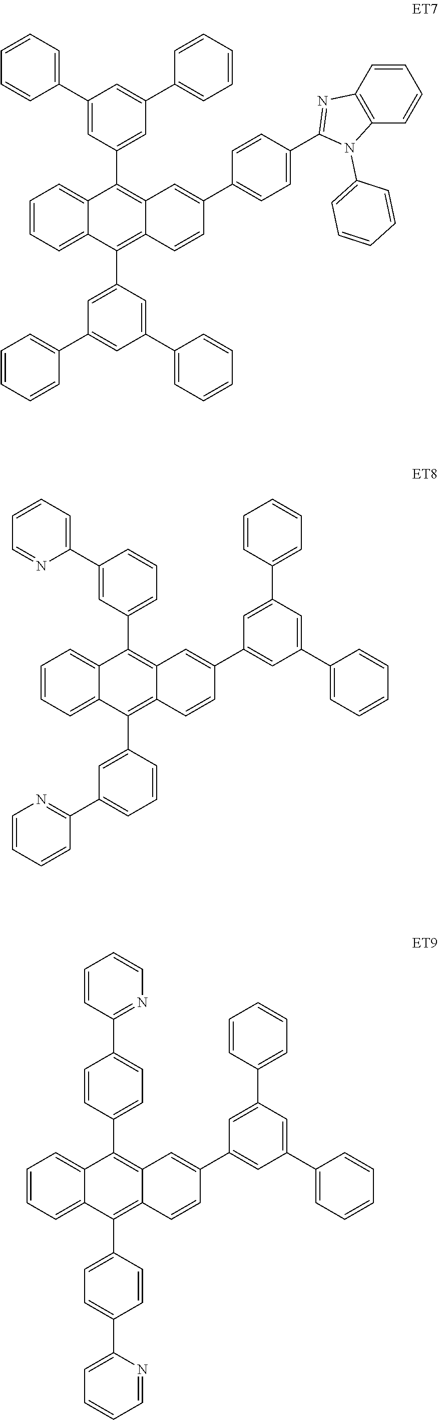 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

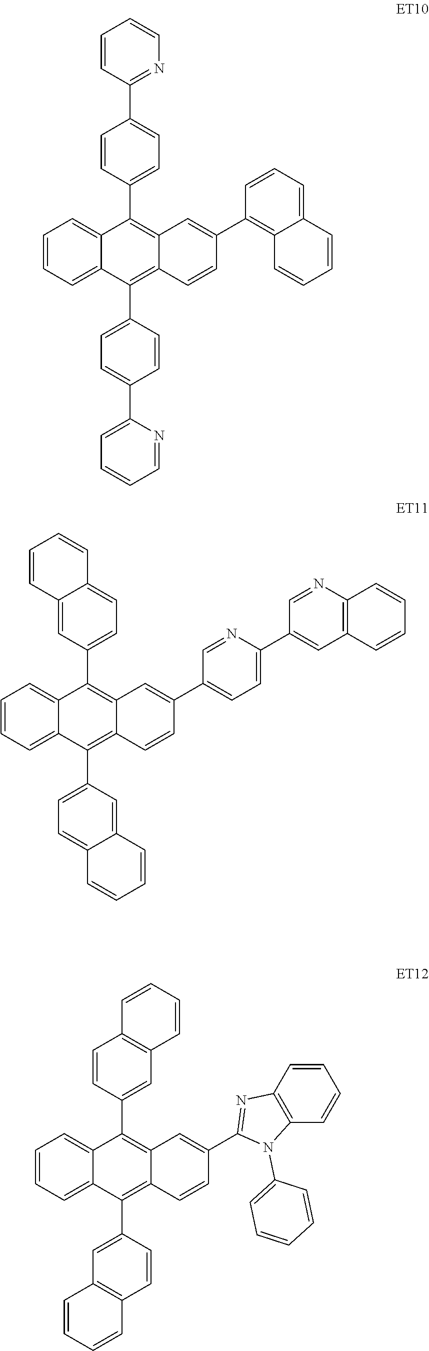 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

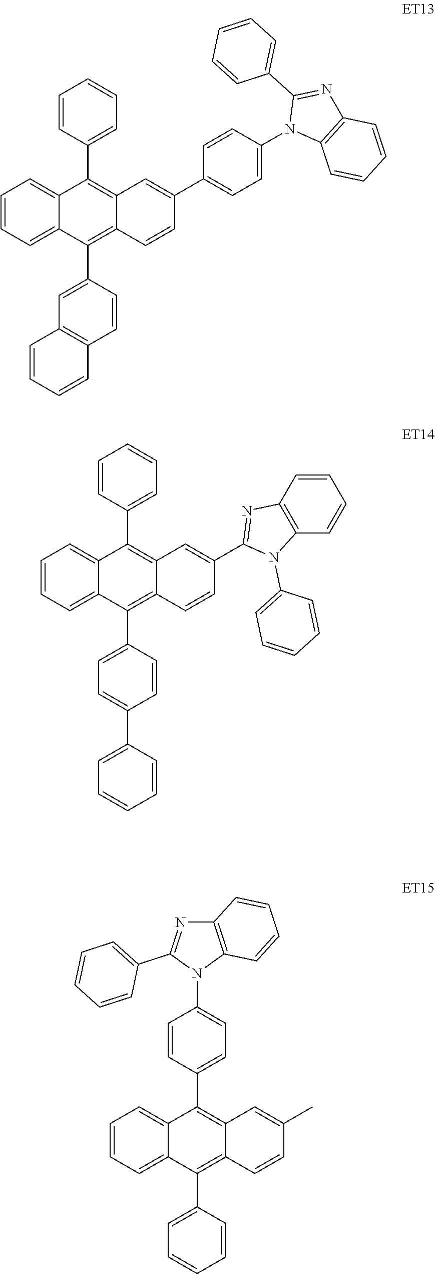 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

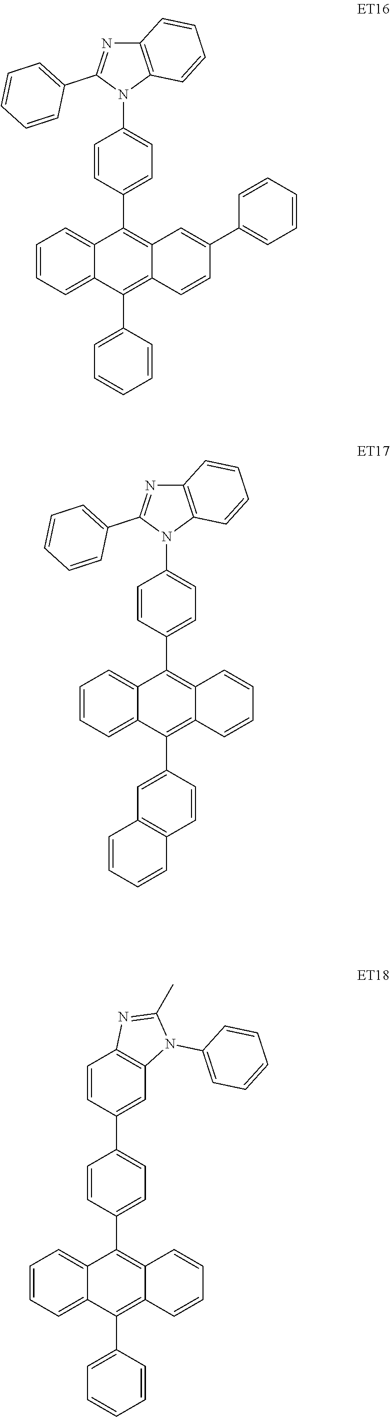 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

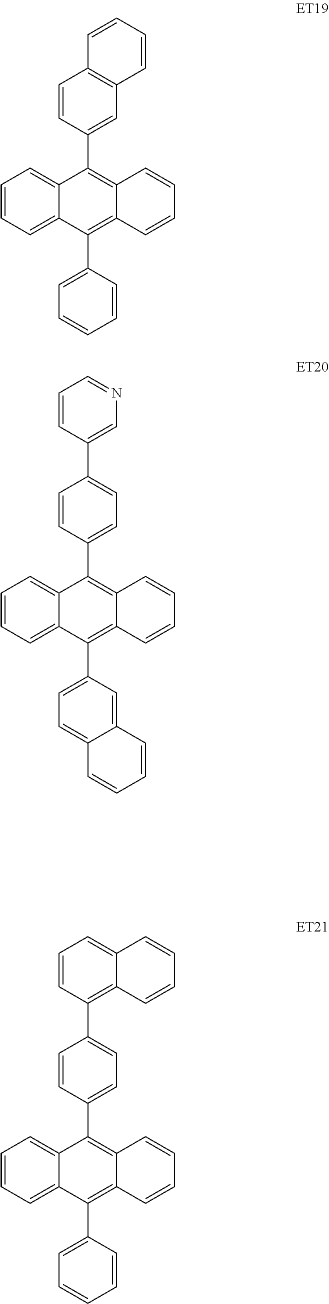

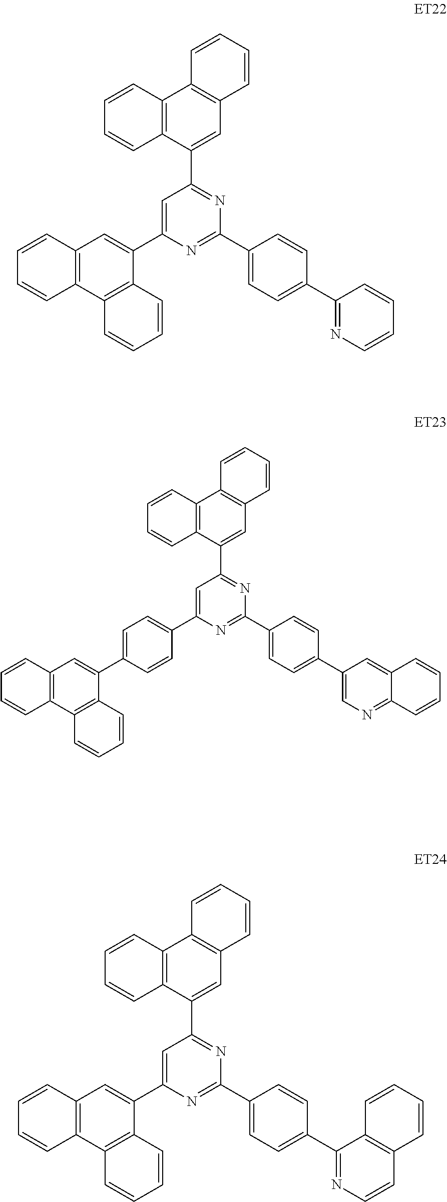 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

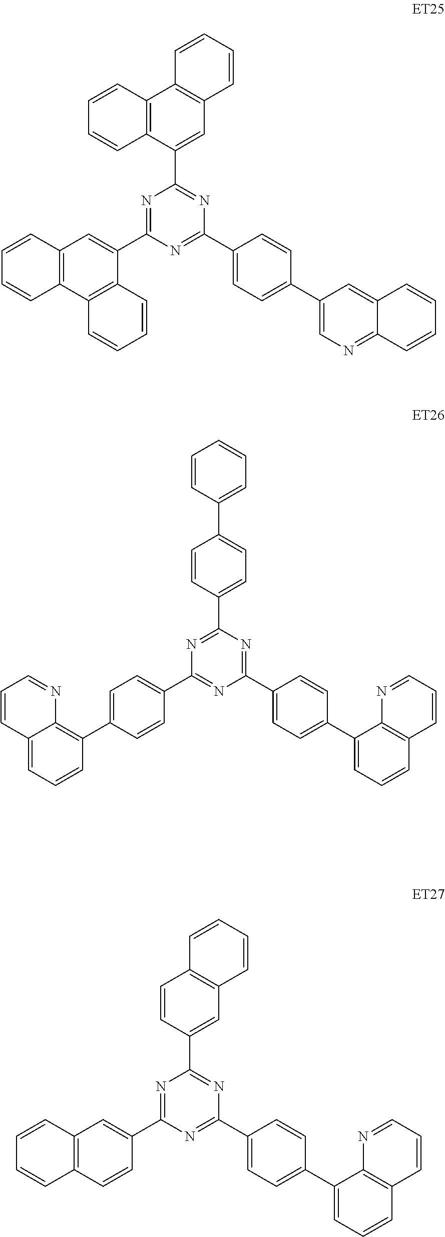 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

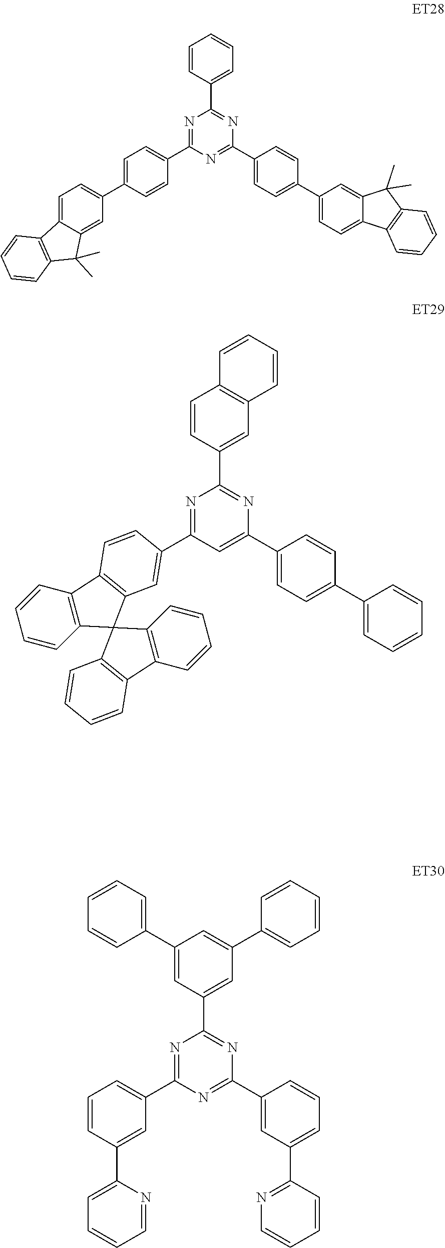 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

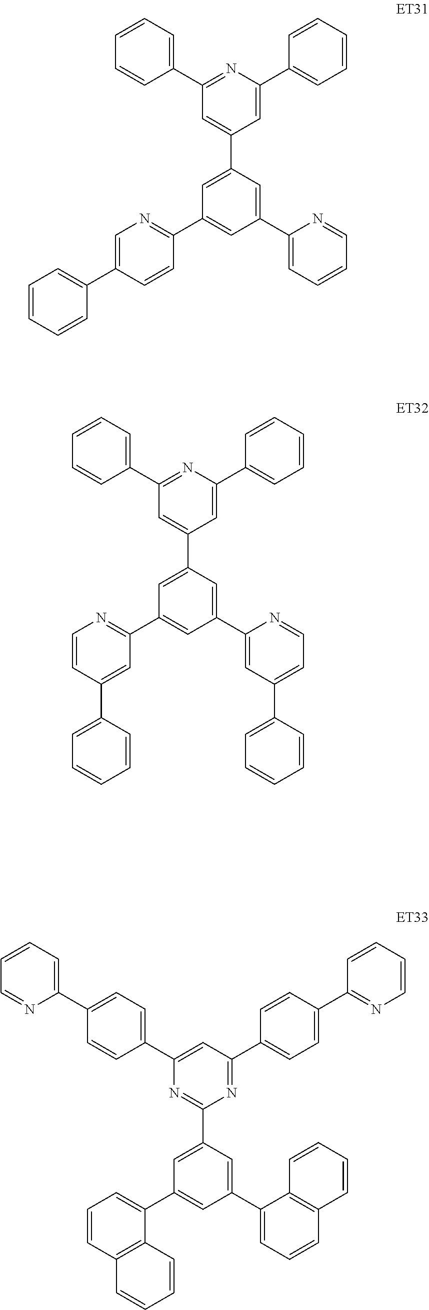 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

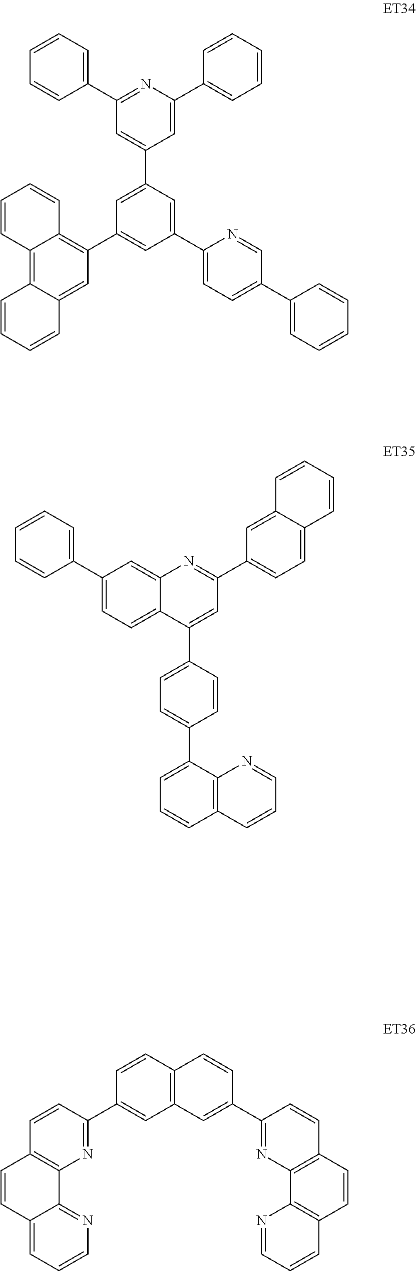 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

The electron transport region ETR may include a metal halide such as LiF, NaCl, CsF, RbCl, RbI, CuI and KI, a lanthanide metal such as Yb, or a co-deposited material of a metal halide and a lanthanide metal. For example, the electron transport region ETR may include KI:Yb, RbI:Yb, etc., as a co-deposited material. The electron transport region ETR may include a metal oxide such as Li₂O and BaO, or 8-hydroxy-lithium quinolate (Liq). However, embodiments are not limited thereto. The electron transport region ETR may be formed of a mixture material of an electron transport material and an insulating organo metal salt. The organo metal salt may be a material having an energy band gap equal to or greater than about 4 eV. For example, the organo metal salt may include metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), or 4,7-diphenyl-1,10-phenanthroline (Bphen) in addition to the aforementioned materials. However, embodiments are not limited thereto.

The electron transport region ETR may include the compounds of the electron transport region in at least one of an electron injection layer EIL, an electron transport layer ETL, or a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies the above-described range, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies the above described range, satisfactory electron injection properties may be obtained without a substantial increase of driving voltage.

The second electrode EL2 is provided on the electron transport region ETR. The second electrode EL2 may be a common electrode. The second electrode EL2 may be a cathode or an anode, but embodiments are not limited thereto. For example, if the first electrode EL1 is an anode, the second electrode EL2 may be a cathode, and if the first electrode EL1 is a cathode, the second electrode EL2 may be an anode.

The second electrode EL2 may be a transmissive electrode, a transflective electrode, or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds thereof, or mixtures thereof (for example, AgMg, AgYb, or MgYb). In another embodiment, the second electrode EL2 may have a multilayered structure including a reflective layer or a transflective layer formed of the above-described materials and a transparent conductive layer formed of ITO, IZO, ZnO, ITZO, etc. For example, the second electrode EL2 may include the aforementioned metal materials, combinations of two or more metal materials selected from the aforementioned metal materials, or oxides of the aforementioned metal materials.

Although not shown in the drawings, the second electrode EL2 may be electrically connected to an auxiliary electrode. If the second electrode EL2 is electrically connected to the auxiliary electrode, the resistance of the second electrode EL2 may decrease.

In an embodiment, the light emitting device ED may further include a capping layer CPL disposed on the second electrode EL2. The capping layer CPL may be a multilayer or a single layer.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNx, SiOy, etc.

For example, if the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, or acrylate such as methacrylate. However, embodiments are not limited thereto, and a capping layer CPL may include at least one selected from Compounds P1 to P5, but embodiments are not limited thereto.

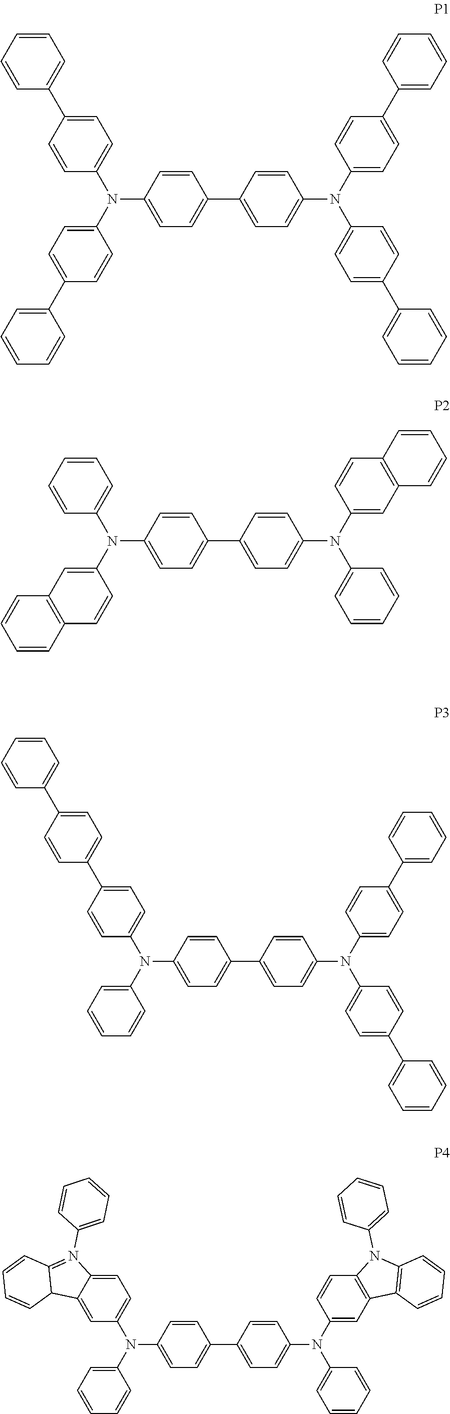

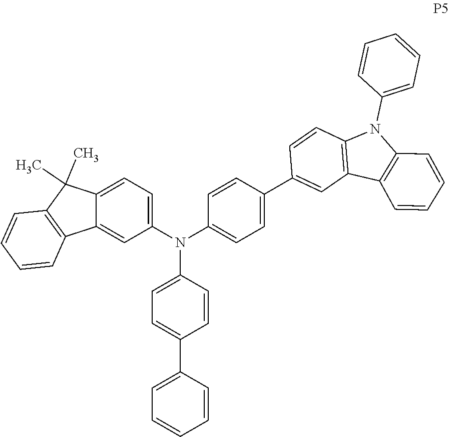 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the capping layer CPL may have a refractive index equal to or greater than about 1.6 with respect to light in a wavelength range of about 550 nm to about 660 nm.

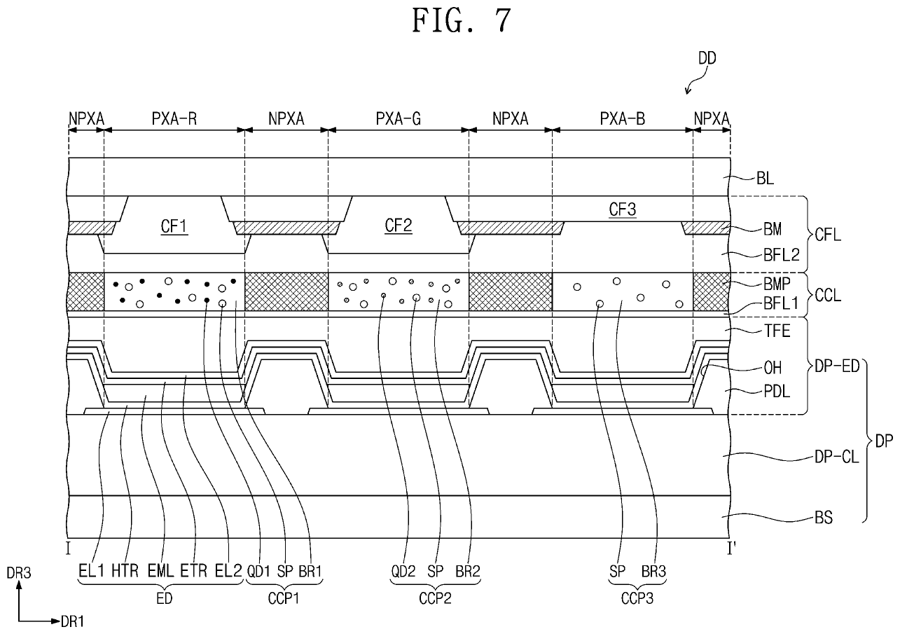

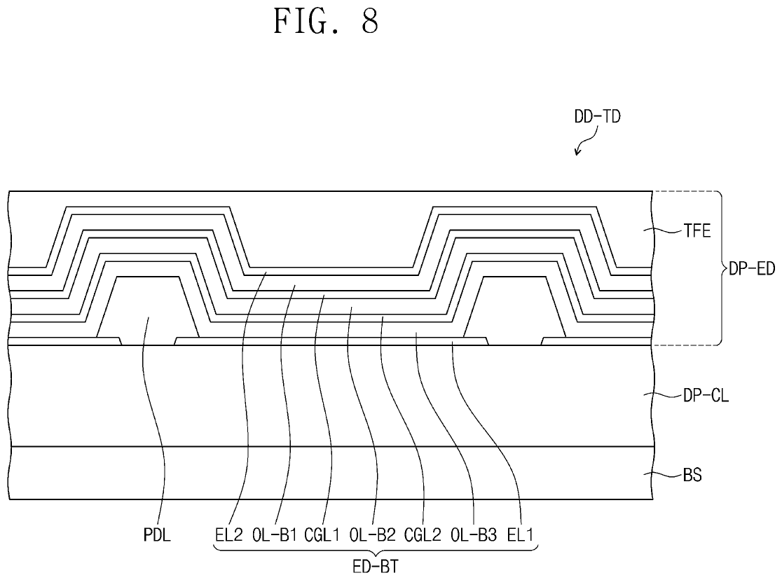

FIG. 7 and FIG. 8 are each a schematic cross-sectional view of a display apparatus according to embodiments. In the explanation on the display apparatuses of embodiments according to FIG. 7 and FIG. 8, the overlapping parts with the explanation on FIG. 1 to FIG. 6 will not be explained again, and the different features will be explained.

Referring to FIG. 7, the display apparatus DD according to an embodiment may include a display panel DP including a display device layer DP-ED, a light controlling layer CCL disposed on the display panel DP, and a color filter layer CFL.

In an embodiment shown in FIG. 7, the display panel DP may include a base layer BS, a circuit layer DP-CL provided on the base layer BS, and a display device layer DP-ED, and the display device layer DP-ED may include a light emitting device ED.

The light emitting device ED may include a first electrode EL1, a hole transport region HTR disposed on the first electrode EL1, an emission layer EIL disposed on the hole transport region HTR, an electron transport region ETR disposed on the emission layer EIL, and a second electrode EL2 disposed on the electron transport region ETR. A structure of the light emitting device according to FIG. 3 to FIG. 6 may be applied to the structure of the light emitting device ED shown in FIG. 7.

Referring to FIG. 7, the emission layer EIL may be disposed in an opening OH defined in a pixel definition layer PDL. For example, the emission layer EIL which is divided by the pixel definition layer PDL and correspondingly provided to each of the luminous areas PXA-R, PXA-G, and PXA-B may emit light in a same wavelength region. In the display apparatus DD of an embodiment, the emission layer EIL may emit blue light. Although not shown in the drawings, in an embodiment, the emission layer EIL may be provided as a common layer for all luminous areas PXA-R, PXA-G, and PXA-B.

The light controlling layer CCL may be disposed on the display panel DP. The light controlling layer CCL may include a light converter. The light converter may include a quantum dot or a phosphor. The light converter may convert the wavelength of a provided light and may emit the converted light. For example, the light controlling layer CCL may be a layer including a quantum dot or a layer including a phosphor.

The light controlling layer CCL may include light controlling parts CCP1, CCP2, and CCP3. The light controlling parts CCP1, CCP2, and CCP3 may be separated from one another.

Referring to FIG. 7, a partition pattern BMP may be disposed between the separated light controlling parts CCP1, CCP2, and CCP3, but embodiments are not limited thereto. FIG. 7 illustrates that the partition pattern BMP does not overlap the light controlling parts CCP1, CCP2, and CCP3, but at least a portion of the edge of the light controlling parts CCP1, CCP2, and CCP3 may overlap the partition pattern BMP.

The light controlling layer CCL may include a first light controlling part CCP1 including a first quantum dot QD1 that converts first color light provided from the light emitting device ED into second color light, a second light controlling part CCP2 including a second quantum dot QD2 that converts first color light into third color light, and a third light controlling part CCP3 that transmits first color light.

In an embodiment, the first light controlling part CCP1 may provide red light which is the second color light, and the second light controlling part CCP2 may provide green light which is the third color light. The third light controlling part CCP3 may transmit and provide blue light, which is the first color light provided from the light emitting device ED. For example, the first quantum dot QD1 may be a red quantum dot, and the second quantum dot QD2 may be a green quantum dot. The same descriptions as provided above with respect to quantum dots may be applied to the quantum dots QD1 and QD2.

The light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include at least one of TiO₂, ZnO, Al₂O₃, SiO₂, and hollow silica, or may be a mixture of two or more materials selected from TiO₂, ZnO, Al₂O₃, SiO₂, and hollow silica.

The first light controlling part CCP1, the second light controlling part CCP2, and the third light controlling part CCP3 may each include base resins BR1, BR2, and BR3 dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2, and BR3 may each be a medium in which the quantum dots QD1 and QD2 and the scatterer SP are dispersed, and may be composed of various resin compositions which may be generally referred to as a binder. For example, the base resins BR1, BR2, and BR3 may each independently be acrylic resins, urethane-based resins, silicone-based resins, epoxy-based resins, etc. The base resins BR1, BR2, and BR3 may each be transparent resins. In an embodiment, the first base resin BR1, the second base resin BR2, and the third base resin BR3 may be the same as or different from each other.

The light controlling layer CCL may include a barrier layer BFL1. The barrier layer BFL1 may block penetration of moisture and/or oxygen (hereinafter, will be referred to as “humidity/oxygen”). The barrier layer BFL1 may block exposure of the light controlling parts CCP1, CCP2, and CCP3 to humidity/oxygen. The barrier layer BFL1 may cover the light controlling parts CCP1, CCP2, and CCP3. For example, the barrier layer BFL2 may be provided between the light controlling parts CCP1, CCP2, and CCP3 and a color filter layer CFL.

The barrier layers BFL1 and BFL2 may each include at least one inorganic layer. For example, the barrier layers BFL1 and BFL2 may each be formed by including an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. The barrier layers BFL1 and BFL2 may each further include an organic layer. The barrier layers BFL1 and BFL2 may each be formed of a single layer or of multiple layers.

In the display apparatus DD of an embodiment, the color filter layer CFL may be disposed on the light controlling layer CCL. In an embodiment, the color filter layer CFL may be disposed directly on the light controlling layer CCL. For example, the barrier layer BFL2 may be omitted.

The color filter layer CFL may include a light blocking part BM and filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. Each of the filters CF1, CF2, and CF3 may include a polymer photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymer photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may be provided in one body without distinction.

The light blocking part BM may be a black matrix. The light blocking part BM may include an organic light blocking material or an inorganic light blocking material including a black pigment or a black dye. The light blocking part BM may prevent light leakage and may separate the boundaries between adjacent filters CF1, CF2, and CF3. In an embodiment, the light blocking part BM may be formed as a blue filter.

The first to third filters CF1, CF2, and CF3 may be respectively disposed corresponding to each of a red luminous area PXA-R, green luminous area PXA-G, and blue luminous area PXA-B.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawing, in an embodiment, the base substrate BL may be omitted.

FIG. 8 is a schematic cross-sectional view showing a portion of the display apparatus according to an embodiment. In FIG. 8, a schematic cross-sectional view of a portion corresponding to the display panel DP in FIG. 7 is shown. In a display apparatus DD-TD of an embodiment, the light emitting device ED-BT may include light emitting structures OL-B1, OL-B2, and OL-B3. The light emitting device ED-BT may include a first electrode EL1 and an oppositely disposed second electrode EL2, and the light emitting structures OL-B1, OL-B2, and OL-B3 stacked in a thickness direction and provided between the first electrode EL1 and the second electrode EL2. Each of the light emitting structures OL-B1, OL-B2, and OL-B3 may include an emission layer EML (FIG. 7), and a hole transport region HTR and an electron transport region ETR disposed with the emission layer EML (FIG. 7) therebetween.

For example, the light emitting device ED-BT included in the display apparatus DD-TD of an embodiment may be a light emitting device having a tandem structure and including multiple emission layers.

In an embodiment shown in FIG. 8, light emitted from the light emitting structures OL-B1, OL-B2, and OL-B3 may be all blue light. However, embodiments are not limited thereto, and the light emitted from the light emitting structures OL-B1, OL-B2, and OL-B3 may have different wavelength regions from each other. For example, the light emitting device ED-BT including the light emitting structures OL-B1, OL-B2, and OL-B3 emitting light in different wavelength regions may emit white light.

Charge generating layers CGL1 and CGL2 may be disposed between neighboring light emitting structures OL-B1, OL-B2, and OL-B3. The charge generating layers CGL1 and CGL2 may each independently include a p-type charge generating layer and/or an n-type charge generating layer.

Hereinafter, a polycyclic compound according to an embodiment and a light emitting device of an embodiment will be explained with reference to the Examples and the Comparative Examples. The Examples are only illustrations for understanding the disclosure, and the scope thereof is not limited thereto.

### Examples

1. Synthesis of Polycyclic Compound of an Embodiment

The synthesis method of the polycyclic compound according to an embodiment will be explained by describing the synthesis methods of Compounds 10, 23, 24, 27, 30, 46, and 69. The synthesis methods of the polycyclic compounds explained below are only examples, and the synthesis method of the polycyclic compound according to embodiments is not limited thereto.

(1) Synthesis of Compound 10

Polycyclic Compound 10 according to an embodiment may be synthesized, for example, by the steps of Reaction 1 below.

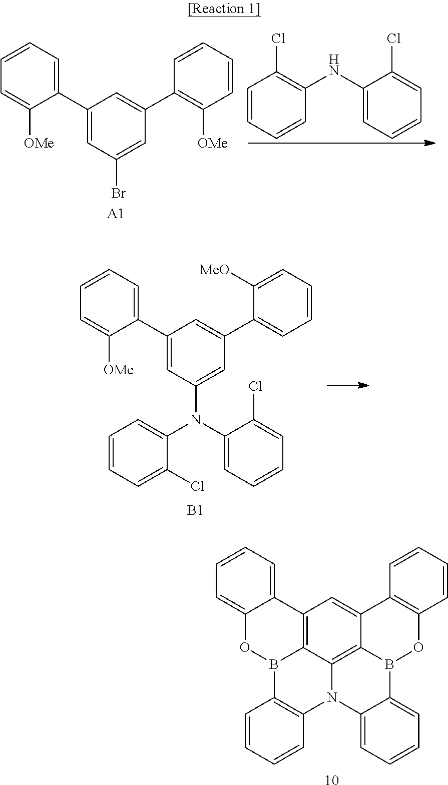

<Synthesis of Compound B1>

Compound A1 was synthesized referring to a nonpatent document (Chemical Communications 2019, 55(17), 2501-2504) and a patent document (US 20200203627 A1). HN(C₆H₄₋₂-Cl)₂ was synthesized referring to a patent document (KR 2018097955 A).

Under an Ar atmosphere, to a 2000 mL, three neck flask, Compound A1 (36.9 g), HN(C₆H₄₋₂-Cl)₂ (23.8 g), bis(dibenzylideneacetone)palladium(0) (Pd(dba)₂, 2.12 g), 2-dicyclohexylphosphino-2′,6′-dimethoxybiphenyl (SPhos, 1.56 g), and sodium tert-butoxide (NaOtBu, 10.0 g) were added and dissolved in toluene (1000 mL), followed by heating and refluxing for about 5 hours. After cooling to room temperature, water was added, and the product was extracted with dichloromethane (CH₂Cl₂). Organic layers were collected and dried with magnesium sulfate (MgSO₄), and the solvent was removed by distillation under a reduced pressure. The crude product thus obtained was separated by silica gel column chromatography to obtain 26.3 g of Compound B1 (yield 50%). The mass number of Compound B1, measured by fast atom bombardment mass spectrometry (FAB-MS) was 525.

<Synthesis of Compound 10>

Under an Ar atmosphere, to a 1000 mL, three neck flask, Compound B1 (26.3 g) was added and dissolved in toluene (500 mL), followed by cooling to about −78° C. To a 1.60 M hexane solution, 0.05 mol of n-butyllithium was added, and thus obtained solution was added to the flask dropwise over about 1 hour. The temperature of the reaction solution was raised to about 0° C., and additional stirring was performed for about 30 minutes. After cooling the reaction solution to about −78° C. again, BBr₃ (50.0 g) was added. While stirring the reaction solution, the temperature was slowly raised to room temperature, and NEt(iPr)₂ (N,N-diisopropylethylamine, 13.0 g) was added and reacted at about 100° C. for about 2 hours. After cooling to room temperature, water was added, and the product was extracted with dichloromethane. Organic layers were collected and dried with magnesium sulfate, and the solvent was removed by distillation under a reduced pressure. The crude product thus obtained was separated by silica gel column chromatography to obtain 2.4 g of Compound 10 (yield 11%). The mass number of Compound 10, measured by FAB-MS was 445.

(2) Synthesis of Compound 23

Polycyclic Compound 23 according to an embodiment may be synthesized, for example, by the step of Reaction 2 below.

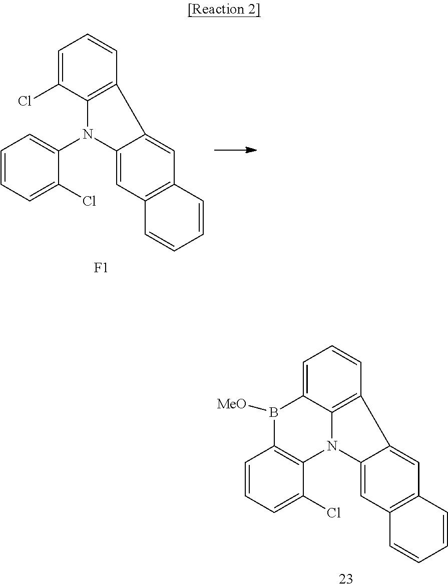 [SMILES: Clc1ccccc1-n1c2cc3ccccc3cc2c2cccc(Cl)c21 ; "F1" ; COB1c2cccc(Cl)c2-n2c3cc4ccccc4cc3c3cccc1c32 ; "23"]

Compound F1 was synthesized referring to a patent document (WO 2020122461 A1). Under an Ar atmosphere, to a 1000 mL, three neck flask, Compound F1 (18.0 g) was added and dissolved in toluene (500 mL), followed by cooling to about −78° C. To a 1.60 M hexane solution, 0.10 mol of n-butyllithium was added, and thus obtained solution was added to the flask dropwise over about 1 hour. The temperature of the reaction solution was raised to about 0° C., and additional stirring was performed for about 30 minutes. After cooling the reaction solution to about −78° C. again, 0.10 mol of BCl₃ was added to a 1.0 M heptane solution, and this solution was added to the reaction solution. While stirring the reaction solution, the temperature was slowly raised to room temperature, and additional stirring was performed at room temperature for about 3 hours. After cooling the reaction solution to about −78° C. again, a toluene solution (100 mL) of MeOSiMe₃ (5.2 g) was added thereto dropwise over about 1 hour. While stirring the reaction solution, the temperature was slowly raised to room temperature, and additional stirring was performed at room temperature for about 12 hours. Water was added, and the product was extracted with dichloromethane. Organic layers were collected and dried with magnesium sulfate, and the solvent was removed by distillation under a reduced pressure. The crude product thus obtained was separated by silica gel column chromatography to obtain 2.4 g of Compound 23 (yield 14%). The mass number of Compound 10, measured by FAB-MS was 333.

(3) Synthesis of Compound 24

Polycyclic Compound 24 according to an embodiment may be synthesized, for example, by the step of Reaction 3 below.

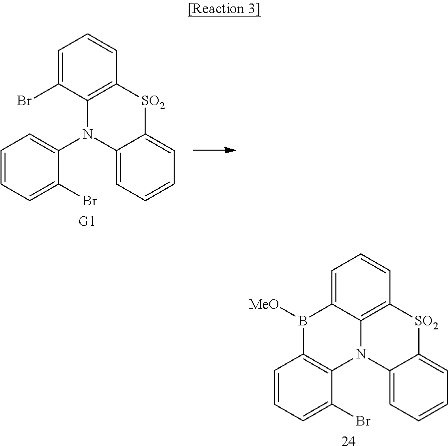

Compound G1 was synthesized referring to a patent document (CN 112079859 A1). Compound 24 (1.9 g, yield 11%) was synthesized by the same method as the synthesis of Compound 23 except for using Compound G1 (23.0 g) instead of Compound F1 (18.0 g). The mass number of Compound 24, measured by FAB-MS was 347.

(4) Synthesis of Compound 27

Polycyclic Compound 27 according to an embodiment may be synthesized, for example, by the step of Reaction 4 below.

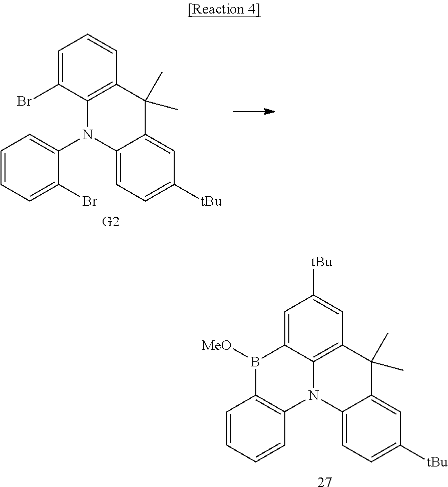

Compound G2 was synthesized referring to a patent document (US 20200274075 A1). Compound 27 (2.8 g, yield 13%) was synthesized by the same method as the synthesis of Compound 23 except for using Compound G2 (28.0 g) instead of Compound F1 (18.0 g). The mass number of Compound 27, measured by FAB-MS was 437.

(5) Synthesis of Compound 30

Polycyclic Compound 30 according to an embodiment may be synthesized, for example, by the steps of Reaction 5 below.

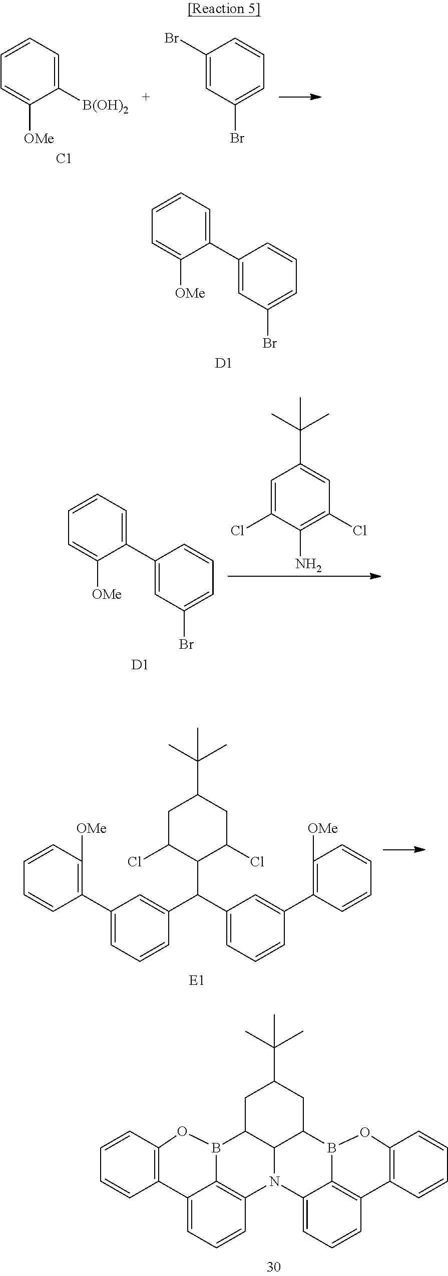

<Synthesis of Compound D1>

Compound D1 was synthesized referring to a nonpatent document (Chemical Communications 2019, 55(17), 2501-2504). For synthesizing Compound D1, Compound C1 (40 g) and C₆H₄-1,3-Br₂ (92 g) were used. The mass number of Compound D1, measured by FAB-MS was 262.

<Synthesis of Compound E1>

H₂N(C₆H₂-2,6-Cl₂-4-tBu) was synthesized referring to a patent document (U.S. Pat. No. 4,444,782 A).

Under an Ar atmosphere, to a 2000 mL, three neck flask, Compound D1 (26.3 g), H₂N(C₆H₂-2,6-Cl₂-4-tBu) (10.8 g), Pd(dba)₂, (1.1 g), SPhos (0.8 g), and NaOtBu (11.0 g) were added and dissolved in toluene (1000 mL), followed by heating and refluxing for about 4 hours. After cooling to room temperature, water was added, and the product was extracted with dichloromethane. Organic layers were collected and dried with magnesium sulfate, and the solvent was removed by distillation under a reduced pressure. The crude product thus obtained was separated by silica gel column chromatography to obtain 8.4 g of Compound E1 (yield 29%). The mass number of Compound E1, measured by FAB-MS was 581.

<Synthesis of Compound 30>

Compound 30 (0.8 g, yield 11%) was synthesized by the same method as the synthesis of Compound 10 except for using Compound E1 (8.4 g) instead of Compound B1 (26.3 g). The mass number of Compound 30, measured by FAB-MS was 501.

(6) Synthesis of Compound 46

Polycyclic Compound 46 according to an embodiment may be synthesized, for example, by the steps of Reaction 6 below.

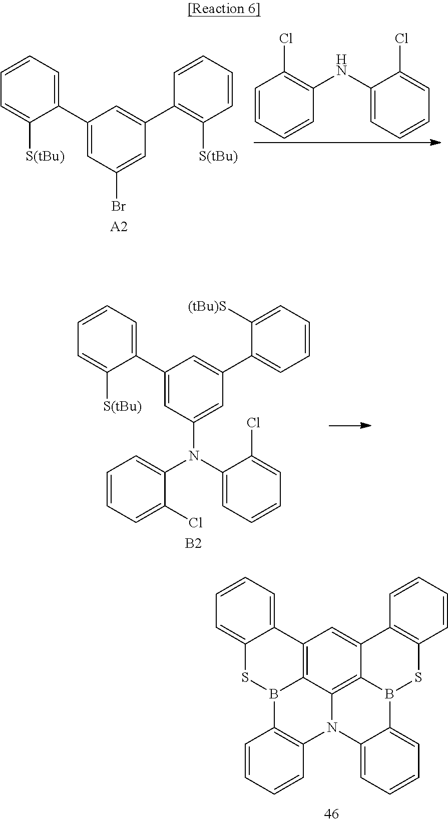

<Synthesis of Compound B2>

Compound A2 was synthesized referring to a nonpatent document (Chemical Communications 2019, 55(17), 2501-2504) and a patent document (US 2020023627 A1). Compound B2 (25.0 g, yield 39%) was synthesized by the same method as the synthesis of Compound B1 except for using Compound A2 (48.5 g) instead of Compound A1 (36.9 g). The mass number of Compound B2, measured by FAB-MS was 641.

<Synthesis of Compound 46>

Compound 46 (1.7 g, yield 9%) was synthesized by the same method as the synthesis of Compound 10 except for using Compound B2 (25.0 g) instead of Compound B1 (26.3 g). The mass number of Compound 46, measured by FAB-MS was 477.

(7) Synthesis of Compound 69

Polycyclic Compound 69 according to an embodiment may be synthesized, for example, by the steps of Reaction 7 below.

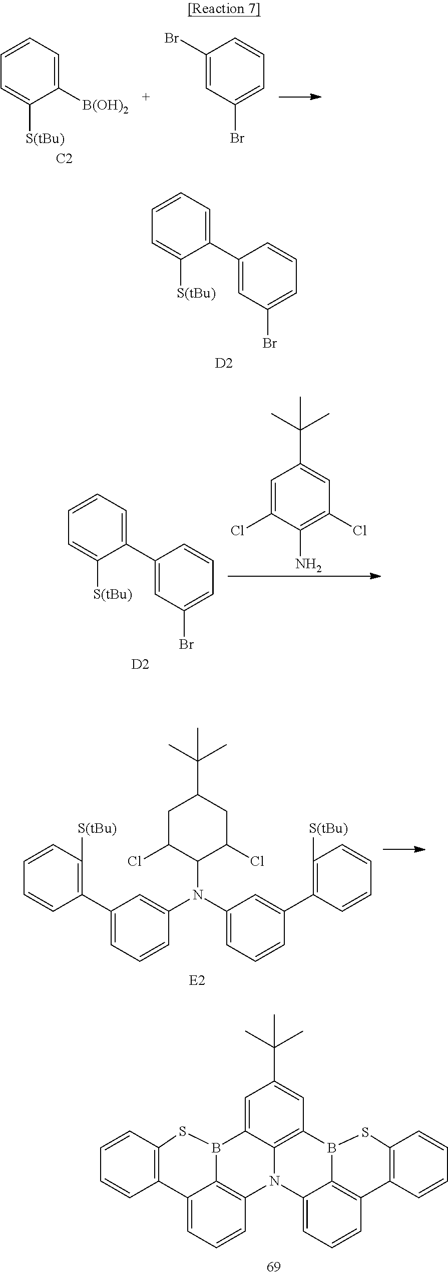

<Synthesis of Compound D2>

Compound D2 (56.0 g, yield 88%) was synthesized by the same method as the synthesis of Compound D1 except for using Compound C2 (42.0 g) instead of Compound C1 (40 g) and using C₆H₄-1,3-Br₂ (68.0 g) instead of C₆H₄-1,3-Br₂ (92 g). The mass number of Compound D2, measured by FAB-MS was 320.

<Synthesis of Compound E2>

Compound E2 (13.0 g, yield 37%) was synthesized by the same method as the synthesis of Compound E1 except for using Compound D2 (32.0 g) instead of Compound D1 (26.3 g). The mass number of Compound E2, measured by FAB-MS was 697.

<Synthesis of Compound 69>

Compound 69 (0.9 g, yield 13%) was synthesized by the same method as the synthesis of Compound 10 except for using Compound E2 (13.0 g) instead of Compound B1 (26.3 g). The mass number of Compound 69, measured by FAB-MS was 533.

2. Manufacture of Light Emitting Device

On a glass substrate, ITO with a thickness of about 1,200 Å was patterned, washed with ultrapure water and ultrasonic waves, exposed to UV for about 30 minutes and treated with ozone. HAT-CN was deposited to a thickness of about 100 Å, α-NPD was deposited to a thickness of about 800 Å, and mCP was deposited to a thickness of about 50 Å to form a hole transport region.

The polycyclic compound of an embodiment or the Comparative Compound was co-deposited with mCBP in a ratio of 1:99 to form a layer with a thickness of about 200 Å to form an emission layer. The emission layer formed by the co-deposition was obtained by mixing each of Compounds 10, 23, 24, 27, 30, 46, and 69 with mCBP and depositing in Example 1 to Example 7, respectively, and by mixing each of Comparative Compounds X-1 to X-3 with mCBP and depositing in Comparative Example 1 to Comparative Example 3, respectively.

A layer was formed on the emission layer using TPBi to a layer of about 300 Å, and a layer was formed of LiF to a thickness of about 5 Å to form an electron transport region. A second electrode was formed of aluminum (Al) to a thickness of about 1,000 Å. In an embodiment, the hole transport region, the emission layer, the electron transport region, and the second electrode were formed using a vacuum deposition apparatus.

HAT-CN, α-NPD, mCP, DPEPO, and TPBi are common materials of the art, and commercial products were used after sublimation and purification.

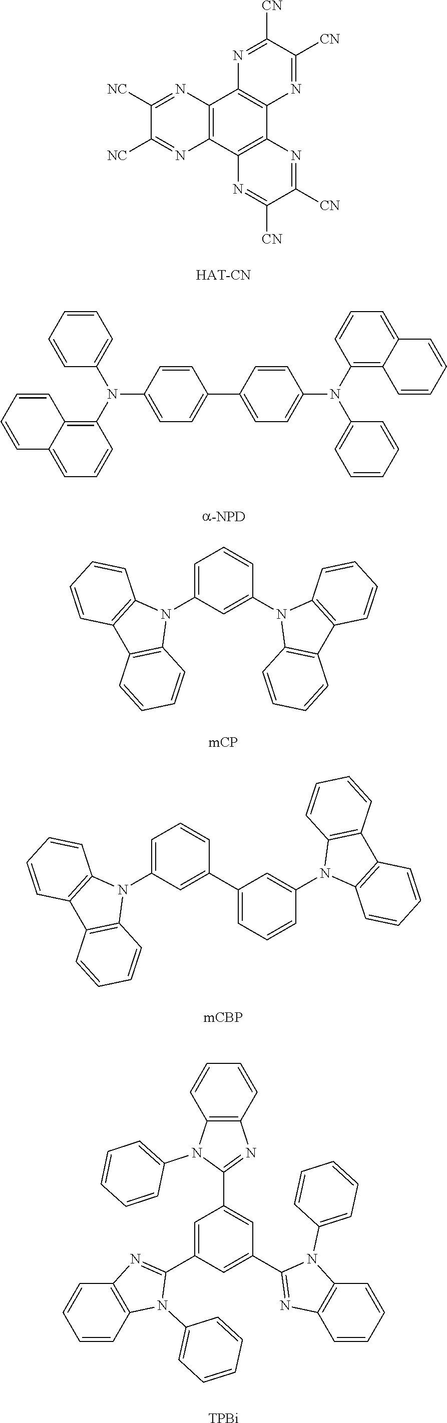

The compounds used in Examples 1 to 7, and Comparative Examples 1 to 3 are shown in Table 1.

TABLE 1

| | |
|---|---|
| Compound 10 | 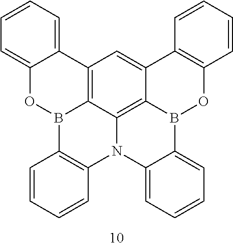 [SMILES: c1ccc2c(c1)OB1c3ccccc3N3c4ccccc4B4Oc5ccccc5-c5cc-2c1c3c54] |
| Compound 23 | 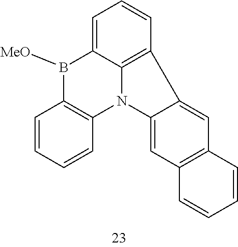 [SMILES: COB1c2ccccc2-n2c3cc4ccccc4cc3c3cccc1c32] |
| Compound 24 | 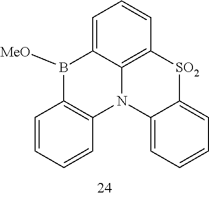 [SMILES: COB1c2ccccc2N2c3ccccc3S(=O)(=O)c3cccc1c32] |
| Compound 27 | 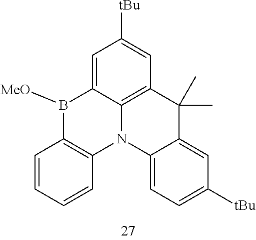 [SMILES: COB1c2ccccc2N2c3ccc(C(C)(C)C)cc3C(C)(C)c3cc(C(C)(C)C)cc1c32] |
| Compound 30 | 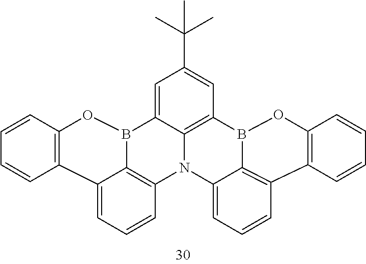 [SMILES: CC(C)(C)c1cc2c3c(c1)B1Oc4ccccc4-c4cccc(c41)N3c1cccc3c1B2Oc1ccccc1-3] |
| Compound 46 | 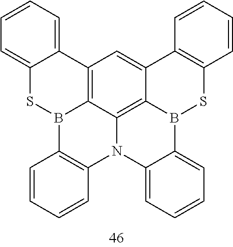 [SMILES: c1ccc2c(c1)SB1c3ccccc3N3c4ccccc4B4Sc5ccccc5-c5cc-2c1c3c54] |
| Compound 69 | 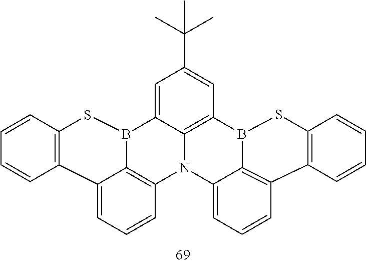 [SMILES: CC(C)(C)c1cc2c3c(c1)B1Sc4ccccc4-c4cccc(c41)N3c1cccc3c1B2Sc1ccccc1-3] |
| Comparative Compound X-1 | 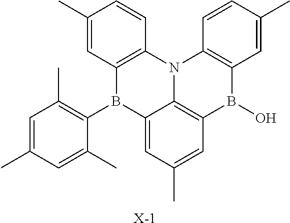 |
| Comparative Compound X-2 | 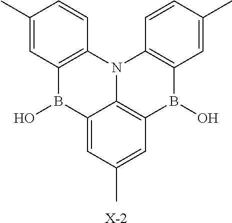 |
| Comparative Compound X-3 | 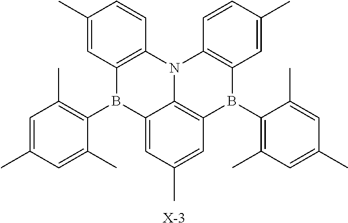 |

3. Evaluation of Properties of Light Emitting Device

In Table 2, the evaluation results of the light emitting devices of Example 1 to Example 7, and Comparative Example 1 to Comparative Example 3 are shown. In Table 2, the maximum emission wavelength (_{λmax}), half life (LT₅₀), and external quantum efficiency (EQE_{max, 1000 nit}) of the light emitting devices manufactured are compared and shown. In the evaluation results on the properties of the Examples and Comparative Examples, shown in Table 2, the maximum emission wavelength (_{λmax}) represents the wavelength showing the maximum value in an emission spectrum, and the half life (LT₅₀) represents time required for reducing an initial luminance of about 1,000 cd/m² to half. The external quantum efficiency (EQE_{max, 1000 nit}) in Table 2 represents external quantum efficiency at a point where a luminance of about 1,000 cd/m² is shown.

TABLE 2

| | | | LT₅₀ | EQE_{max, 1000 nit} |
|---|---|---|---|---|
| Division | Dopant material | _{λmax} (nm) | (hour) | (%) |
| Example 1 | Compound 10 | 467 | 2.0 | 9 |
| Example 2 | Compound 23 | 464 | 1.1 | 6 |
| Example 3 | Compound 24 | 475 | 1.5 | 8 |
| Example 4 | Compound 27 | 461 | 1.2 | 5 |
| Example 5 | Compound 30 | 471 | 2.4 | 6 |
| Example 6 | Compound 46 | 468 | 2.1 | 10 |
| Example 7 | Compound 69 | 474 | 2.6 | 8 |
| Comparative | Comparative | 455 | <0.1 | 1 |
| Example 1 | Compound X-1 | | | |
| Comparative | Comparative | 451 | <0.1 | 2 |
| Example 2 | Compound X-2 | | | |
| Comparative | Comparative | 480 | 0.8 | 4 |
| Example 3 | Compound X-3 | | | |

Referring to Table 2, it could be found that the light emitting devices of Example 1 to Example 7 and the light emitting devices of Comparative Example 1 to Comparative Example 3 emitted light in a wavelength region of about 450 nm to about 480 nm. It could be found that the light emitting devices of Example 1 to Example 7 and the light emitting devices of Comparative Example 1 to Comparative Example 3 emitted blue light.

In Table 2, it could be found that the light emitting devices of Example 1 to Example 7 showed excellent device efficiency and life when compared to the light emitting devices of Comparative Example 1 to Comparative Example 3. It is thought that the light emitting devices of Example 1 to Example 7 included Compounds 10, 23, 24, 27, 30, 46, and 69, which are the polycyclic compounds of embodiments, and showed improved device efficiency and life. Compounds 10, 23, 24, 27, 30, 46, and 69, which are the polycyclic compounds of embodiments, include a boron atom as a ring-forming atom, and an oxygen atom or a sulfur atom is directly bonded to the boron atom.

It could be found that the light emitting devices of Examples 1, and 5 to 7 showed longer life than the light emitting devices of Examples 2 and 3. The light emitting devices of Examples 1, and 5 to 7 include Compounds 10, 30, 46, and 69, which are the polycyclic compounds of embodiments, and in Compounds 10, 30, 46, and 69, an oxygen atom or a sulfur atom is combined with an adjacent ring group to form a fused ring of seven rings or nine rings. In the fused ring structure of seven rings or nine rings, it is thought that an oxygen atom or a sulfur atom is directly bonded to a boron atom, and device life is further improved. Accordingly, the light emitting device including the polycyclic compound of an embodiment may show improved efficiency and life characteristics.

The light emitting device of Comparative Example 1 includes Comparative Compound X-1, and the light emitting device of Comparative Example 2 includes Comparative Compound X-2. In Comparative Compound X-1 and Comparative Compound X-2, a hydroxyl group is bonded to a boron atom, and it is thought that since the hydroxyl group bonded to the boron atom is unstable, the efficiency and life of the device were not improved.

The light emitting device of Comparative Example 3 includes Comparative Compound X-3. Comparative Compound X-3 has a structure in which a phenyl group is combined with a boron atom and is a compound in which an oxygen atom or a sulfur atom is not combined with a boron atom. It is thought that since Comparative Compound X-3 does not include an oxygen atom or a sulfur atom directly bonded to a boron atom, the life of the light emitting device of Comparative Example 3, including Comparative Compound X-3 was not improved.

The polycyclic compound of an embodiment may include a fused ring including a nitrogen atom and a boron atom as ring-forming atoms. The fused ring may be a fused ring of five rings, seven rings, or nine rings, and to the boron atom which is a ring-forming atom, an oxygen atom or a sulfur atom may be bonded. The oxygen atom or the sulfur atom is directly bonded to the boron atom, and the stability of the polycyclic compound may be improved. Accordingly, the polycyclic compound of an embodiment may contribute to the improvement of the efficiency and life of the light emitting device.

The light emitting device of an embodiment may include a first electrode, a second electrode disposed on the first electrode, and an emission layer disposed between the first electrode and the second electrode. The emission layer may include the polycyclic compound of an embodiment. The light emitting device of an embodiment including the polycyclic compound may show improved properties of efficiency and life.

The light emitting device of an embodiment may show improved device properties of high efficiency in a blue wavelength region.

The polycyclic compound of an embodiment may be included in an emission layer of a light emitting device to contribute to the increase of the efficiency of the light emitting device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A light emitting device, comprising:
a first electrode;
a second electrode disposed on the first electrode; and
an emission layer disposed between the first electrode and the second electrode and comprising a polycyclic compound represented by Formula 1: 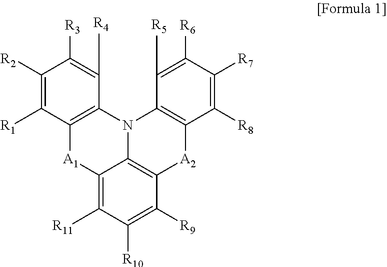
wherein in Formula 1,
at least one of A₁ and A₂ is a group represented by 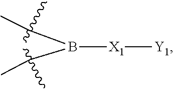
and the remainder of A₁ and A₂ is a direct linkage, C(R₂₁)(R₂₂), B(R₂₃), N(R₂₄), Si(R₂₅)(R₂₆), P(R₂₇), O, S, SO, SO₂, or CO,
X₁ is O, S, SO, or SO₂,
Y₁ is CO(R₂₈) or R₂₉,
R₁ to R₁₁ and R₂₁ to R₂₈ are each independently a hydrogen atom, a deuterium atom, a halogen atom, a hydroxyl group, a cyano group, a substituted or unsubstituted oxy group, a substituted or unsubstituted thio group, a substituted or unsubstituted amino group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or are combined with an adjacent group to form a ring, and
R₂₉ is a deuterium atom, a halogen atom, a hydroxyl group, a cyano group, a substituted or unsubstituted oxy group, a substituted or unsubstituted thio group, a substituted or unsubstituted amino group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or is combined with an adjacent group to form a ring.

2. The light emitting device of claim 1, wherein the polycyclic compound represented by Formula 1 is represented by Formula 1-A1 or Formula 1-A2: 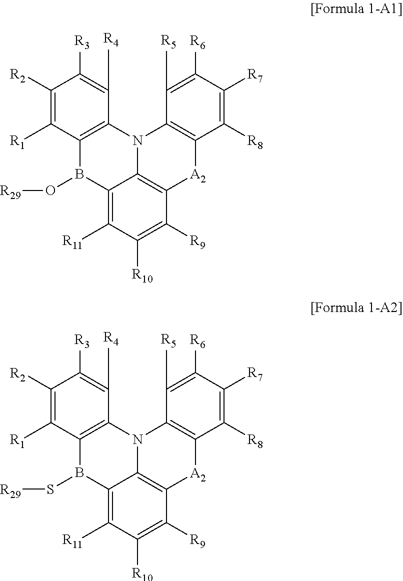
wherein in Formula 1-A1 and Formula 1-A2,
A₂, R₁ to R₁₁, and R₂₉ are the same as defined in Formula 1.

3. The light emitting device of claim 1, wherein the polycyclic compound represented by Formula 1 is represented by Formula 1-B1 or Formula 1-B2: 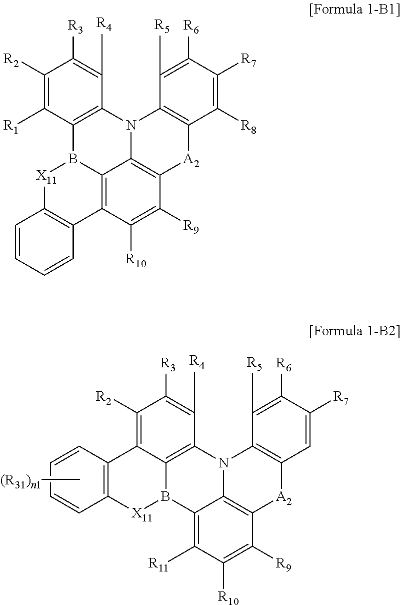
wherein in Formula 1-B1 and Formula 1-B2,
X₁₁ is O, S, or SO,
n1 is an integer from 0 to 4,
R₃₁ is a hydrogen atom, a deuterium atom, a substituted or unsubstituted alkyl group or 1 to 20 carbon atoms, or a substituted or unsubstituted aryl group of 6 to 30 ring-forming carbon atoms, and
A₂ and R₁ to R₁₁ are the same as defined in Formula 1.

4. The light emitting device of claim 1, wherein the polycyclic compound represented by Formula 1 is represented by Formula 1-B11 or Formula 1-B21: 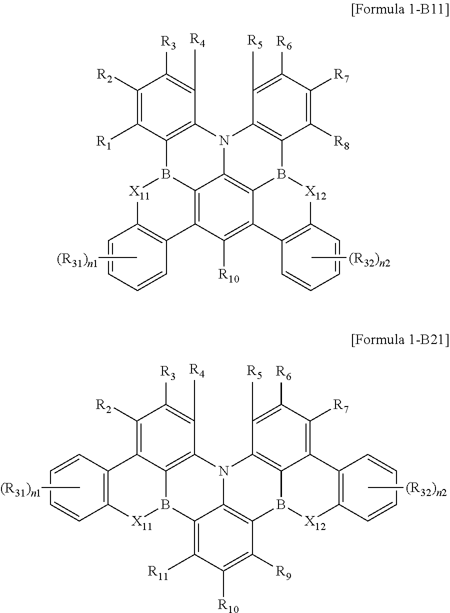
wherein in Formula 1-B11 and Formula 1-B21,
X₁₁ and X₁₂ are each independently O or S,
n1 and n2 are each independently an integer from 0 to 4,
R₃₁ and R₃₂ are each independently a hydrogen atom, a deuterium atom, or a substituted or unsubstituted alkyl group of 1 to 20 carbon atoms, and
R₁ to R₁₁ are the same as defined in Formula 1.

5. The light emitting device of claim 1, wherein the polycyclic compound represented by Formula 1 is represented by Formula 1-C: 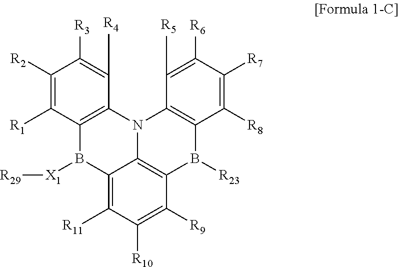
wherein in Formula 1-C,
R₁ to R₁₁, R₂₃, R₂₉, and X₁ are the same as defined in Formula 1.

6. The light emitting device of claim 1, wherein
A₁ or A₂ is B(R₂₃), and
R₂₃ is a substituted or unsubstituted methoxy group, a substituted or unsubstituted isopropoxy group, a substituted or unsubstituted methylthio group, a substituted or unsubstituted isopropylthio group, a substituted or unsubstituted phenoxy group, a substituted or unsubstituted phenyl group, or a substituted or unsubstituted phenylthio group.

7. The light emitting device of claim 1, wherein R₁ to R₁₁ are each independently a substituted or unsubstituted alkyl group of 1 to 5 carbon atoms, a substituted or unsubstituted aryl group of 6 to 12 carbon atoms, a substituted or unsubstituted alkyl amino group, a substituted or unsubstituted aryl amino group, a substituted or unsubstituted aryl oxy group, or an unsubstituted carbazole group.

8. The light emitting device of claim 1, wherein the polycyclic compound represented by Formula 1 is represented by one of Formula 1-E1 to Formula 1-E3: 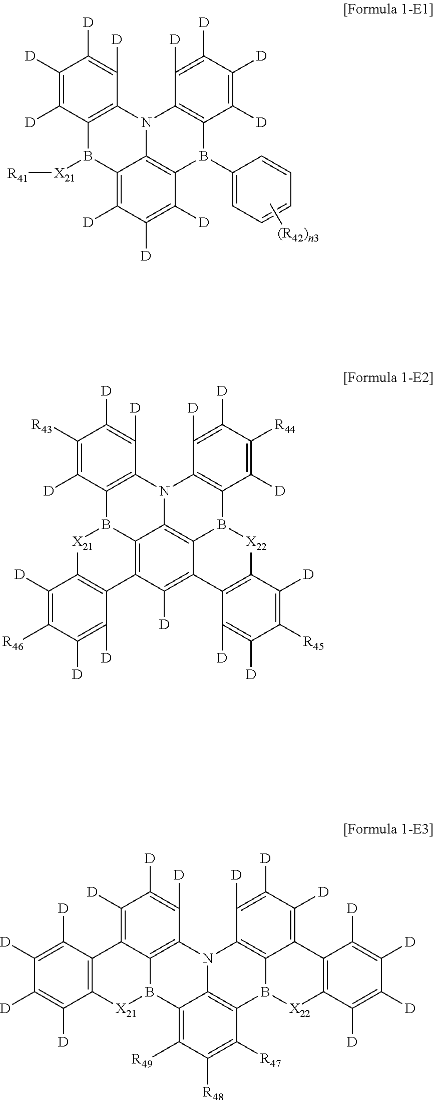
wherein in Formula 1-E1,
n3 is an integer from 0 to 5,
wherein in Formula 1-E1 to Formula 1-E3,
X₂₁ and X₂₂ are each independently O or S, and
R₄₁ to R₄₉ are each independently a hydrogen atom, a deuterium atom, a methyl group substituted with a deuterium atom, an isopropyl group substituted with a deuterium atom, a t-butyl group substituted with a deuterium atom, or a phenyl group substituted with a deuterium atom.

9. The light emitting device of claim 1, wherein A₁ and A₂ in Formula 1 are the same.

10. The light emitting device of claim 1, wherein
the emission layer is a delayed fluorescence emission layer comprising a host and a dopant, and
the dopant comprises the polycyclic compound.

11. The light emitting device of claim 1, wherein the emission layer comprises at least one compound selected from Compound Group 1: 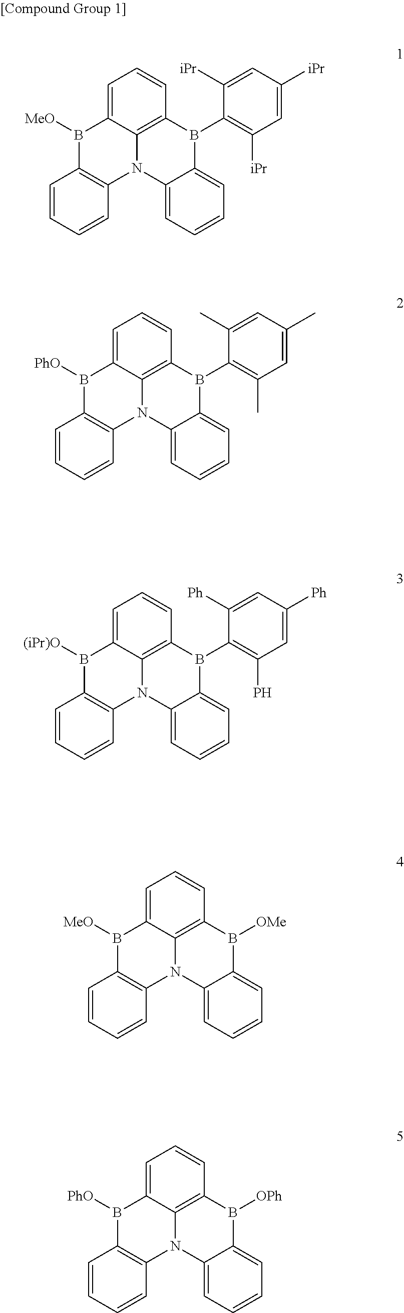 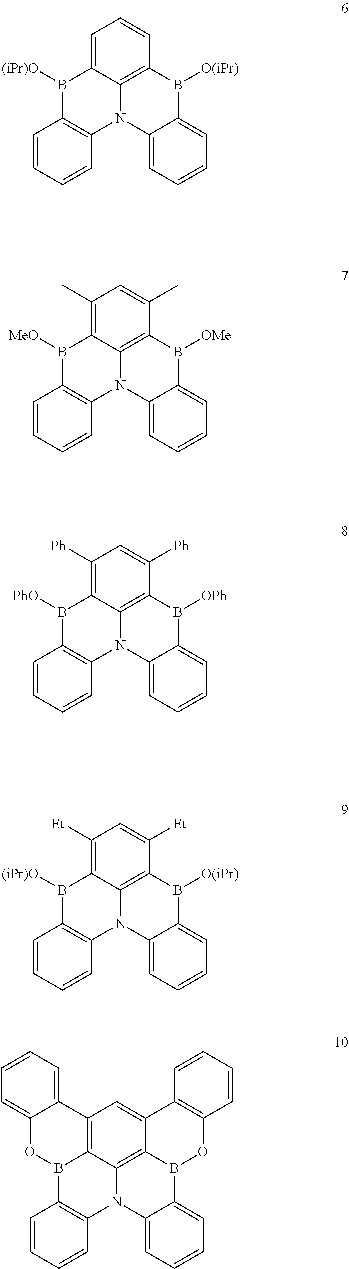 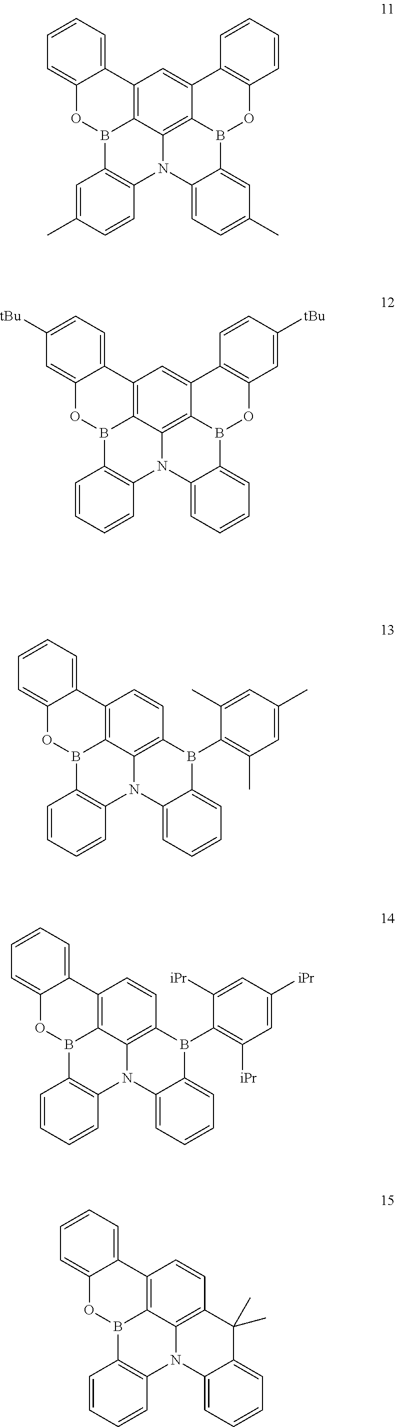 [SMILES: Cc1ccc2c(c1)B1Oc3ccccc3-c3cc4c5c(c31)N2c1ccc(C)cc1B5Oc1ccccc1-4 ; CC(C)(C)c1ccc2c(c1)OB1c3ccccc3N3c4ccccc4B4Oc5cc(C(C)(C)C)ccc5-c5cc-2c1c3c54 ; Cc1cc(C)c(B2c3ccccc3N3c4ccccc4B4Oc5ccccc5-c5ccc2c3c54)c(C)c1 ; CC(C)c1cc(C(C)C)c(B2c3ccccc3N3c4ccccc4B4Oc5ccccc5-c5ccc2c3c54)c(C(C)C)c1 ; CC1(C)c2ccccc2N2c3ccccc3B3Oc4ccccc4-c4ccc1c2c43] 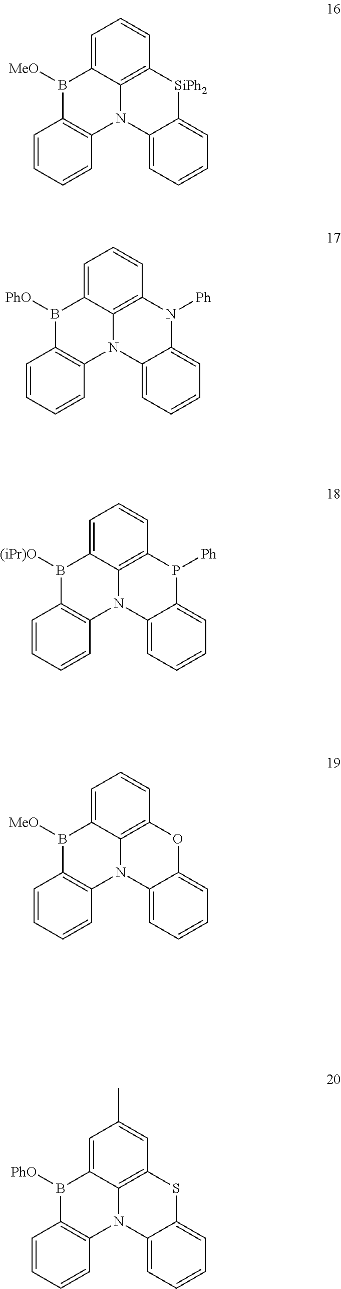 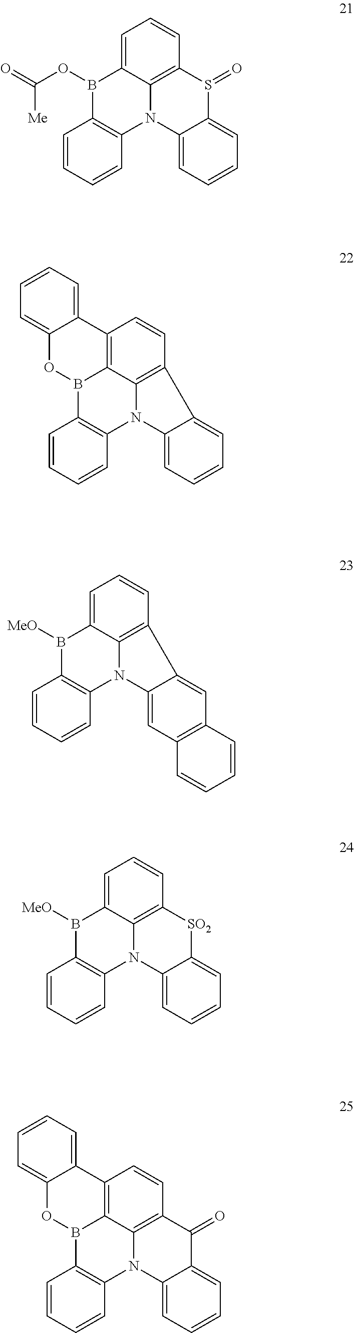 [SMILES: CC(=O)OB1c2ccccc2N2c3ccccc3S(=O)c3cccc1c32 ; c1ccc2c(c1)OB1c3ccccc3-n3c4ccccc4c4ccc-2c1c43 ; COB1c2ccccc2-n2c3cc4ccccc4cc3c3cccc1c32 ; COB1c2ccccc2N2c3ccccc3S(=O)(=O)c3cccc1c32 ; O=c1c2ccccc2n2c3c4c(ccc13)-c1ccccc1OB4c1ccccc1-2] 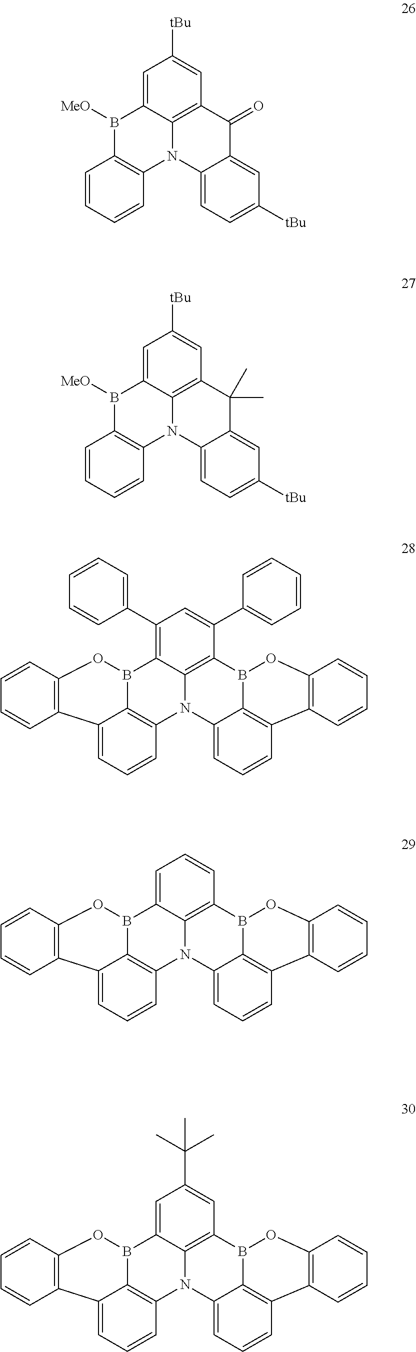 [SMILES: COB1c2ccccc2-n2c3ccc(C(C)(C)C)cc3c(=O)c3cc(C(C)(C)C)cc1c32 ; COB1c2ccccc2N2c3ccc(C(C)(C)C)cc3C(C)(C)c3cc(C(C)(C)C)cc1c32 ; c1ccc(-c2cc(-c3ccccc3)c3c4c2B2Oc5ccccc5-c5cccc(c52)N4c2cccc4c2B3Oc2ccccc2-4)cc1 ; c1ccc2c(c1)OB1c3cccc4c3N(c3cccc-2c31)c1cccc2c1B4Oc1ccccc1-2 ; CC(C)(C)c1cc2c3c(c1)B1Oc4ccccc4-c4cccc(c41)N3c1cccc3c1B2Oc1ccccc1-3] 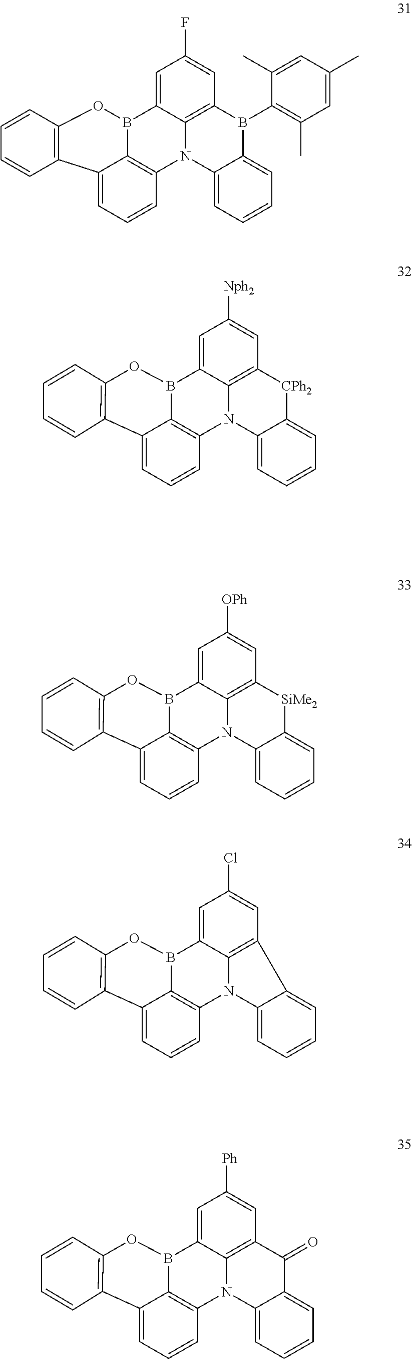 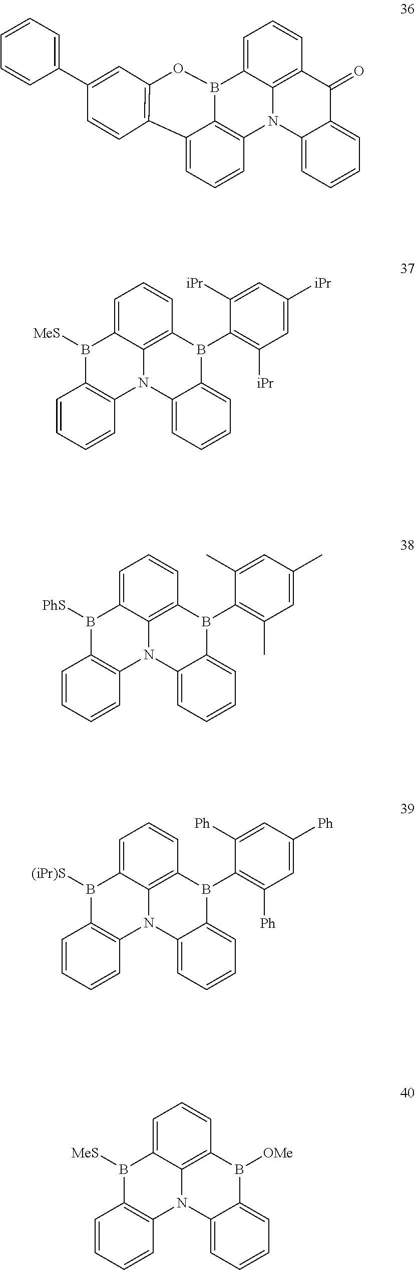 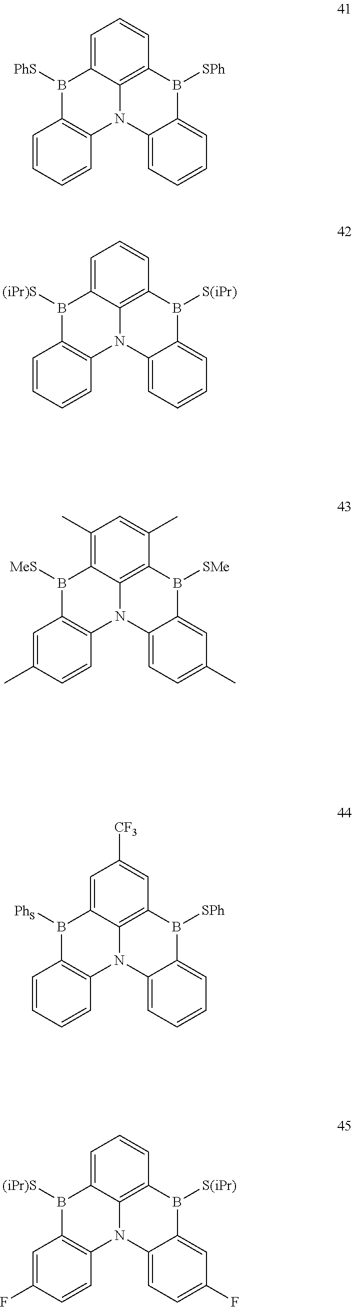 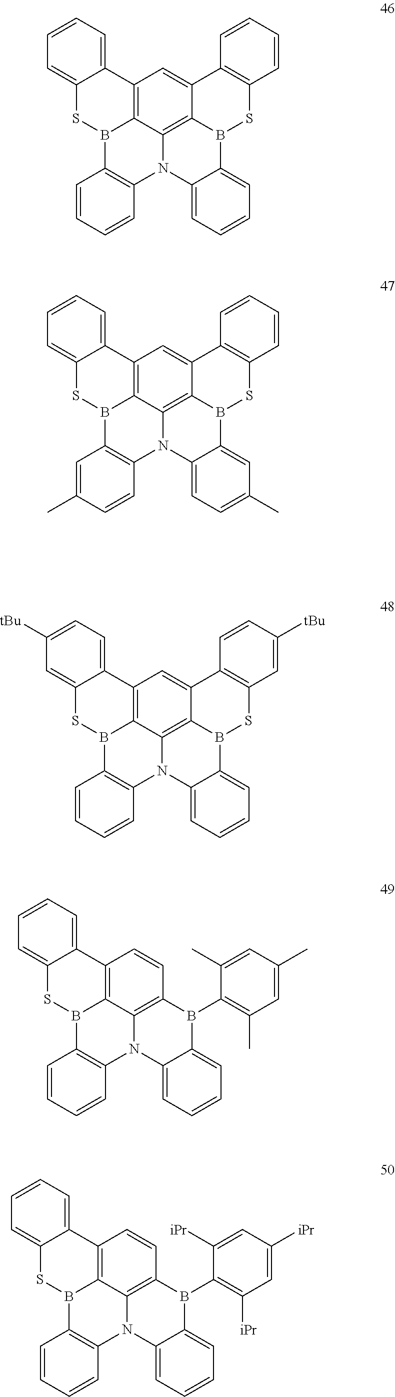 [SMILES: c1ccc2c(c1)SB1c3ccccc3N3c4ccccc4B4Sc5ccccc5-c5cc-2c1c3c54 ; Cc1ccc2c(c1)B1Sc3ccccc3-c3cc4c5c(c31)N2c1ccc(C)cc1B5Sc1ccccc1-4 ; CC(C)(C)c1ccc2c(c1)SB1c3ccccc3N3c4ccccc4B4Sc5cc(C(C)(C)C)ccc5-c5cc-2c1c3c54 ; Cc1cc(C)c(B2c3ccccc3N3c4ccccc4B4Sc5ccccc5-c5ccc2c3c54)c(C)c1 ; CC(C)c1cc(C(C)C)c(B2c3ccccc3N3c4ccccc4B4Sc5ccccc5-c5ccc2c3c54)c(C(C)C)c1] 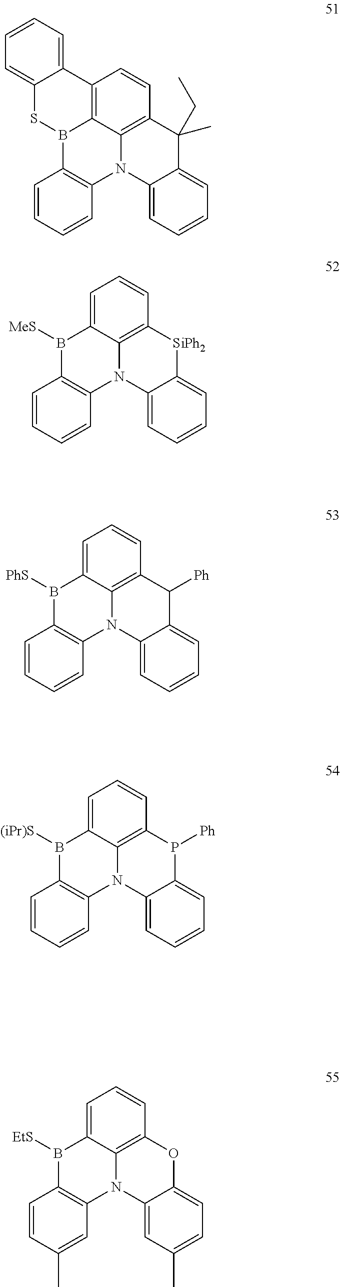 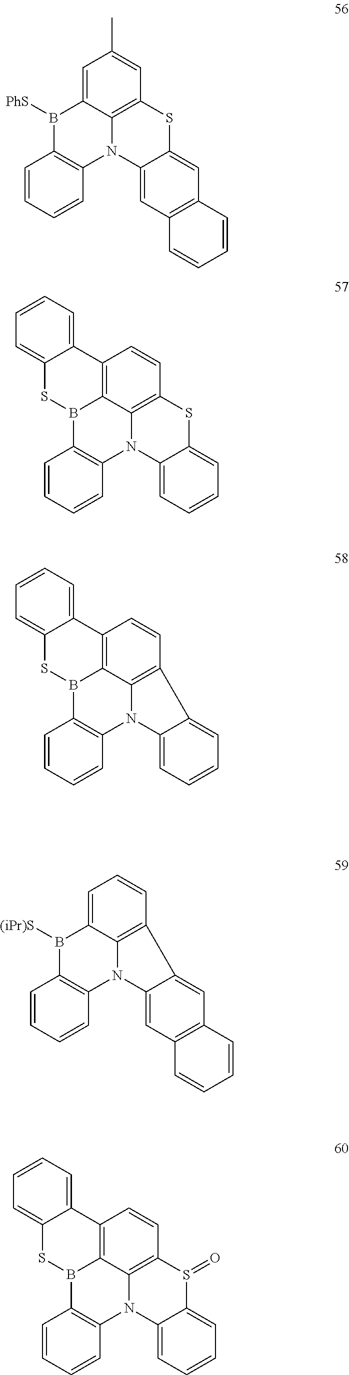 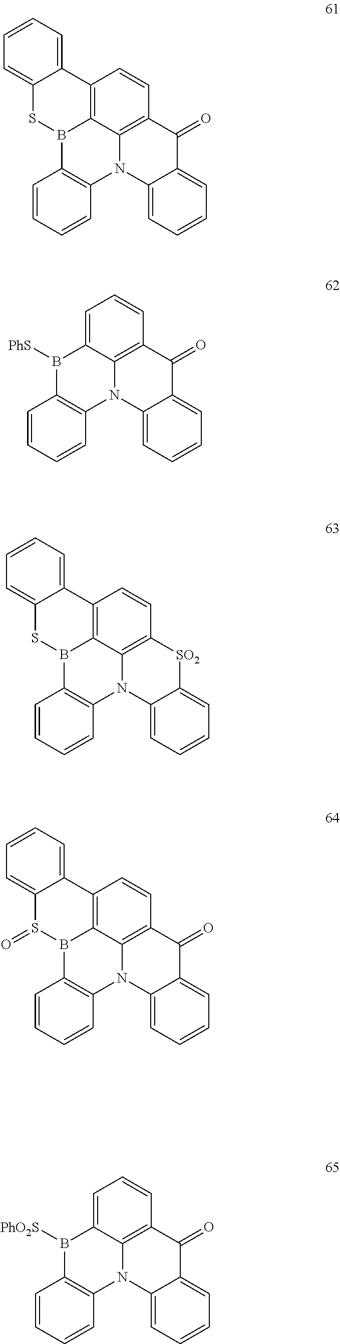 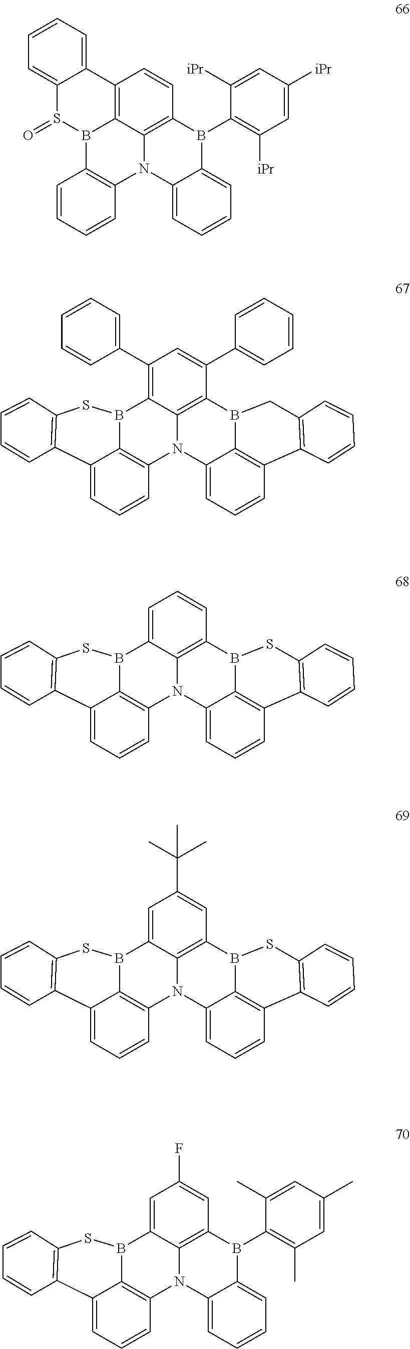 [SMILES: CC(C)c1cc(C(C)C)c(B2c3ccccc3N3c4ccccc4B4c5c(ccc2c53)-c2ccccc2S4=O)c(C(C)C)c1 ; c1ccc(-c2cc(-c3ccccc3)c3c4c2B2Cc5ccccc5-c5cccc(c52)N4c2cccc4c2B3Sc2ccccc2-4)cc1 ; c1ccc2c(c1)SB1c3cccc4c3N(c3cccc-2c31)c1cccc2c1B4Sc1ccccc1-2 ; CC(C)(C)c1cc2c3c(c1)B1Sc4ccccc4-c4cccc(c41)N3c1cccc3c1B2Sc1ccccc1-3 ; Cc1cc(C)c(B2c3ccccc3N3c4cccc5c4B(Sc4ccccc4-5)c4cc(F)cc2c43)c(C)c1] 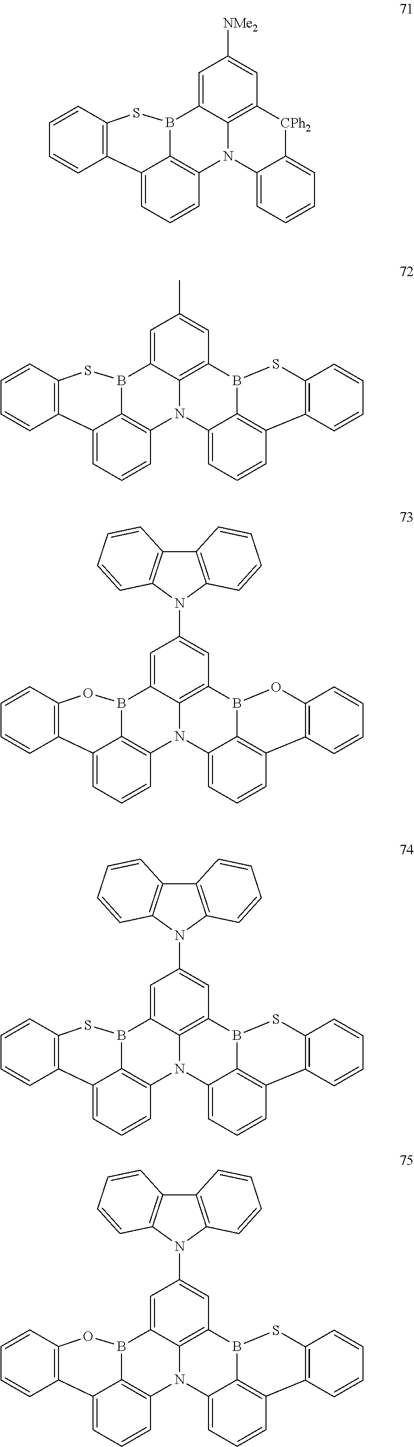 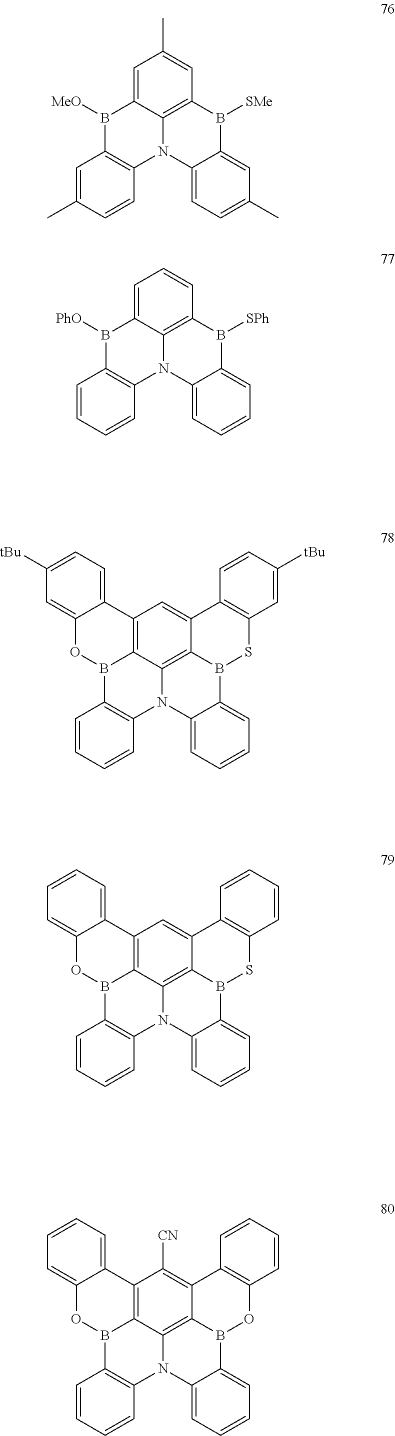 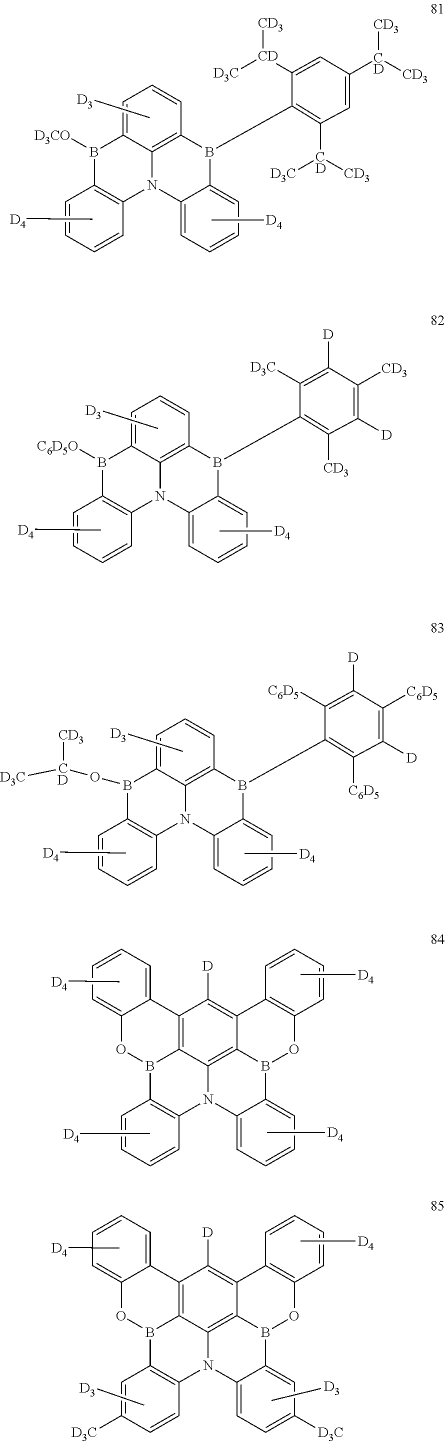 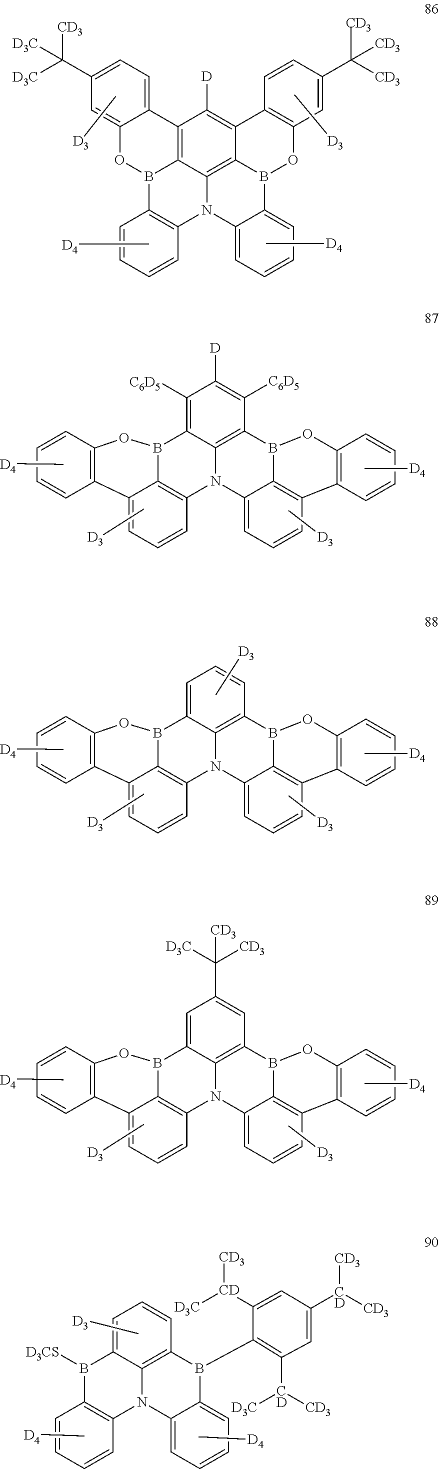 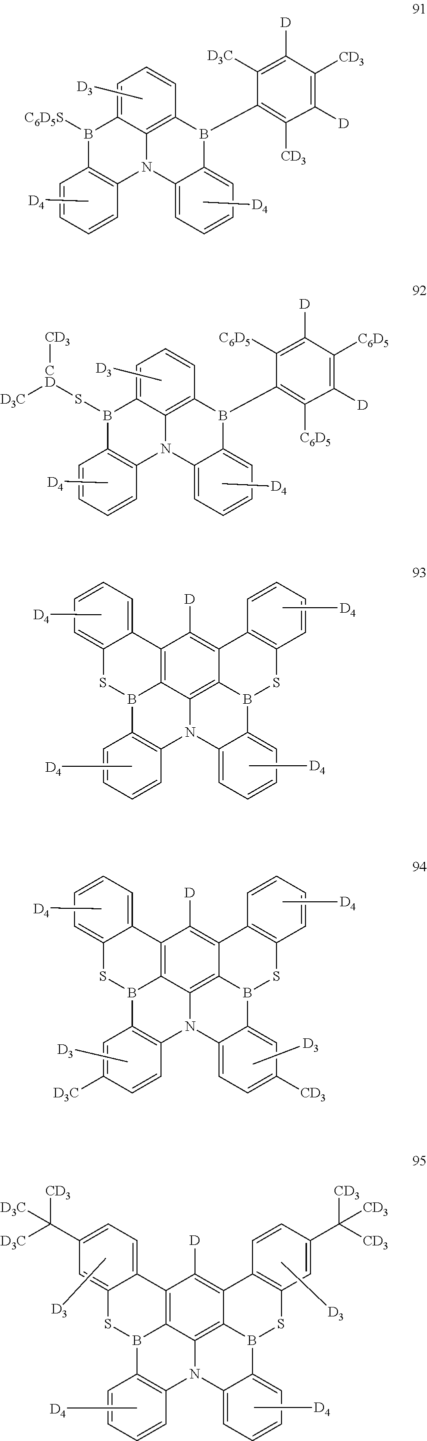 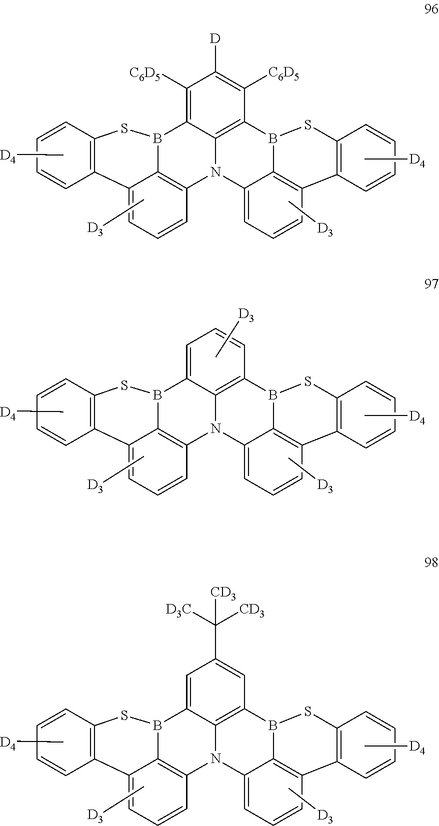
wherein in Compound Group 1,
Me is a methyl group,
Et is an ethyl group,
iPr is an isopropyl group,
tBu is a t-butyl group,
Ph is a phenyl group, and
D is a deuterium atom.

12. A polycyclic compound represented by Formula 1: 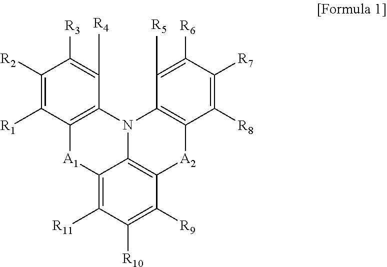
wherein in Formula 1,
at least one of A1 and A₂ is a group represented by 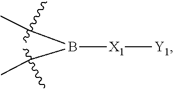
and the remainder of A₁ and A₂ is a direct linkage, C(R₂₁)(R₂₂), B(R₂₃), N(R₂₄), Si(R₂₅)(R₂₆), P(R₂₇), O, S, SO, SO₂, or CO,
X₁ is O, S, SO, or SO₂,
Y₁ is CO(R₂₈) or R₂₉,
R₁ to R₁₁ and R₂₁ to R₂₈ are each independently a hydrogen atom, a deuterium atom, a halogen atom, a hydroxyl group, a cyano group, a substituted or unsubstituted oxy group, a substituted or unsubstituted thio group, a substituted or unsubstituted amino group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or are combined with an adjacent group to form a ring, and
R₂₉ is a deuterium atom, a halogen atom, a hydroxyl group, a cyano group, a substituted or unsubstituted oxy group, a substituted or unsubstituted thio group, a substituted or unsubstituted amino group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or is combined with an adjacent group to form a ring.

13. The polycyclic compound of claim 12, wherein Formula 1 is represented by Formula 1-A1 or Formula 1-A2: 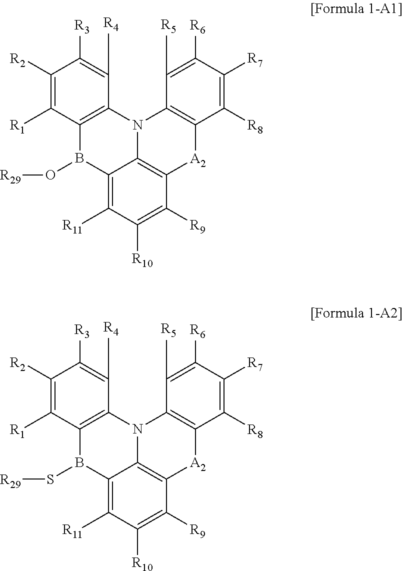
wherein in Formula 1-A1 and Formula 1-A2,
A₂, R₁ to R₁₁, and R₂₉ are the same as defined in Formula 1.

14. The polycyclic compound of claim 12, wherein Formula 1 is represented by Formula 1-B1 or Formula 1-B2: 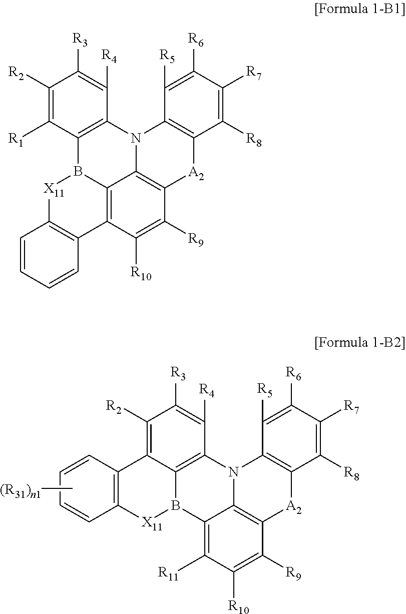
wherein in Formula 1-B1 and Formula 1-B2,
X₁₁ is O, S, or SO,
n1 is an integer from 0 to 4,
R₃₁ is a hydrogen atom, a deuterium atom, a substituted or unsubstituted alkyl group or 1 to 20 carbon atoms, or a substituted or unsubstituted aryl group of 6 to 30 ring-forming carbon atoms, and
A₂ and R₁ to R₁₁ are the same as defined in Formula 1.

15. The polycyclic compound of claim 12, wherein Formula 1 is represented by Formula 1-B11 or Formula 1-B21: 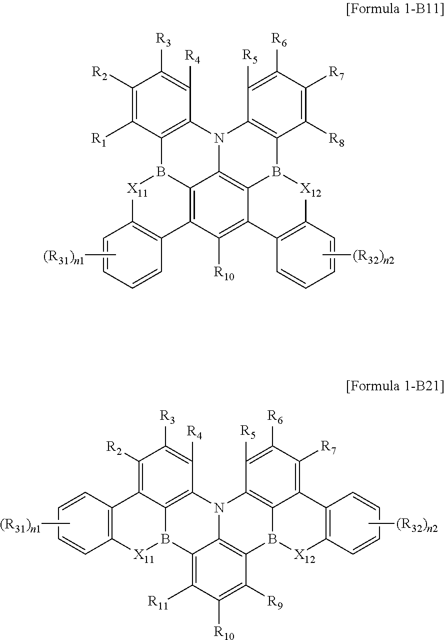
wherein in Formula 1-B11 and Formula 1-B21,
X₁₁ and X₁₂ are each independently O, or S,
n1 and n2 are each independently an integer from 0 to 4,
R₃₁ and R₃₂ are each independently a hydrogen atom, a deuterium atom, or a substituted or unsubstituted alkyl group or 1 to 20 carbon atoms, and
R₁ to R₁₁ are the same as defined in Formula 1.

16. The polycyclic compound of claim 12, wherein Formula 1 is represented by Formula 1-C: 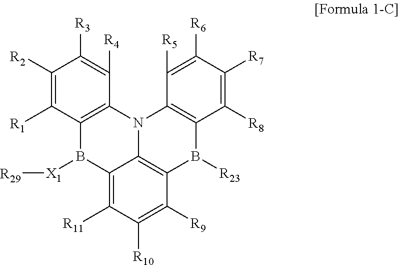
wherein in Formula 1-C,
R₁ to R₁₁, R₂₃, R₂₉, and X₁ are the same as defined in Formula 1.

17. The polycyclic compound of claim 12, wherein
A₁ or A₂ is B(R₂₃), and
R₂₃ is a substituted or unsubstituted methoxy group, a substituted or unsubstituted isopropoxy group, a substituted or unsubstituted methylthio group, a substituted or unsubstituted isopropylthio group, a substituted or unsubstituted phenoxy group, a substituted or unsubstituted phenyl group, or a substituted or unsubstituted phenylthio group.

18. The polycyclic compound of claim 12, wherein R₁ to R₁₁ are each independently a substituted or unsubstituted alkyl group of 1 to 5 carbon atoms, a substituted or unsubstituted aryl group of 6 to 12 carbon atoms, a substituted or unsubstituted alkyl amino group, a substituted or unsubstituted aryl amino group, a substituted or unsubstituted aryl oxy group, or an unsubstituted carbazole group.

19. The polycyclic compound of claim 12, wherein Formula 1 is represented by one of Formula 1-E1 to Formula 1-E3: 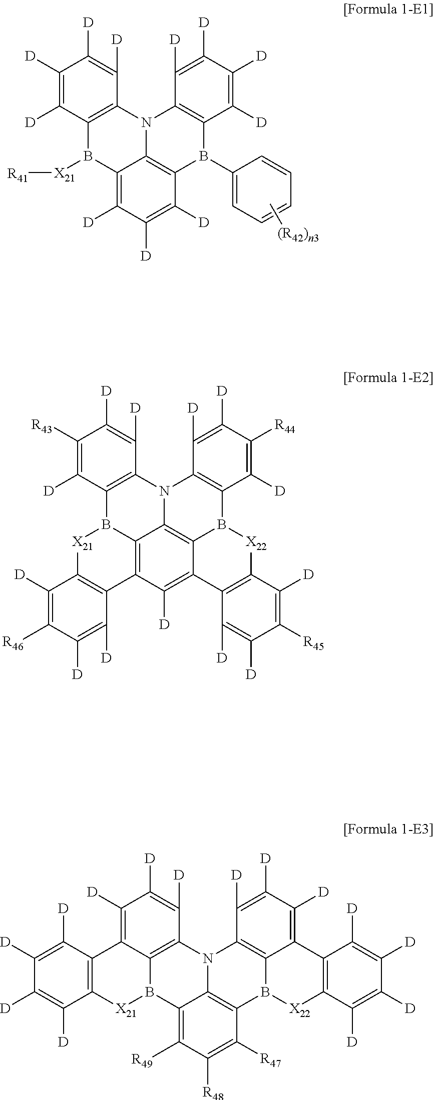
wherein in Formula 1-E1,
n3 is an integer from 0 to 5,
wherein in Formula 1-E1 to Formula 1-E3,
X₂₁ and X₂₂ are each independently O or S, and
R₄₁ to R₄₉ are each independently a hydrogen atom, a deuterium atom, a methyl group substituted with a deuterium atom, an isopropyl group substituted with a deuterium atom, a t-butyl group substituted with a deuterium atom, or a phenyl group substituted with a deuterium atom.

20. The polycyclic compound of claim 12, wherein
at least one of R₁ to R₁₁ is a deuterium atom, or
at least one of A₁, A₂, and R₁ to R₁₁ comprises a deuterium atom as a substituent.

21. The polycyclic compound of claim 12, wherein A₁ and A₂ in Formula 1 are the same.

22. The polycyclic compound of claim 12, wherein Formula 1 is represented by one selected from Compound Group 1: 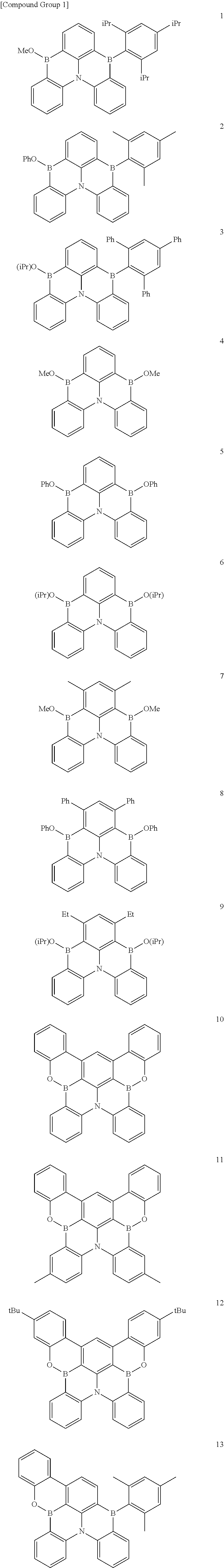 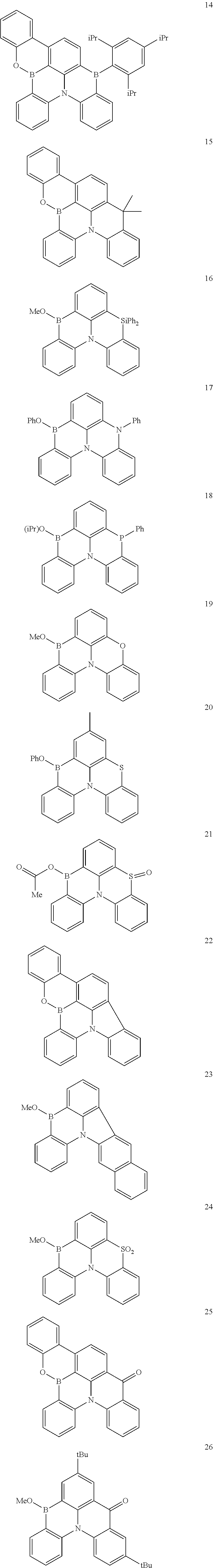 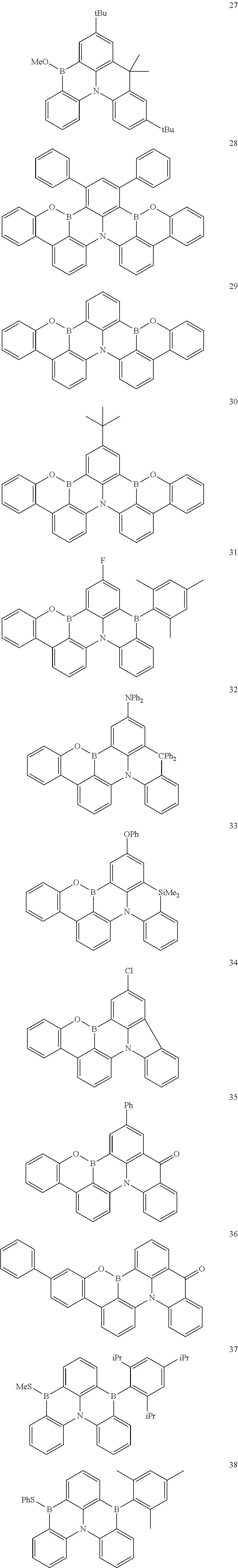 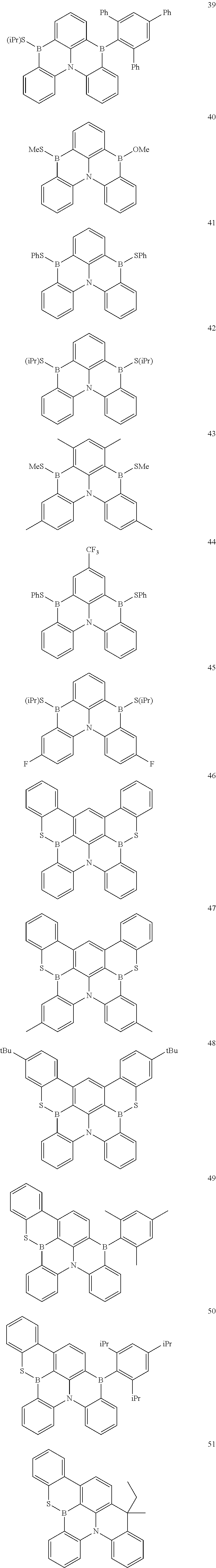 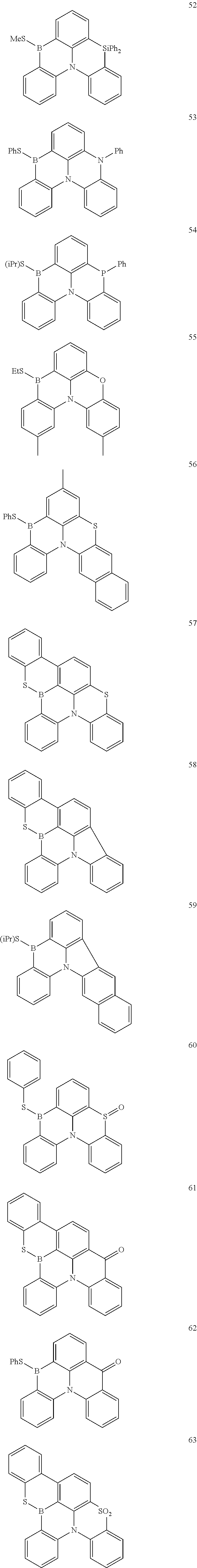 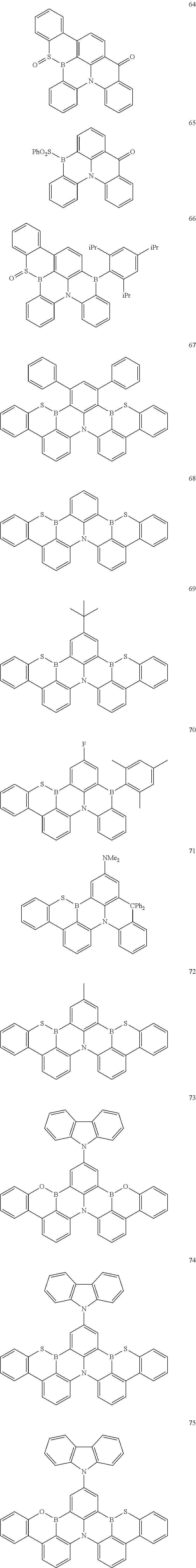 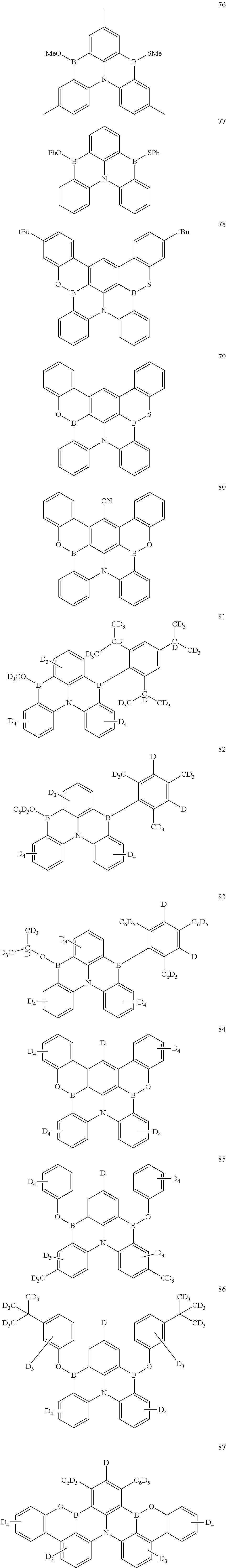 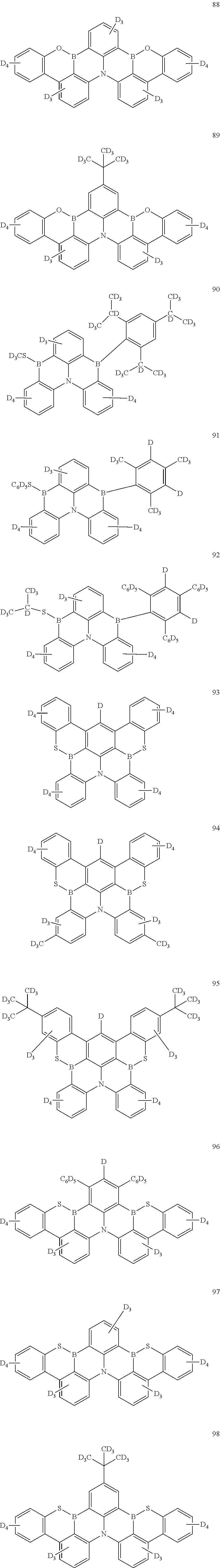
wherein in Compound Group 1,
Me is a methyl group,
Et is an ethyl group,
iPr is an isopropyl group,
tBu is a t-butyl group,
Ph is a phenyl group, and
D is a deuterium atom.
